(19) United States
(12) Patent Application Publication
(10) Pub. No.: US 2026/0230045 A1
(43) Pub. Date: Aug. 6, 2026

(54) METHODS AND APPARATUS TO CALIBRATE VOLTAGE-TO-DELAY CONVERSIONS

(71) Applicant: Texas Instruments Incorporated, Dallas, TX (US)

(72) Inventors: Sai Vikas Kandimalla, Miryalaguda (IN); Neeraj Shrivastava, Bangalore (IN); Samriddh Bhalla, Bengaluru (IN); Ashwin Ravi, Bangalore (IN); Shivam Srivastava, Roorkee (IN)

(21) Appl. No.: 19/042,335

(22) Filed: Jan. 31, 2025

(51) Int. Cl. H03F 3/04; G04F 10/00; H03K 5/00; H03K 5/13

(52) U.S. Cl. CPC H03F 3/04; G04F 10/005; H03K 5/13; H03K 2005/00019

(57) ABSTRACT

An example apparatus includes: first amplifier circuitry having a first output and a second output; second amplifier circuitry having an output; first transistor circuitry having a first terminal and a control terminal; second transistor circuitry having a first terminal and a control terminal, the control terminal of the second transistor circuitry coupled to the output of the second amplifier circuitry and the control terminal of the first transistor circuitry; and voltage-to-delay circuitry having a first input and a second input, the first input of the voltage-to-delay circuitry coupled to the first output of the first amplifier circuitry and the first terminal of the first transistor circuitry, the second input of the voltage-to-delay circuitry coupled to the second output of the first amplifier circuitry and the first terminal of the second transistor circuitry.

### CROSS-REFERENCE TO RELATED APPLICATION

This patent application herein incorporates by reference in its entirety “VOLTAGE-TO-DELAY CONVERTER” U.S. patent application Ser. No. 18/498,358, which is assigned to the assignee of the instant application.

### TECHNICAL FIELD

This description relates generally to voltage-to-delay conversions and, more particularly, to methods and apparatus to calibrate voltage-to-delay conversions.

### BACKGROUND

Analog-to-digital converter (ADC) circuitry generates a digital output responsive to an analog input. Digital outputs of the ADC circuitry allow digital systems to perform digital signal processing operations using digital representations of analog signals. Some ADC circuitry implements a pipeline design to sequentially produce portions of digital values representing an analog signal over time. Some pipeline designs convert an analog voltage-to-delays, which represent the analog voltage in a time domain. In such pipelines, a time-to-digital converter (TDC) produces a digital output responsive to the timing of the delays in continuous time.

### SUMMARY

For methods and apparatus to calibrate voltage-to-delay conversions, an example apparatus includes first amplifier circuitry having a first output and a second output; second amplifier circuitry having an output; first transistor circuitry having a first terminal and a control terminal; second transistor circuitry having a first terminal and a control terminal, the control terminal of the second transistor circuitry coupled to the output of the second amplifier circuitry and the control terminal of the first transistor circuitry; and voltage-to-delay circuitry having a first input and a second input, the first input of the voltage-to-delay circuitry coupled to the first output of the first amplifier circuitry and the first terminal of the first transistor circuitry, the second input of the voltage-to-delay circuitry coupled to the second output of the first amplifier circuitry and the first terminal of the second transistor circuitry. Other examples are described.

For methods and apparatus to calibrate voltage-to-delay conversions, an example apparatus includes amplifier circuitry having a first input, a second input, a first output, and a second output; voltage-to-delay circuitry having a first input and a second input; pulse generator circuitry having a first input and a second input; and calibration circuitry having a first input, a second input, a first output, and a second output, the first input of the calibration circuitry coupled to the first input of the amplifier circuitry, the second input of the calibration circuitry coupled to the second input of the amplifier circuitry, the first output of the calibration circuitry coupled to the first output of the amplifier circuitry, the first input of the voltage-to-delay circuitry, and the first input of the pulse generator circuitry, the second output of the calibration circuitry coupled to the second output of the amplifier circuitry, the second input of the voltage-to-delay circuitry, and the second input of the pulse generator circuitry. Other examples are described.

For methods and apparatus to calibrate voltage-to-delay conversions, an example apparatus includes amplifier circuitry having an input and an output; voltage-to-delay circuitry having an input; calibration circuitry having an input and an output, the input of the calibration circuitry coupled to the input of the amplifier circuitry, the output of the calibration circuitry coupled to the output of the amplifier circuitry and the input of the voltage-to-delay circuitry, the calibration circuitry configured to: adjust a common mode voltage at the output of the amplifier circuitry by an offset correction value; and adjust the common mode voltage at the output of the amplifier circuitry by a gain correction value. Other examples are described.

### BRIEF DESCRIPTION OF THE DRAWINGS

FIG. 1 is a block and schematic diagram of example ADC circuitry including example delay ADC circuitry and example calibration controller circuitry.

FIG. 2 is a block and schematic diagram of an example of the delay ADC circuitry of FIG. 1 including example sampling circuitry, example amplifier circuitry, example calibration circuitry, example voltage-to-delay circuitry, and example pulse generator circuitry.

FIG. 3 is a schematic diagram of an example of the sampling circuitry of FIG. 2.

FIG. 4 is a schematic diagram of an example of the delay ADC circuitry of FIG. 2 including examples of the amplifier circuitry of FIG. 2, the calibration circuitry of FIG. 2, the voltage-to-delay circuitry of FIG. 2, and the pulse generator circuitry of FIG. 2.

FIG. 5 is a timing diagram of example operations of the delay ADC circuitry of FIGS. 2 and 4.

FIG. 6 is a schematic diagram of an example of the calibration circuitry of FIGS. 2 and 4 including example amplifier circuitry.

FIG. 7 is a block diagram of an example of the calibration controller circuitry of FIG. 1 including example offset correction circuitry and example gain correction circuitry.

FIG. 8 is a flowchart representative of example machine-readable instructions or example operations that may be at least one of executed, instantiated, or performed using an example implementation of the delay ADC circuitry of FIGS. 2 and 4.

FIG. 9 is a flowchart representative of example machine-readable instructions or example operations that may be at least one of executed, instantiated, or performed using example implementations of the calibration circuitry of FIGS. 2, 4, and 6, the offset correction circuitry of FIG. 7, or more generally the delay ADC circuitry of FIGS. 2 and 4 and the calibration controller circuitry of FIGS. 1 and 7.

FIG. 10 is a flowchart representative of example machine-readable instructions or example operations that may be at least one of executed, instantiated, or performed using example implementations of the calibration circuitry of FIGS. 2, 4, and 6, the gain correction circuitry of FIG. 7, or more generally the delay ADC circuitry of FIGS. 2 and 4 and the calibration controller circuitry of FIGS. 1 and 7.

FIG. 11 is a plot of an example common mode rejection ratio of the voltage-to-delay circuitry of FIGS. 2 and 4 with and without the calibration operations of FIGS. 9 and 10.

FIG. 12 is a plot of an example sound to noise ratio of the delay ADC circuitry of FIGS. 2 and 4 with and without the calibration operations of FIGS. 9 and 10.

FIG. 13 is a schematic diagram of another example of the ADC circuitry of FIG. 1 including an amplifier circuitry to implement the calibration operations of FIGS. 9 and 10 in a first stage.

FIG. 14 is a block diagram of an example processing platform including programmable circuitry structured to execute, instantiate, or perform the example machine-readable instructions or perform the example operations of FIGS. 8, 9, and 10 to implement the calibration controller circuitry of FIGS. 1 and 7.

FIG. 15 is a block diagram of an example implementation of the programmable circuitry of FIG. 14.

FIG. 16 is a block diagram of another example implementation of the programmable circuitry of FIG. 14.

The drawings are not necessarily to scale. Generally, the same reference numbers in the drawing(s) and this description refer to the same or similar (functionally and/or structurally) features and/or parts. Although the drawings show regions with clean lines and boundaries, some or all of these lines and boundaries may be idealized. In reality, the boundaries or lines may be unobservable, blended or irregular.

### DETAILED DESCRIPTION

Analog-to-digital converter (ADC) circuitry generates a digital output responsive to an analog input. Digital outputs of the ADC circuitry allow digital systems to perform digital signal processing operations using digital representations of analog signals. Some ADC circuitry implements a pipeline design to sequentially produce portions of digital values representing an analog signal over time. Some pipeline designs convert an analog voltage-to-delays, which represent the analog voltage in a time domain. In such pipelines, a time-to-digital converter (TDC) produces a digital output responsive to the timing of the delays in continuous time.

Voltage-to-delay conversions occur in a series of stages. In a first stage of the voltage-to-delay conversion, also referred to as a reset stage, a first and second capacitor of the voltage-to-delay circuitry are charged to a reference voltage. During a second stage of the voltage-to-delay conversion, amplifier circuitry discharges the first and second capacitors at different rates based on the magnitude of the analog input signals. For example, the amplifier circuitry sinks a first current from the first capacitor responsive to the first analog input signal. Similarly, the amplifier circuitry sinks a second current from the second capacitor responsive to the second analog input signal. During the second stage, the difference between the plus and minus analog inputs produces different discharge rates of the capacitors of the voltage-to-delay circuitry. At the end of the second stage, the voltages of the first and second capacitors have shifted responsive to the difference between the analog input signals.

During a third stage of the voltage-to-delay conversion, the voltage-to-delay circuitry uses a bias current to evenly discharge the remaining charge of the first and second capacitors. Also, during the third stage, pulse generator circuitry monitors the discharge of the first and second capacitors. The pulse generator circuitry generates a plus delay signal representing the voltage of the first capacitor and a minus delay signal representing the voltage of the second capacitor. The pulse generator circuitry produces a falling edge on the plus delay signal responsive to the voltage of the first capacitor falling below a threshold voltage. Similarly, the pulse generator circuitry produces a falling edge on the minus delay signal responsive to the voltage of the second capacitor falling below the threshold voltage. The difference between the falling edges of the plus and minus delay signals is proportional to difference in the rate of discharge during the second stage of the voltage-to-delay conversion. Such voltage-to-delay operations are further illustrated and described in “VOLTAGE-TO-DELAY CONVERTER” U.S. patent application Ser. No. 18/498,358, which is incorporated by reference in its entirety and is assigned to the assignee of the instant application.

In differential analog-to-digital conversions, the analog input of the ADC circuitry is represented as the voltage difference between analog input signals, which may be referred to as plus and minus input signals. The voltage halfway between the voltages of the analog inputs is referred to as a common mode voltage. For example, if the plus input signal is four volts and the minus input signal is eight volts, the analog input voltage of the ADC circuitry is four volts and the common mode voltage is six volts. In another example, if the plus input signal is eight volts and the minus input signal is twelve volts, the analog input voltage of the ADC circuitry is four volts and the common mode voltage is ten volts. Preferably, in both examples, the ADC circuitry produces a digital output representing four volts. However, during conversion, components of the ADC circuitry fail to completely reject the contributions of the common mode voltage. In such examples, although the differential voltages are the same, the digital output varies. Such variation in the output voltage of the ADC circuitry responsive to different common mode voltages are characterized by a common mode rejection ratio (CMRR). CMRR represents the ability of differential circuitry to reduce the impact of common mode voltages on an output. ADC circuitry having a low CMRR produces an output that is susceptible to changes in the common mode voltage of the analog inputs.

In voltage-to-delay conversions, a midpoint between the plus and minus delay signals, which differentially represent the analog voltage, represents the common mode voltage. In operation, mismatches between components of the voltage-to-delay circuitry modify the timing of the falling edges of the plus or minus delay signals. Such modifications in the timing of the falling edges of the plus or minus delay signals change the common mode and degrades CMRR. Also, during the voltage-to-delay conversion, the amplifier circuitry and the voltage-to-delay circuitry may amplify the common mode voltage by a gain, which further degrades the CMRR of the ADC circuitry.

Examples described herein include methods and apparatus to calibrate voltage-to-delay conversions using calibration circuitry. In some examples, the delay domain ADC circuitry includes first amplifier circuitry, second amplifier circuitry, sampling circuitry, calibration circuitry, voltage-to-delay (V2D) circuitry, pulse generator circuitry, time to digital converter (TDC) circuitry, and calibration controller circuitry. The first amplifier circuitry and the sampling circuitry receive plus and minus analog input signals from an analog signal source. The second amplifier circuitry receives plus and minus DAC signals from a calibration DAC of the calibration controller circuitry. In non-calibration operations, the sampling circuitry provides the plus and minus analog input signals to the calibration circuitry. In calibration operations, the sampling circuitry provides the plus and minus DAC signals to the calibration circuitry. The calibration circuitry compares the common mode voltage of the plus and minus input signals to a reference input common mode voltage from the calibration controller circuitry. During the second stage of the voltage-to-delay conversion, the calibration circuitry sinks currents from the first and second capacitors of the V2D circuitry responsive to the difference between the reference input common mode voltage and the common mode voltage from the sampling circuitry. Advantageously, the currents of the calibration circuitry may correct for one or both common mode voltage offset or common mode gain. Advantageously, using the calibration circuitry to reduce the common mode voltage offset or common mode gain improves the CMRR of the voltage-to-delay conversion.

In some described examples, the calibration controller circuitry performs calibration operations to determine the reference input common mode voltage and set the gain of the calibration circuitry. In offset calibration operations, the calibration controller circuitry disables the first amplifier circuitry and sets the plus and minus DAC signals to have a common mode voltage approximately equal to zero. The TDC circuitry produces a digital output representing the offset of the voltage-to-delay conversion. The calibration controller circuitry adjusts the reference input common mode voltage responsive to the digital output. Advantageously, the difference between the digital output and the target common mode offset represents an offset correction value. Advantageously, adjusting the reference input common mode voltage by the offset correction value reduces the offset of the voltage-to-delay conversion. Advantageously, reducing the offset of the voltage-to-delay conversion increases the CMRR of the ADC circuitry.

In gain calibration operations, the calibration controller circuitry disables the first amplifier circuitry and sets the plus and minus DAC signals to a relatively high differential voltage. The calibration controller circuitry adjusts the common mode voltage of the plus and minus DAC signals to determine a common mode voltage with the largest gain. The calibration controller circuitry adjusts the gain of the calibration controller circuitry to compensate for the largest determined gain. Advantageously, the gain of the calibration circuitry may be set to cancel out the common mode gain of the amplifier circuitry and the V2D circuitry. Advantageously, adjusting the gain of the calibration circuitry reduces the common mode gain of the voltage-to-delay conversion. Advantageously, reducing the common mode gain of the voltage-to-delay conversion increases the CMRR of the ADC circuitry.

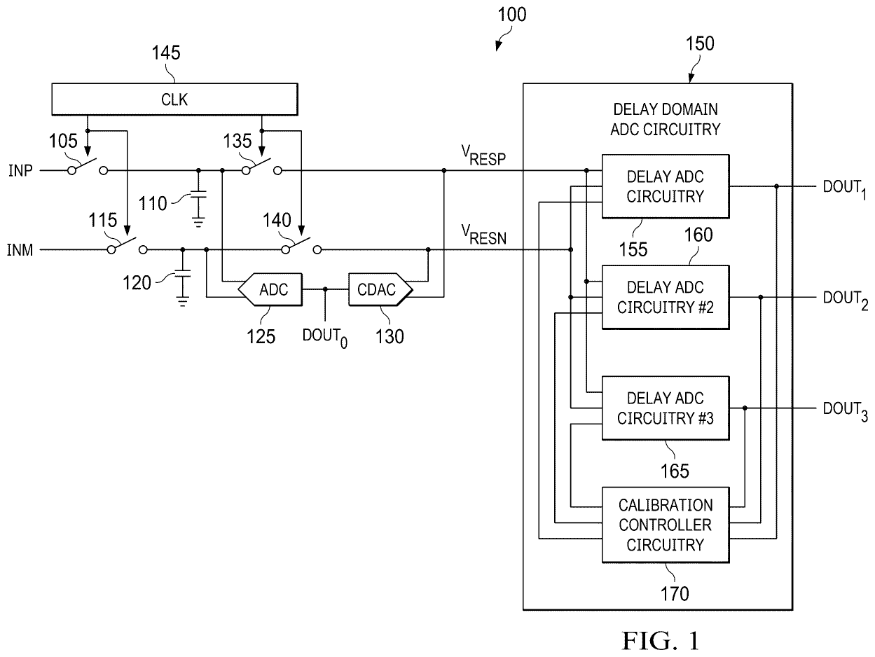

FIG. 1 is a block and schematic diagram of example ADC circuitry 100. In the example of FIG. 1, the ADC circuitry 100 includes a first switch 105, a first capacitor 110, a second switch 115, a second capacitor 120, an ADC 125, a capacitor digital-to-analog converter (CDAC) 130, a third switch 135, a fourth switch 140, example clock circuitry 145, and example delay domain ADC circuitry 150. The example delay domain ADC circuitry 150 of FIG. 1 includes first example delay ADC circuitry 155, second example delay ADC circuitry 160, third example delay ADC circuitry 165, and example calibration controller circuitry 170.

The ADC circuitry 100 has a first input, a second input, a first output, a second output, a third output, and a fourth output. The first and second inputs of the ADC circuitry 100 are structured to be coupled to external circuitry, which supplies plus and minus input signals (INP, INM). In the example of FIG. 1, the plus and minus input signals form a differential pair of input signals having an analog value equal to the difference between the first and second inputs. The first, second, third, and fourth outputs of the ADC circuitry 100 are structured to be coupled to external circuitry, which receive first, second, third, and fourth digital values (DOUT₀, DOUT₁, DOUT₂, DOUT₃).

The switch 105 has a first terminal, a second terminal, and a control terminal. The first terminal of the switch 105 is coupled to the first input of the ADC circuitry 100, which supplies the plus side input signal. The second terminal of the switch 105 is coupled to the first capacitor 110, the ADC 125, and the switch 135. The control terminal of the switch 105 is coupled to the switch 115 and the clock circuitry 145.

The capacitor 110 has a first terminal and a second terminal. The first terminal of the capacitor 110 is coupled to the switches 105, 135 and the ADC 125. The second terminal of the capacitor 110 is coupled to a common terminal, which supplies a common potential.

The switch 115 has a first terminal, a second terminal, and a control terminal. The first terminal of the switch 115 is coupled to the second input of the ADC circuitry 100, which supplies the minus side input signal. The second terminal of the switch 115 is coupled to the capacitor 120, the ADC 125, and the switch 140. The control terminal of the switch 115 is coupled to the control terminal of switch 105 and the clock circuitry 145.

The capacitor 120 has a first terminal and a second terminal. The first terminal of the capacitor 120 is coupled to the switches 115, 140 and the ADC 125. The second terminal of the capacitor 120 is coupled to the common terminal, which supplies the common potential.

The ADC 125 has a first input, a second input, and an output. The first input of the ADC 125 is coupled to the switches 105, 135 and the capacitor 110. The second input of the ADC 125 is coupled to the switches 115, 140 and the capacitor 120. The output of the ADC 125 is coupled to the CDAC 130 and the first output of the ADC circuitry 100.

The CDAC 130 has an input, a first output, and a second output. The input of the CDAC 130 is coupled to the ADC 125. The first output of the CDAC 130 is coupled to the switch 135 and the delay domain ADC circuitry 150. The second output of the CDAC 130 is coupled to the switch 140 and the delay domain ADC circuitry 150.

The switch 135 has a first terminal, a second terminal, and a control terminal. The first terminal of the switch 135 is coupled to the switch 105, the capacitor 110, and the ADC 125. The second terminal of the switch 135 is coupled to the CDAC 130 and the delay domain ADC circuitry 150. The control terminal of the switch 135 is coupled to the control terminal of the switch 140 and the clock circuitry 145.

The switch 140 has a first terminal, a second terminal, and a control terminal. The first terminal of the switch 140 is coupled to the switch 115, the capacitor 120, and the ADC 125. The second terminal of the switch 140 is coupled to the CDAC 130 and the delay domain ADC circuitry 150. The control terminal of the switch 140 is coupled to the control terminal of the switch 135 and the clock circuitry 145. In some examples, the switches 105, 115, 135, 140 are implemented as transistors or alternative switch circuitry. Also, in some examples, the switches 105, 115, 135, 140 are illustrated or described as sample and hold circuitry.

The clock circuitry 145 has a first output and a second output. The first output of the clock circuitry 145 is coupled to the control terminals of the switches 105, 115. The second output of the clock circuitry 145 is coupled to the control terminal of the switches 135, 140.

The delay domain ADC circuitry 150 has a first input, a second input, a first output, a second output, and a third output. The first input of the delay domain ADC circuitry 150 is coupled to the CDAC 130 and the switch 135. The second input of the delay domain ADC circuitry 150 is coupled to the CDAC 130 and the switch 140. The first and second inputs of the delay domain ADC circuitry 150 respectively receive a plus residue voltage (V_{RESP}) and a minus residue voltage (V_{RESM}). The first, second, and third outputs of the delay domain ADC circuitry 150 are coupled to the second, third, and fourth outputs of the delay domain ADC circuitry 150 (DOUT₁, DOUT₂, DOUT₃). The first, second, and third outputs of the delay domain ADC circuitry 150 provide the digital values.

The delay ADC circuitry 155 has a first input, a second input, a third input, and an output. The first input of the delay ADC circuitry 155 is coupled to the delay ADC circuitry 160, 165 and the first input of the delay domain ADC circuitry 150 (V_{RESP}). The second input of the delay ADC circuitry 155 is coupled to the delay ADC circuitry 160, 165 and the second input of the delay domain ADC circuitry 150 (V_{RESM}). The third input of the delay ADC circuitry 155 is coupled to the calibration controller circuitry 170.

The delay ADC circuitry 160 has a first input, a second input, a third input, and an output. The first input of the delay ADC circuitry 160 is coupled to the delay ADC circuitry 155, 165 and the first input of the delay domain ADC circuitry 150 (V_{RESP}). The second input of the delay ADC circuitry 160 is coupled to the delay ADC circuitry 155, 165 and the second input of the delay domain ADC circuitry 150 (V_{RESM}). The third input of the delay ADC circuitry 160 is coupled to the calibration controller circuitry 170.

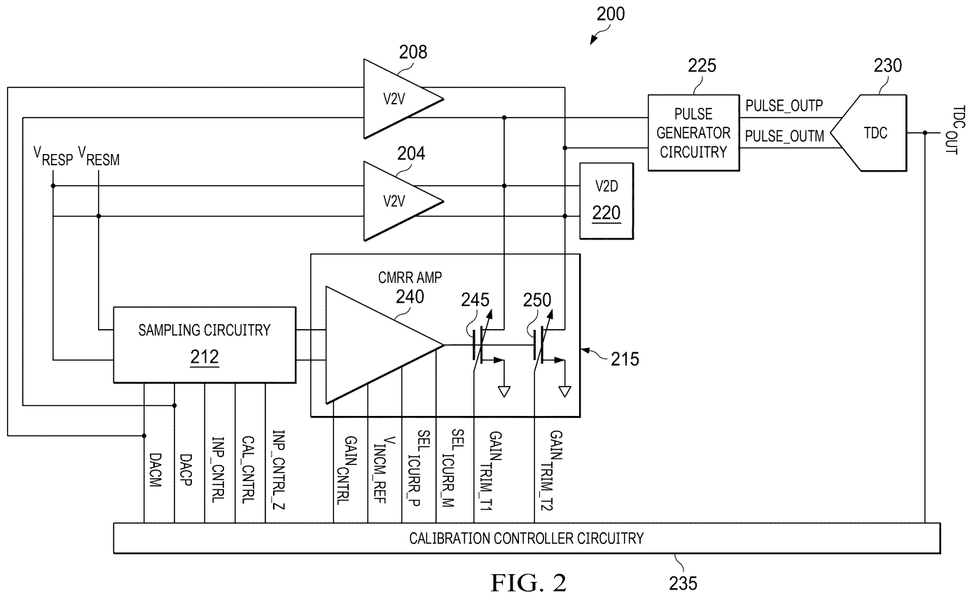

The delay ADC circuitry 165 has a first input, a second input, a third input, and an output. The first input of the delay ADC circuitry 165 is coupled to the delay ADC circuitry 155, 160 and the first input of the delay domain ADC circuitry 150 (V_{RESP}). The second input of the delay ADC circuitry 165 is coupled to the delay ADC circuitry 155, 160 and the second input of the delay domain ADC circuitry 150 (V_{RESM}). The third input of the delay ADC circuitry 165 is coupled to the calibration controller circuitry 170. Examples of the delay ADC circuitry 155, 160, 165 are further illustrated and described in connection with FIGS. 2, 4, and 6.

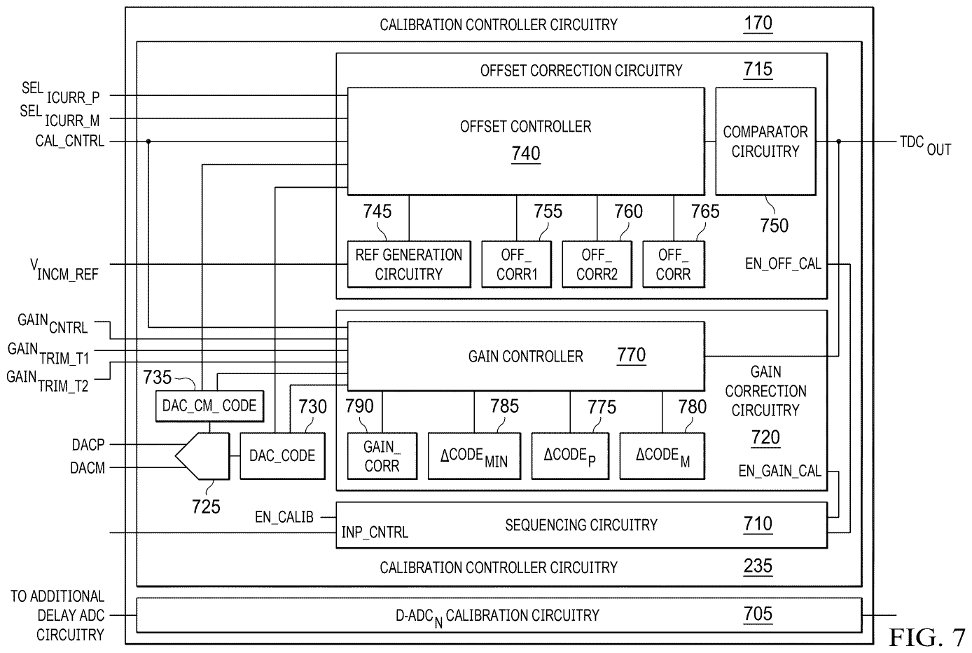

The calibration controller circuitry 170 has a first input, a second input, a third input, a first output, a second output, and a third output. The first input of the calibration controller circuitry 170 is coupled to the delay ADC circuitry 155 and the second output of the ADC circuitry 100. The second input of the calibration controller circuitry 170 is coupled to the delay ADC circuitry 160 and the third output of the ADC circuitry 100. The third input of the calibration controller circuitry 170 is coupled to the delay ADC circuitry 165 and the fourth output of the ADC circuitry 100. An example of the calibration controller circuitry 170 is further illustrated and described in connection with FIG. 7.

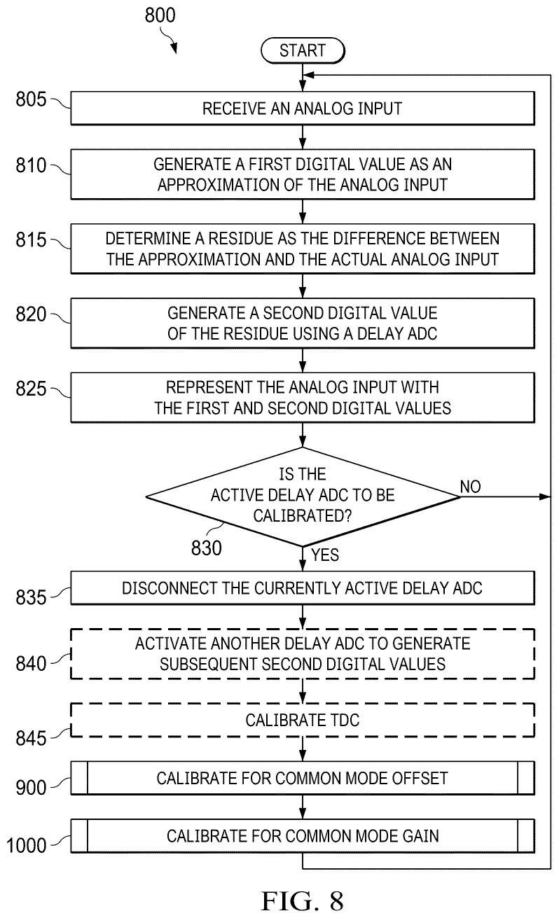

In example operations, the clock circuitry 145 closes the switches 105, 115 for a first period and opens the switches 135, 140. During the first period, plus and minus input signals charge the capacitors 110, 120. During a second period, the clock circuitry 145 opens the switches 105, 115 and closes the switches 135, 140. Also, the ADC 125 generates the first digital value (DOUT₀) responsive to the analog voltages of the capacitors 110, 120. In such example operations, the CDAC 130 converts the first digital value into an analog approximation of the analog voltages of the capacitors 110, 120. The CDAC 130 generates plus and minus residue voltages by subtracting the approximation of the analog value of the capacitors 110, 120 from the actual analog values of the capacitors 110, 120. Example operations of the switches 105, 115, 135, 140, the capacitors 110, 120, the ADC 125, the CDAC 130, and the clock circuitry 145 (also referred to as a first stage) are further illustrated and described in connection with FIG. 8.

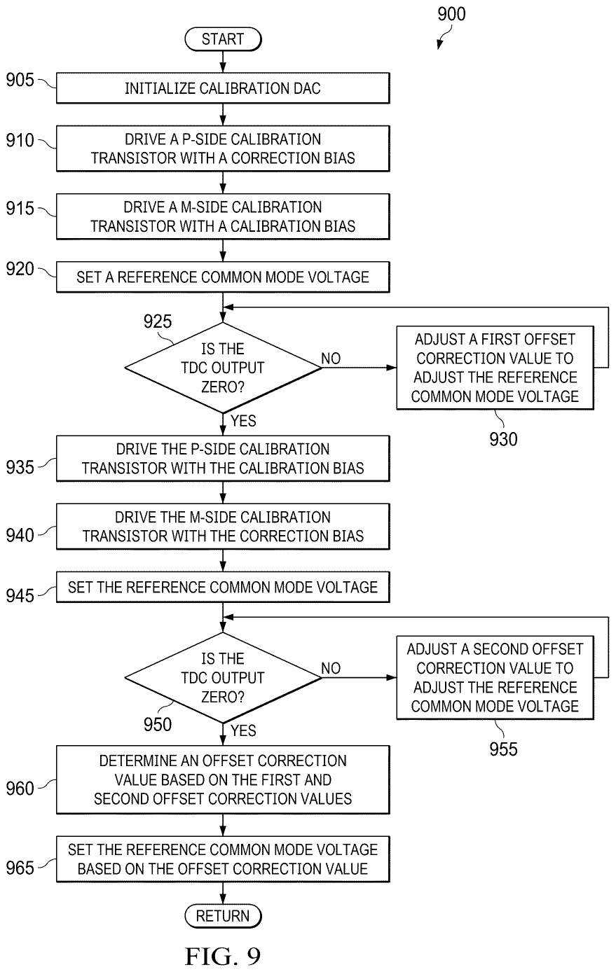

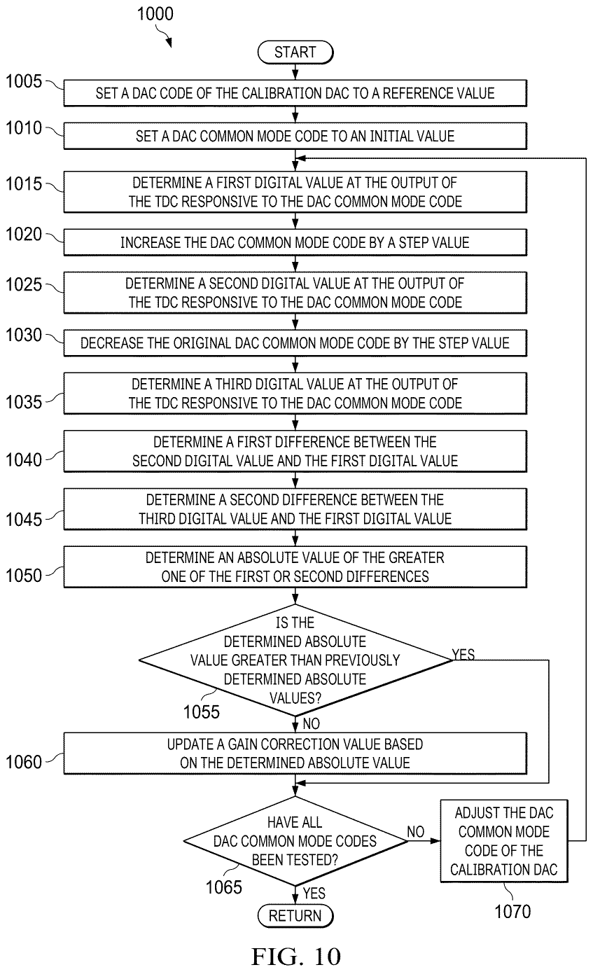

In example operations, the delay domain ADC circuitry 150 receives the plus and minus residue voltages from the CDAC 130. The calibration controller circuitry 170 activates at least one of the delay ADC circuitry 155, 160, 165. The calibration controller circuitry 170 performs calibration operations on the inactive one(s) of the delay ADC circuitry 155, 160, 165. Example operations of the calibration controller circuitry 170 are further illustrated and described in connection with FIGS. 9 and 10. Once calibrated, the calibration controller circuitry 170 activates the one(s) of the delay ADC circuitry 155, 160, 165. In some examples, the calibration controller circuitry 170 periodically calibrates the delay ADC circuitry 155, 160, 165. Advantageously, the ADC circuitry 100 continues to produce digital values during the calibration of one or more of the delay ADC circuitry 155, 160, 165. Advantageously, calibrating the delay ADC circuitry 155, 160, 165 improves the CMRR of the ADC circuitry 100.

FIG. 2 is a block and schematic diagram of delay ADC circuitry 200, which is an example of the delay ADC circuitry 155, 160, 165 of FIG. 1. In the example of FIG. 2, the delay ADC circuitry 200 includes first amplifier circuitry 204, second amplifier circuitry 208, sampling circuitry 212, calibration circuitry 215, voltage-to-delay (V2D) circuitry 220, pulse generator circuitry 225, and example time-to-digital converter (TDC) circuitry 230. In some examples, such as in FIG. 2, the delay ADC circuitry 200 also includes example calibration controller circuitry 235, which is an example of the calibration controller circuitry 170 of FIG. 1. In other examples, such as in FIG. 1, the calibration controller circuitry 235 may be external to the delay ADC circuitry 200. The example calibration circuitry 215 of FIG. 2 includes example amplifier circuitry 240, a first example transistor 245, and a second example transistor 250.

The delay ADC circuitry 200 has a first input, a second input, and an output. The first input of the delay ADC circuitry 200 is structured to be coupled to the CDAC 130 of FIG. 1 and the switch 135 of FIG. 1. The first input of the delay ADC circuitry 200 receives the plus residue voltage (V_{RESP}). The second input of the delay ADC circuitry 200 is structured to be coupled to the CDAC 130 and the switch 140 of FIG. 1. The second input of the delay ADC circuitry 200 receives the minus residue voltage (V_{RESM}). The output of the delay ADC circuitry 200 is structured to be coupled to the external circuitry. The output of the delay ADC circuitry 200 provides a digital output (DOUT).

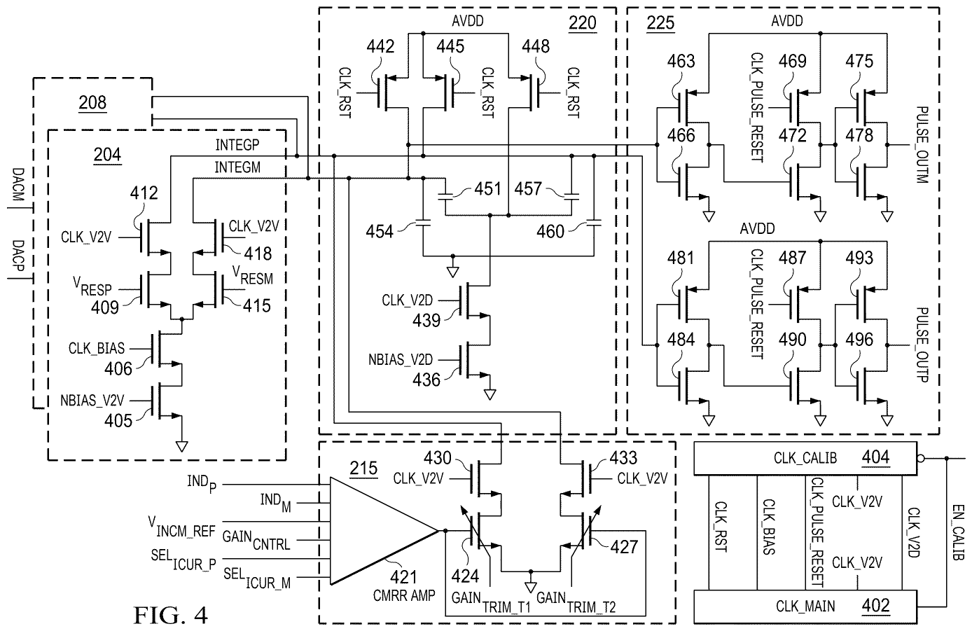

The amplifier circuitry 204 has a first terminal, a second terminal, a third terminal, and a fourth terminal. The first terminal of the amplifier circuitry 204 is coupled to the sampling circuitry 212 and the first input of the delay ADC circuitry 200 (V_{RESP}). The second terminal of the amplifier circuitry 204 is coupled to the sampling circuitry 212 and the second input of the delay ADC circuitry 200 (V_{RESM}). The third and fourth terminals of the amplifier circuitry 204 are coupled to the amplifier circuitry 208, the calibration circuitry 215, the V2D circuitry 220, and the pulse generator circuitry 225. In some examples, the amplifier circuitry 204 is referred to as voltage-to-voltage (V2V) circuitry. Also, as illustrated in FIG. 4, the amplifier circuitry 204 may include clock inputs, which control the amplifier circuitry 204. An example of the amplifier circuitry 204 is illustrated and described in FIG. 4.

The amplifier circuitry 208 has a first terminal, a second terminal, a third terminal, and a fourth terminal. The first and second terminals of the amplifier circuitry 208 are coupled to the sampling circuitry 212 and the calibration controller circuitry 235. The first and second terminals of the amplifier circuitry 208 respectively receive plus and minus DAC signals (DACP, DACM) from the calibration controller circuitry 235. The plus and minus DAC signals are a differential pair of analog signals that allow the calibration controller circuitry 235 to control the input of the amplifier circuitry 208, 240. The third and fourth terminals of the amplifier circuitry 208 are coupled to the amplifier circuitry 204, the calibration circuitry 215, the V2D circuitry 220, and the pulse generator circuitry 225. In some examples, the amplifier circuitry 208 is referred to as voltage-to-voltage (V2V) circuitry. However, unlike the amplifier circuitry 204, the amplifier circuitry 208 is structured for calibration operations, which are illustrated and described in connection with FIGS. 9, 10, and 11. Alternatively, in some examples, the amplifier circuitry 208 may be replaced with sampling circuitry, such as the sampling circuitry 212. In such alternative examples, the additional components between the inputs of the delay ADC circuitry 200 and the amplifier circuitry 204 increase noise.

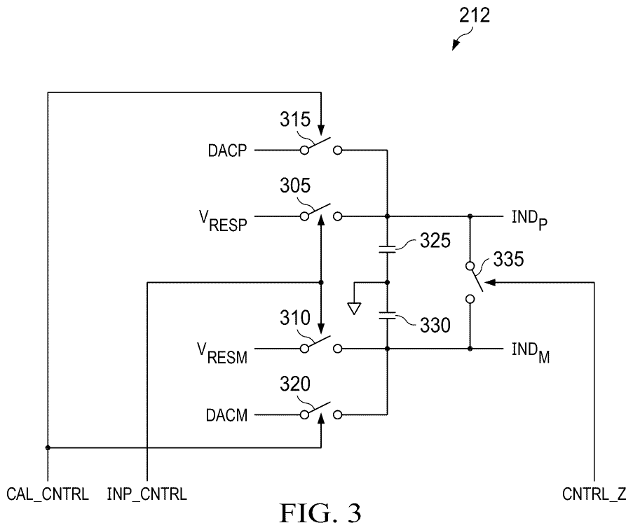

The sampling circuitry 212 has a first terminal, a second terminal, a third terminal, a fourth terminal, a fifth terminal, a sixth terminal, a seventh terminal, an eighth terminal, and a ninth terminal. The first terminal of the sampling circuitry 212 is coupled to the amplifier circuitry 204 and the first input of the delay ADC circuitry 200 (V_{RESP}). The second terminal of the sampling circuitry 212 is coupled to the amplifier circuitry 204 and the second input of the delay ADC circuitry 200 (V_{RESM}). The third and fourth terminals of the sampling circuitry 212 are coupled to the amplifier circuitry 208 and the calibration controller circuitry 235. The fifth, sixth, and seventh terminals of the sampling circuitry 212 are coupled to the calibration controller circuitry 235. The eighth and ninth terminals of the sampling circuitry 212 are coupled to the calibration circuitry 215. An example of the sampling circuitry 212 is further illustrated and described in connection with FIG. 3.

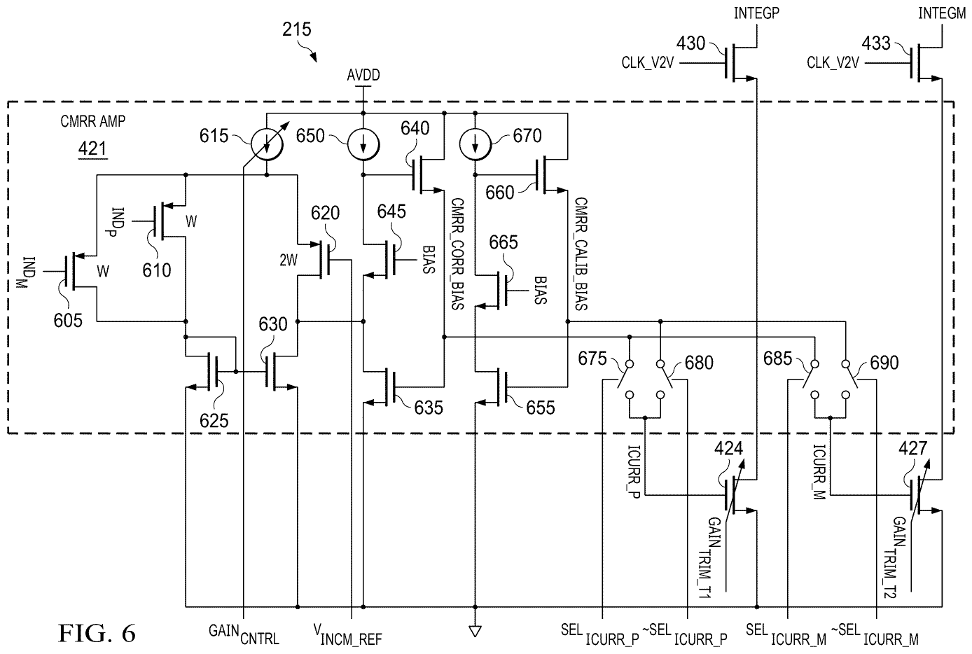

The calibration circuitry 215 (also referred to as correction circuitry) has a first terminal, a second terminal, a third terminal, a fourth terminal, a fifth terminal, a sixth terminal, a seventh terminal, an eighth terminal, a ninth terminal, and a tenth terminal. The first and second terminals of the calibration circuitry 215 are coupled to the sampling circuitry 212. The third and fourth terminals of the calibration circuitry 215 are coupled to the amplifier circuitry 204, 208, the V2D circuitry 220, and the pulse generator circuitry 225. The fifth, sixth, seventh, eighth, ninth, tenth terminals of the calibration circuitry 215 are coupled to the calibration controller circuitry 235. Examples of the calibration circuitry 215 are further illustrated and described in connection with FIGS. 4 and 6.

The V2D circuitry 220 has a first terminal and a second terminal. The first and second terminals of the V2D circuitry 220 are coupled to the amplifier circuitry 204, 208, the calibration circuitry 215, and the pulse generator circuitry 225. An example of the V2D circuitry 220 is further illustrated and described in connection with FIG. 4.

The pulse generator circuitry 225 has a first terminal, a second terminal, a third terminal, and a fourth terminal. The first and second terminals of the pulse generator circuitry 225 are coupled to the amplifier circuitry 204, 208, the calibration circuitry 215, and the V2D circuitry 220. The third and fourth terminals of the pulse generator circuitry 225 are coupled to the TDC circuitry 230. An example of the pulse generator circuitry 225 is further illustrated and described in connection with FIG. 4.

The TDC circuitry 230 has a first input, a second input, and an output. The first and second inputs of the TDC circuitry 230 are coupled to the pulse generator circuitry 225. The pulse generator circuitry 225 provides plus and minus delay signals (PULSE_OUTP, PULSE_OUTM) at the inputs of the TDC circuitry 230. A delay between edges of the plus and minus delay signals is proportional to the difference between the plus and minus residue voltages (V_{RESP}, V_{RESM}) at the inputs of the delay ADC circuitry 200. The output of the TDC circuitry 230 is coupled to the calibration controller circuitry 235 and the output of the delay ADC circuitry 200. The TDC circuitry 230 provides a digital value (TDC_{OUT}) representing the delay of the plus and minus delay signals and the analog voltage at the inputs of the delay ADC circuitry 200.

The calibration controller circuitry 235 has an input, a first output, a second output, a third output, a fourth output, a fifth output, a sixth output, a seventh output, an eighth output, a ninth output, a tenth output, and an eleventh output. The input of the calibration controller circuitry 235 is coupled to the TDC circuitry 230 and the output of the delay ADC circuitry 200 (TDC_{OUT}). The first and second outputs of the calibration controller circuitry 235 are coupled to the amplifier circuitry 208 and the sampling circuitry 212. The third, fourth, and fifth outputs of the calibration controller circuitry 235 are coupled to the sampling circuitry 212. The sixth, seventh, eighth, and ninth outputs of the calibration controller circuitry 235 are coupled to the amplifier circuitry 240, or more generally the calibration circuitry 215. The tenth and eleventh outputs of the calibration controller circuitry 235 are respectively coupled to the transistors 245, 250, or more generally the calibration circuitry 215. An example of the calibration controller circuitry 235 is further illustrated and described in connection with FIG. 7.

The amplifier circuitry 240 has a first terminal, a second terminal, a third terminal, a fourth terminal, a fifth terminal, a sixth terminal, and a seventh terminal. The first and second terminals of the amplifier circuitry 240 are coupled to the sampling circuitry 212. The third, fourth, fifth, and sixth terminals of the amplifier circuitry 240 are coupled to the calibration controller circuitry 235. The seventh terminal of the amplifier circuitry 240 is coupled to the transistors 245, 250. In some examples, the amplifier circuitry 240 is referred to as a common mode rejection ratio (CMRR) amplifier. An example of the amplifier circuitry 240 is further illustrated and described in connection with FIG. 6.

The transistor 245 has a first terminal, a second terminal, a control terminal, and a trim input. The first terminal of the transistor 245 is coupled to the amplifier circuitry 204, 208, the V2D circuitry 220, and the pulse generator circuitry 225. The second terminal of the transistor 245 is coupled to a common terminal, which supplies a common potential (e.g., ground, AVSS, etc.). The control terminal of the transistor 245 is coupled to the amplifier circuitry 240 and the control terminal of the transistor 250. The trim input of the transistor 245 is coupled to the calibration controller circuitry 235. The calibration controller circuitry 235 provides a first gain trim value (GAIN_{TRIM_T1}) at the trim input of the transistor 245. The first gain trim value controls the size of the transistor 245 by setting at least one of the channel length or width.

The transistor 250 has a first terminal, a second terminal, a control terminal, and a trim input. The first terminal of the transistor 250 is coupled to the amplifier circuitry 204, 208, the V2D circuitry 220, and the pulse generator circuitry 225. The second terminal of the transistor 250 is coupled to the common terminal, which supplies the common potential. The control terminal of the transistor 250 is coupled to the amplifier circuitry 240 and the control terminal of the transistor 245. The trim input of the transistor 250 is coupled to the calibration controller circuitry 235. The calibration controller circuitry 235 provides a second gain trim value (GAIN_{TRIM_T2}) at the trim input of the transistor 250. The second gain trim value controls the size of the transistor 250 by setting at least one of the channel length or width.

In the example of FIG. 2, the transistors 245, 250 are n-channel metal-oxide semiconductor field-effect transistors (MOSFETs). Alternatively, the transistors 245, 250 may be n-channel field-effect transistors (FETs), n-channel insulated-gate bipolar transistors (IGBTs), n-channel junction field effect transistors (JFETs), NPN bipolar junction transistors (BJTs) or, with slight modifications, p-type equivalent devices. The transistors 245, 250 may be depletion mode devices, drain-extended devices, enhancement mode devices, natural transistors or other type of device structure transistors. Furthermore, the transistors 245, 250 may be implemented in/over a silicon substrate (Si), a silicon carbide substrate (SiC), a gallium nitride substrate (GaN) or a gallium arsenide substrate (GaAs).

In example non-calibration operations (also referred to as normal operations), the amplifier circuitry 204 is active, the amplifier circuitry 208 is inactive, and the sampling circuitry 212 provides the plus and minus residue voltages to the calibration circuitry 215. In some examples, such as FIGS. 3, 4, and 7, the calibration controller circuitry 235 controls the sampling circuitry 212 using an input control signal (INP_CNTRL), an inverted input control signal (INP_CNTRL_Z), and a calibration control signal (CAL_CNTRL). Examples of the input control signal (INP_CNTRL), the inverted input control signal (INP_CNTRL_Z), and the calibration control signal (CAL_CNTRL) are further described in connection with FIG. 3.

In such example non-calibration operations, the amplifier circuitry 240 compares the common mode voltage of the plus and minus residue voltages to a reference input common mode voltage (V_{INCM_REF}) from the calibration controller circuitry 235. The transistors 245, 250 sink current from the V2D circuitry 220 responsive to the comparison of the amplifier circuitry 240. The pulse generator circuitry 225 generates the plus and minus delay signals (PULSE_OUTP, PULSE_OUTM) responsive to the voltages of the V2D circuitry 220. Example operations of transistors 245, 250 are further illustrated and described in connection with FIGS. 4, 6, 8. Also, example operations of the amplifier circuitry 204, the V2D circuitry 220, and the pulse generator circuitry 225 are further illustrated and described in “VOLTAGE-TO-DELAY CONVERTER” U.S. patent application Ser. No. 18/498,358, which is incorporated by reference in its entirety and is assigned to the assignee of the instant application. The TDC circuitry 230 produces the digital value (TDC_{OUT}) responsive to the delay between the plus and minus delay signals. Advantageously, sinking currents from the amplifier circuitry 204, 208 and the V2D circuitry 220 compensate for at least one of the offset or gain of the amplifier circuitry 204 and the V2D circuitry 220. Advantageously, the calibration circuitry 215 improves the CMRR of the delay ADC circuitry 200. Example operations of the amplifier circuitry 204, the V2D circuitry 220, and the pulse generator circuitry 225 are further illustrated and described in connection with FIGS. 4, 6, and 8.

In example calibration operations, the amplifier circuitry 204 is inactive, the amplifier circuitry 208 is active, and the sampling circuitry 212 provides the plus and minus DAC signals (DACP, DACM) to the calibration circuitry 215. In some examples, such as FIGS. 3, 4, and 7, the calibration controller circuitry 235 controls the sampling circuitry 212 using the input control signal (INP_CNTRL), the inverted input control signal (INP_CNTRL_Z), and the calibration control signal (CAL_CNTRL).

In such example calibration operations, the calibration controller circuitry 235 calibrates the offset of the delay ADC circuitry 200 using the plus and minus DAC signals (DACP, DACM), a plus bias current select signal (SEL_{ICUR_P}), and a minus bias current select signal (SEL_{ICUR_M}), and the reference input common mode voltage (V_{INCM_REF}). Examples of the plus and minus bias current select signals are further illustrated and described in connection with FIGS. 6 and 7. Example offset calibration operations are further illustrated and described in connection with FIG. 9. Advantageously, the calibration controller circuitry 235 may reduce the offset of the delay ADC circuitry 200 responsive to adjusting the reference input common mode voltage (V_{INCM_REF}).

Also, in such example calibration operations, the calibration controller circuitry 235 calibrates the gain of the delay ADC circuitry 200 using the plus and minus DAC signals (DACP, DACM), a gain control signal (GAIN_{CNTRL}), and the first and second gain trim values (GAIN_{TRIM_T1}, GAIN_{TRIM_T2}). Examples of the gain control signal and the gain trim values are further described in connection with FIGS. 6 and 7. Example gain calibration operations are further illustrated and described in connection with FIG. 10. Advantageously, the calibration controller circuitry 235 may reduce the gain of the delay ADC circuitry 200 responsive to adjusting the gain of the calibration circuitry 215. Advantageously, the offset and gain calibration operations improve the accuracy of the calibration circuitry 215.

FIG. 3 is a schematic diagram of an example of the sampling circuitry 212 of FIG. 2. The example sampling circuitry 212 of FIG. 3 includes a first example switch 305, a second example switch 310, a third example switch 315, a fourth example switch 320, a first example capacitor 325, a second example capacitor 330, and a fifth example switch 335. The sampling circuitry 212 has a first input, a second input, a third input, a fourth input, a fifth input, a sixth input, a seventh input, a first output, and a second output. The first input of the sampling circuitry 212 is structured to be coupled to the CDAC 130 of FIG. 1 and the switch 135 of FIG. 1. The second input of the sampling circuitry 212 is structured to be coupled to the CDAC 130 and the switch 140 of FIG. 1. The first and second inputs of the sampling circuitry 212 respectively receive the plus residue voltage (V_{RESP}) and the minus residue voltage (V_{RESM}). The third, fourth, fifth, sixth, and seventh inputs of the sampling circuitry 212 are structured to be coupled to the calibration controller circuitry 170, 235 of FIGS. 1 and 2 respectively. The third, fourth, fifth, sixth, and seventh inputs of the sampling circuitry 212 respectively receive an input control signal (INP_CNTRL), an inverted input control signal (INP_CNTRL_Z), plus and minus DAC signals (DACP, DACM), and a calibration control signal (CAL_CNTRL). The first and second outputs of the sampling circuitry 212 are structured to be coupled to the calibration circuitry 215 of FIG. 2. The first and second outputs of the sampling circuitry 212 provide plus and minus inputs signals (IND_{P}, IND_{M}).

The switch 305 has a first terminal, a second terminal, and a control terminal. The first terminal of the switch 305 is coupled to the first input of the sampling circuitry 212 (V_{RESP}). The second terminal of the switch 305 is coupled to the switches 315, 335, the capacitor 325, and the first output of the sampling circuitry 212. The control terminal of the switch 305 is coupled to the control terminal of the switch 310 and the third input of the sampling circuitry 212 (INP_CNTRL).

The switch 310 has a first terminal, a second terminal, and a control terminal. The first terminal of the switch 310 is coupled to the second input of the sampling circuitry 212 (V_{RESM}). The second terminal of the switch 310 is coupled to the switches 320, 335, the capacitor 330, and the second output of the sampling circuitry 212. The control terminal of the switch 310 is coupled to the control terminal of the switch 305 and the third input of the sampling circuitry 212 (INP_CNTRL).

The switch 315 has a first terminal, a second terminal, and a control terminal. The first terminal of the switch 315 is coupled to the fourth input of the sampling circuitry 212 (DACP). The second terminal of the switch 315 is coupled to the switches 305, 335, the capacitor 325, and the first output of the sampling circuitry 212. The control terminal of the switch 315 is coupled to the control terminal of the switch 320 and the sixth input of the sampling circuitry 212 (CAL_CNTRL).

The switch 320 has a first terminal, a second terminal, and a control terminal. The first terminal of the switch 320 is coupled to the fifth input of the sampling circuitry 212 (DACM). The second terminal of the switch 320 is coupled to the switches 310, 335, the capacitor 330, and the second output of the sampling circuitry 212. The control terminal of the switch 320 is coupled to the control terminal of the switch 315 and the sixth input of the sampling circuitry 212 (CAL_CNTRL).

The capacitor 325 has a first terminal and a second terminal. The first terminal of the capacitor 325 is coupled to the switches 305, 315, 335 and the first output of the sampling circuitry 212. The second terminal of the capacitor 325 is coupled to the common terminal, which supplies the common potential.

The capacitor 330 has a first terminal and a second terminal. The first terminal of the capacitor 330 is couped to the switches 310, 320, 335 and the second output of the sampling circuitry 212. The second terminal of the capacitor 330 is coupled to the common terminal, which supplies the common potential.

The switch 335 has a first terminal, a second terminal, and a control terminal. The first terminal of the switch 335 is coupled to the switches 305, 315, the capacitor 325, and the first output of the sampling circuitry 212. The second terminal of the switch 335 is coupled to the switches 310, 320, the capacitor 330, and the second output of the sampling circuitry 212. The control terminal of the switch 335 is coupled to the seventh input of the sampling circuitry 212 (INP_CNTRL_Z).

In example non-calibration operations, the calibration control signal (CAL_CNTRL) opens the switches 315, 320. Also, the input control signal (INP_CNTRL) periodically closes the switches 305, 310. The plus and minus residue voltages (VRESP and VRESM) charge the capacitors 325, 330 responsive to the switches 305, 310 closing. During a second portion of the period, the input control signal (INP_CNTRL) opens the switches 305, 310 and the inverted input control signal (INP_CNTRL_Z) closes the switch 335. During the second portion of the period, the switch shorts the capacitors 325, 330 to set the plus and minus input signals (IND_{P}, IND_{M}) at the outputs of the sampling circuitry 212 to the common mode voltage of the plus and minus residue voltages. Advantageously, during non-calibration operations, the sampling circuitry 212 provides the plus and minus residue voltages to the calibration circuitry 215.

In example calibration operations, the input control signal (INP_CNTRL) opens the switches 305, 310 and the calibration control signal (CAL_CNTRL) closes the switches 315, 320. The plus and minus DAC signals charge the capacitors 325, 330 responsive to the switches 315, 320 closing. In some examples, similar to during non-calibration operations, periodically closing the switch 335 sets the plus and minus input signals (IND_{P}, IND_{M}) at the outputs of the sampling circuitry 212 to the common mode voltage of the plus and minus DAC signals. Advantageously, during calibration operations, the sampling circuitry 212 provides the plus and minus DAC signals (DACP, DACM) to the calibration circuitry 215. Example operations of the sampling circuitry 212 are further described in connection with FIG. 8.

FIG. 4 is a schematic diagram of examples of the amplifier circuitry 204 of FIG. 2, the calibration circuitry 215 of FIG. 2, the V2D circuitry 220 of FIG. 2, the pulse generator circuitry 225 of FIG. 2, example main clock circuitry 402, and example calibration clock circuitry 404. The example amplifier circuitry 204 of FIG. 4 includes a first example transistor 405, a second example transistor 406, a third example transistor 409, a fourth example transistor 412, a fifth example transistor 415, and a sixth example transistor 418. Although in the example of FIG. 4, the amplifier circuitry 208 is not illustrated schematically, the amplifier circuitry 204, 208, in one example, are structurally similar. The example calibration circuitry 215 of FIG. 4 includes example amplifier circuitry 421 (CMRR amplifier), a first example transistor 424, a second example transistor 427, a third example transistor 430, and a fourth example transistor 433. The example V2D circuitry 220 of FIG. 4 includes a first example transistor 436, a second example transistor 439, a third example transistor 442, a fourth example transistor 445, a fifth example transistor 448, a first example capacitor 451, a second example capacitor 454, a third example capacitor 457, and a fourth example capacitor 460. The example pulse generator circuitry 225 of FIG. 4 includes a first example transistor 463, a second example transistor 466, a third example transistor 469, a fourth example transistor 472, a fifth example transistor 475, a sixth example transistor 478, a seventh example transistor 481, an eighth example transistor 484, a ninth example transistor 487, a tenth example transistor 490, an eleventh example transistor 493, and a twelfth example transistor 496.

The amplifier circuitry 204 has a first input, a second input, a third input, a fourth input, a first output, and a second output. The first and second inputs of the amplifier circuitry 204 are coupled to the first and second inputs of the delay ADC circuitry 200 (V_{RESP}, V_{RESM}). The third and fourth inputs of the amplifier circuitry 204 are coupled to the main clock circuitry 402, which provides a V2V clock signal (CLK_V2V) and a bias clock signal (CLK_BIAS). The first and second outputs of the amplifier circuitry 204 are coupled to the amplifier circuitry 208, the calibration circuitry 215, the V2D circuitry 220, and the pulse generator circuitry 225.

The amplifier circuitry 208 has a first input, a second input, a third input, a fourth input, a first output, and a second output. The first and second inputs of the amplifier circuitry 208 are structured to be coupled to the calibration controller circuitry 235, which provides the plus and minus DAC signals (DACP, DACM). The third and fourth inputs of the amplifier circuitry 208 are coupled to the calibration clock circuitry 404, which provides a V2V clock signal (CLK_V2V) and a bias clock signal (CLK_BIAS). The first and second outputs of the amplifier circuitry 208 are coupled to the amplifier circuitry 204, the calibration circuitry 215, the V2D circuitry 220, and the pulse generator circuitry 225.

In some examples, the clock circuitry 402, 404 control the amplifier circuitry 204, 208 responsive to a control of the supply of the V2V clock signal (CLK_V2V). In some examples, such as in FIG. 4, the clock circuitry 402, 404 are structured to control operations of the amplifier circuitry 204, 208 during one of calibration operations or non-calibration operations. In such examples, the V2V clock signal (CLK_V2V) of the clock circuitry 402 may enable the amplifier circuitry 204 for non-calibration operations and the V2V clock signal (CLK_V2V) of the clock circuitry 404 enables the amplifier circuitry 208 for calibration operations. For example, during calibration operations, the main clock circuitry 402 disables the amplifier circuitry 204 by not supplying the V2V clock signal (CLK_V2V) and the calibration clock circuitry 404 activates the amplifier circuitry 208 by supplying the V2V clock signal (CLK_V2V). In another example, during non-calibration operations, the main clock circuitry 402 activates the amplifier circuitry 204 by supplying the V2V clock signal (CLK_V2V) and the calibration clock circuitry 404 disables the amplifier circuitry 208 by not supplying the V2V clock signal (CLK_V2V). In other examples, the clock circuitry 402, 404 may be partially or fully combined.

The calibration circuitry 215 has a first input, a second input, a third input, a first output, and a second output. The first and second inputs of the calibration circuitry 215 are coupled to the sampling circuitry 212, which provides the plus and minus delay input signals (IND_{P}, IND_{M}). The third input of the calibration circuitry 215 is coupled to the clock circuitry 402, which provides the V2V clock signal (CLK_V2V). The first and second outputs of the calibration circuitry 215 are coupled to the amplifier circuitry 204, the V2D circuitry 220, and the pulse generator circuitry 225. Another example of the calibration circuitry 215 is further illustrated and described in connection with FIG. 6.

The V2D circuitry 220 has a first input, a second input, a third input, and a fourth input. The first and second inputs of the V2D circuitry 220 are coupled to the amplifier circuitry 204, the calibration circuitry 215, and the pulse generator circuitry 225. The third and fourth inputs of the V2D circuitry 220 are coupled to the clock circuitry 402, which provides a reset clock signal (CLK_RESET) and a V2D clock signal (CLK_V2D).

The pulse generator circuitry 225 has a first input, a second input, a third input, a first output, and a second output. The first and second inputs of the pulse generator circuitry 225 are coupled to the amplifier circuitry 204, the calibration circuitry 215, and the V2D circuitry 220. The third input of the pulse generator circuitry 225 is coupled to the clock circuitry 402, which supplies a clock pulse reset signal (CLK_PULSE_RESET). The first and second outputs of the pulse generator circuitry 225 are structured to be coupled to the TDC circuitry 230 of FIG. 2, which receives plus and minus pulses (PULSE_OUTP, PULSE_OUTM).

The main clock circuitry 402 has a first terminal, a second terminal, a third terminal, a fourth terminal, a fifth terminal, and a sixth terminal. The first terminal of the main clock circuitry 402 (CLK_V2V) is coupled to the amplifier circuitry 204 and the calibration circuitry 215. The second terminal of the main clock circuitry 402 (CLK_BIAS) is coupled to the amplifier circuitry 204 and the calibration clock circuitry 404. The third and fourth terminals of the main clock circuitry 402 (CLK_RST, CLK_V2D) are coupled to the V2D circuitry 220 and the calibration clock circuitry 404. The fifth terminal of the main clock circuitry 402 (CLK_PULSE_RESET) is coupled to the pulse generator circuitry 225 and the calibration clock circuitry 404. The sixth terminal of the main clock circuitry 402 (EN_CALIB) is coupled to the calibration clock circuitry 404 and is structured to be coupled to the calibration controller circuitry 235. The calibration controller circuitry 235 provides a calibration enable signal (EN_CALIB) at the sixth terminal of the main clock circuitry 402.

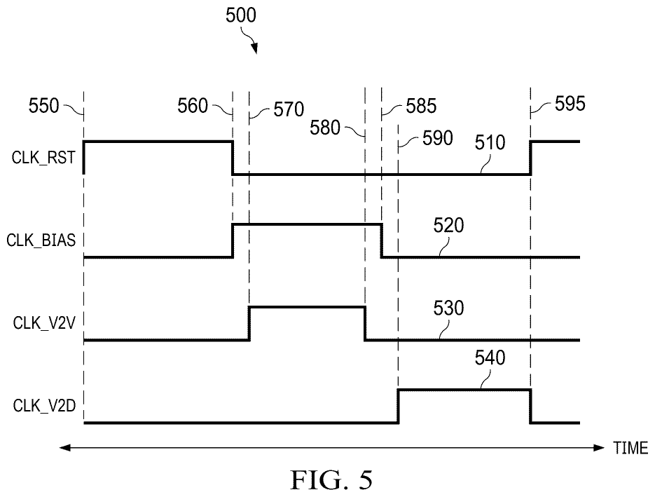

The calibration clock circuitry 404 has a first terminal, a second terminal, a third terminal, a fourth terminal, a fifth terminal, and a sixth terminal. The first terminal of the calibration clock circuitry 404 (CLK_V2V) is coupled to the amplifier circuitry 208 and the calibration circuitry 215. The second terminal of the calibration clock circuitry 404 (CLK_BIAS) is coupled to the amplifier circuitry 204 and the main clock circuitry 402. The third and fourth terminals of the calibration clock circuitry 404 (CLK_RST, CLK_V2D) are coupled to the V2D circuitry 220 and the main clock circuitry 402. The fifth terminal of the calibration clock circuitry 404 (CLK_PULSE_RESET) is coupled to the pulse generator circuitry 225 and the main clock circuitry 402. The sixth terminal of the calibration clock circuitry 404 (EN_CALIB) is coupled to the main clock circuitry 402 and is structured to be coupled to the calibration controller circuitry 235. The calibration controller circuitry 235 provides the calibration enable signal (EN_CALIB) at the sixth terminal of the calibration clock circuitry 404. Example operations of the clock circuitry 402, 404 are illustrated and described in connection with FIG. 5.

The transistor 405 has a first terminal, a second terminal, and a control terminal. The first terminal of the transistor 405 is coupled to the transistor 406. The second terminal of the transistor 405 is coupled to the common terminal, which supplies the common potential. The control terminal of the transistor 405 is coupled to a reference terminal, which supplies a V2V bias voltage (NBIAS_V2V). The V2V bias voltage controls the conduction of current by the transistor 405. In some examples, the V2V bias voltage sets the operating region of the transistor 406 responsive to the transistor 405 pulling down a source voltage of the transistor 405. In some such examples, the V2V bias voltage is a constant voltage.

The transistor 406 has a first terminal, a second terminal, and a control terminal. The first terminal of the transistor 406 is coupled to the transistor 409, 415. The second terminal of the transistor 406 is coupled to the transistor 405. The control terminal of the transistor 406 is coupled to the main clock circuitry 402, which provides the bias clock signal (CLK_BIAS).

The transistor 409 has a first terminal, a second terminal, and a control terminal. The first terminal of the transistor 409 is coupled to the transistor 412. The second terminal of the transistor 409 is coupled to the transistor 406, 415. The control terminal of the transistor 409 is coupled to the first input of the amplifier circuitry 204, which supplies the plus residue voltage (V_{RESP}).

The transistor 412 has a first terminal, a second terminal, and a control terminal. The first terminal of the transistor 412 is coupled to the transistors 430, 445, 481, 484 and the capacitors 457, 460. The second terminal of the transistor 412 is coupled to the transistor 409. The control terminal of the transistor 412 is coupled to the transistors 418, 430, 433 and the main clock circuitry 402, which supplies the V2V clock signal (CLK_V2V).

The transistor 415 has a first terminal, a second terminal, and a control terminal. The first terminal of the transistor 415 is coupled to the transistors 406, 409. The second terminal of the transistor 415 is coupled to the transistor 418. The control terminal of the transistor 415 is coupled to the amplifier circuitry 421 and the second input of the amplifier circuitry 204, which supplies the minus residue voltage (V_{RESM}).

The transistor 418 has a first terminal, a second terminal, and a control terminal. The first terminal of the transistor 418 is coupled to the transistors 433, 442, 463, 466 and the capacitors 451, 454. The second terminal of the transistor 418 is coupled to the transistor 415. The control terminal of the transistor 418 is coupled to the transistors 412, 430, 433 and the main clock circuitry 402, which provides the V2V clock signal (CLK_V2V).

The amplifier circuitry 421 has a first terminal, a second terminal, a third terminal, a fourth terminal, a fifth terminal, a sixth terminal, and a seventh terminal. The first and second terminals of the amplifier circuitry 421 are coupled to the first input of the calibration circuitry 215, which supplies the plus and minus delay input signals (IND_{P}, IND_{M}). The third, fourth, fifth, and sixth terminals of the amplifier circuitry 421 are structured to be coupled to the calibration controller circuitry 235. The calibration control circuitry 235 respectively supplies the reference input common mode voltage (V_{INCM_REF}), the gain control signal (GAIN_{CNTRL}), the plus bias current select signal (SEL_{ICUR_P}), and the minus bias current select signal (SEL_{ICUR_M}) at the third, fourth, fifth, and sixth terminals of the amplifier circuitry 421. The sixth terminal of the amplifier circuitry 421 is coupled to the transistor 424, 427. The amplifier circuitry 421 is an example implementation of the amplifier circuitry 240 of FIG. 2. In some examples, the amplifier circuitry 421 includes additional terminals, which are coupled to the calibration controller circuitry 170, 235. Another example of the amplifier circuitry 240, 421 is further illustrated and described in connection with FIG. 6.

The transistor 424 has a first terminal, a second terminal, a control terminal, and a trim input. The first terminal of the transistor 424 is coupled to the transistor 430. The second terminal of the transistor 424 is coupled to the common terminal, which supplies the common potential. The control terminal of the transistor 424 is coupled to the amplifier circuitry 421 and the transistor 427. The trim input of the transistor 424 is coupled to the calibration controller circuitry 235. The calibration controller circuitry 235 provides the first gain trim value (GAIN_{TRIM_T1}) at the trim input of the transistor 424. The first gain trim value controls the size of the transistor 424 by setting at least one of the channel length or width.

The transistor 427 has a first terminal, a second terminal, a control terminal, and a trim input. The first terminal of the transistor 427 is coupled to the transistor 433. The second terminal of the transistor 427 is coupled to the common terminal, which supplies the common potential. The control terminal of the transistor 427 is coupled to the amplifier circuitry 421 and the transistor 424. The trim input of the transistor 427 is coupled to the calibration controller circuitry 235. The calibration controller circuitry 235 provides the second gain trim value (GAIN_{TRIM_T2}) at the trim input of the transistor 427. The second gain trim value controls the size of the transistor 427 by setting at least one of the channel length or width.

The transistor 430 has a first terminal, a second terminal, and a control terminal. The first terminal of the transistor 430 is coupled to the transistors 412, 481, 484 and the capacitors 457, 460. The second terminal of the transistor 430 is coupled to the transistor 424. The control terminal of the transistor 430 is coupled to the transistors 412, 418, 433 and the clock circuitry 402, 404, which supply the V2V clock signal (CLK_V2V).

The transistor 433 has a first terminal, a second terminal, and a control terminal. The first terminal of the transistor 433 is coupled to the transistors 418, 463, 466 and the capacitors 451, 454. The second terminal of the transistor 433 is coupled to the transistor 427. The control terminal of the transistor 433 is coupled to the transistors 412, 418, 430 and the clock circuitry 402, 404, which supply the V2V clock signal (CLK_V2V).

The transistor 436 has a first terminal, a second terminal, and a control terminal. The first terminal of the transistor 436 is coupled to the transistor 439. The second terminal of the transistor 436 is coupled to the common terminal, which supplies the common potential. The control terminal of the transistor 436 is coupled to a reference terminal, which supplies a V2D bias voltage (NBIAS_V2D). The V2D bias voltage controls the conduction of current by the transistor 436. In some examples, the V2D bias voltage sets the operating region of the transistor 439 responsive to the transistor 436 pulling down a source voltage of the transistor 439. In some such examples, the V2D bias voltage is a constant voltage.

The transistor 439 has a first terminal, a second terminal, and a control terminal. The first terminal of the transistor 439 is coupled to the transistor 448 and the capacitors 451, 457. The second terminal of the transistor 439 is coupled to the transistor 436. The control terminal of the transistor 439 is coupled to the clock circuitry 402, 404, which supplies the V2D clock signal (CLK_V2D).

The transistor 442 has a first terminal, a second terminal, and a control terminal. The first terminal of the transistor 442 is coupled to a supply terminal, which supplies a supply voltage (e.g., VDD, AVDD, etc.). The second terminal of the transistor 442 is coupled to the transistors 418, 433, 463, 466 and the capacitors 451, 454. The control terminal of the transistor 442 is coupled to the transistors 445, 448 and the clock circuitry 402, 404, which supply the reset clock signal (CLK_RST).

The transistor 445 has a first terminal, a second terminal, and a control terminal. The first terminal of the transistor 445 is coupled to the supply terminal, which supplies the supply voltage. The second terminal of the transistor 445 is coupled to the transistors 412, 430, 481, 484 and the capacitors 457, 460. The control terminal of the transistor 445 is coupled to the transistor 442, 448 and the clock circuitry 402.

The transistor 448 has a first terminal, a second terminal, and a control terminal. The first terminal of the transistor 448 is coupled to the supply terminal, which supplies the supply voltage. The second terminal of the transistor 448 is coupled to the transistor 439 and the capacitors 451, 457. The control terminal of the transistor 448 is coupled to the transistors 442, 445 and the clock circuitry 402.

The capacitor 451 has a first terminal and a second terminal. The first terminal of the capacitor 451 is coupled to the transistors 418, 433, 463, 466 and the capacitor 454. The second terminal of the capacitor 451 is coupled to the transistors 439, 448 and the capacitor 457.

The capacitor 454 has a first terminal and a second terminal. The first terminal of the capacitor 454 is coupled to the transistors 418, 433, 463, 466 and the capacitor 451. The second terminal of the capacitor 454 is coupled to the common terminal, which supplies the common potential.

The capacitor 457 has a first terminal and a second terminal. The first terminal of the capacitor 457 is coupled to the transistors 412, 430, 445, 481, 484 and the capacitor 460. The second terminal of the capacitor 457 is coupled to the transistors 439, 448 and the capacitor 451.

The capacitor 460 has a first terminal and a second terminal. The first terminal of the capacitor 460 is coupled to the transistors 412, 430, 445, 481, 484 and the capacitor 457. The second terminal of the capacitor 460 is coupled to the common terminal, which supplies the common potential.

The transistor 463 has a first terminal, a second terminal, and a control terminal. The first terminal of the transistor 463 is coupled to the supply terminal, which supplies the supply voltage. The second terminal of the transistor 463 is coupled to the transistors 466, 472. The control terminal of the transistor 463 is coupled to the transistors 418, 433, 466 and the capacitors 451, 454.

The transistor 466 has a first terminal, a second terminal, and a control terminal. The first terminal of the transistor 466 is coupled to the transistors 463, 472. The second terminal of the transistor 466 is coupled to the common terminal, which supplies the common potential. The control terminal of the transistor 466 is coupled to the transistors 418, 433, 463 and the capacitors 451, 454.

The transistor 469 has a first terminal, a second terminal, and a control terminal. The first terminal of the transistor 469 is coupled to the supply terminal, which supplies the supply voltage. The second terminal of the transistor 469 is coupled to the transistors 472, 475, 478. The control terminal of the transistor 469 is coupled to the clock circuitry 402, 404, which supply the clock pulse reset signal (CLK_PULSE_RESET).

The transistor 472 has a first terminal, a second terminal, and a control terminal. The first terminal of the transistor 472 is coupled to the transistors 469, 475, 478. The second terminal of the transistor 472 is coupled to the common terminal, which supplies the common potential. The control terminal of the transistor 472 is coupled to the transistor 463, 466.

The transistor 475 has a first terminal, a second terminal, and a control terminal. The first terminal of the transistor 475 is coupled to the supply terminal, which supplies the supply voltage. The second terminal of the transistor 475 is coupled to the transistor 478 and the second output of the pulse generator circuitry 225, which supplies the minus delay signal (PULSE_OUTM). The control terminal of the transistor 475 is coupled to the transistors 469, 472, 478.

The transistor 478 has a first terminal, a second terminal, and a control terminal. The first terminal of the transistor 478 is coupled to the transistor 475 and the second output of the pulse generator circuitry 225, which supplies the minus delay signal. The second terminal of the transistor 478 is coupled to the common terminal, which supplies the common potential. The control terminal of the transistor 478 is coupled to the transistor 469, 472, 475.

The transistor 481 has a first terminal, a second terminal, and a control terminal. The first terminal of the transistor 481 is coupled to the supply terminal, which supplies the supply voltage. The second terminal of the transistor 481 is coupled to the transistors 484, 490. The control terminal of the transistor 481 is coupled to the transistors 412, 430, 484 and the capacitors 457, 460.

The transistor 484 has a first terminal, a second terminal, and a control terminal. The first terminal of the transistor 484 is coupled to the transistors 481, 490. The second terminal of the transistor 484 is coupled to the common terminal, which supplies the common potential. The control terminal of the transistor 484 is coupled to the transistors 412, 430, 481 and the capacitors 457, 460.

The transistor 487 has a first terminal, a second terminal, and a control terminal. The first terminal of the transistor 487 is coupled to the supply terminal, which supplies the supply voltage. The second terminal of the transistor 487 is coupled to the transistors 490, 493, 496. The control terminal of the transistor 487 is coupled to the clock circuitry 402, 404, which supplies the clock pulse reset signal.

The transistor 490 has a first terminal, a second terminal, and a control terminal. The first terminal of the transistor 490 is coupled to the transistors 487, 493, 496. The second terminal of the transistor 490 is coupled to the common terminal, which supplies the common potential. The control terminal of the transistor 490 is coupled to the transistor 481, 484.

The transistor 493 has a first terminal, a second terminal, and a control terminal. The first terminal of the transistor 493 is coupled to the supply terminal, which supplies the supply voltage. The second terminal of the transistor 493 is coupled to the transistor 496 and the first output of the pulse generator circuitry 225, which supplies the plus delay signal. The control terminal of the transistor 493 is coupled to the transistors 487, 490, 496.

The transistor 496 has a first terminal, a second terminal, and a control terminal. The first terminal of the transistor 496 is coupled to the transistor 493 and the first output of the pulse generator circuitry 225, which supplies the plus delay signal. The second terminal of the transistor 496 is coupled to the common terminal, which supplies the common potential. The control terminal of the transistor 496 is coupled to the transistor 487, 490, 493.

In the example of FIG. 4, the transistors 405, 406, 409, 412, 415, 418, 424, 427, 430, 433, 436, 439, 466, 472, 478, 484, 490, 496 are n-channel MOSFETs. Alternatively, the transistors 405, 406, 409, 412, 415, 418, 424, 427, 430, 433, 436, 439, 466, 472, 478, 484, 490, 496 may be n-channel FETs, n-channel IGBTs, n-channel JFETs, NPN BJTs or, with slight modifications, p-type equivalent devices. In the example of FIG. 4, the transistors 442, 445, 448, 463, 469, 475, 481, 487, 493 are p-channel MOSFETs. Alternatively, the transistors 442, 445, 448, 463, 469, 475, 481, 487, 493 may be p-channel FETs, p-channel IGBTs, p-channel JFETs, PNP BJTs, or, with slight modifications, N-type equivalent devices. The transistors 405, 406, 409, 412, 415, 418, 424, 427, 430, 433, 436, 439, 442, 445, 448, 463, 466, 469, 472, 475, 478, 481, 484, 487, 490, 493, 496 may be depletion mode devices, drain-extended devices, enhancement mode devices, natural transistors or other type of device structure transistors. Furthermore, the transistors 405, 406, 409, 412, 415, 418, 424, 427, 430, 433, 436, 439, 442, 445, 448, 463, 466, 469, 472, 475, 478, 481, 484, 487, 490, 493, 496 may be implemented in/over a silicon substrate (Si), a silicon carbide substrate (SiC), a gallium nitride substrate (GaN) or a gallium arsenide substrate (GaAs).

Example operations of the amplifier circuitry 204, the V2D circuitry 220, the pulse generator circuitry 225 are further illustrated and described in “VOLTAGE-TO-DELAY CONVERTER” U.S. patent application Ser. No. 18/498,358, which is incorporated by reference in its entirety and is assigned to the assignee of the instant application. Example operations of the amplifier circuitry 204, 208, the calibration circuitry 215, the V2D circuitry 220, the pulse generator circuitry 225, and the clock circuitry 402, 404 are illustrated and described in connection with FIG. 5.

FIG. 5 is a timing diagram 500 of example operations of the clock circuitry 402, 404 of FIG. 4 or more generally the delay ADC circuitry 200 of FIG. 2. In the example of FIG. 5, the timing diagram 500 includes a reset clock signal 510 (CLK_RST), a bias clock signal 520 (CLK_BIAS), a V2V clock signal 530 (CLK_V2V), and a V2D clock signal 540 (CLK_V2D). In non-calibration operations, the clock circuitry 402 generates the V2V clock signal 530, which controls the amplifier circuitry 204. In calibration operations, the clock circuitry 404 generates the V2V clock signal 530, which controls the amplifier circuitry 208. In some examples, the calibration controller circuitry 235 controls which of the clock circuitry 402, 404 generate the V2V clock signal 530 responsive to the enable calibration signal (EN_CALIB). Advantageously, using the amplifier circuitry 208 for calibration operations reduces the number of switching components along the main signal path (e.g., the first and second inputs of the delay ADC circuitry 200 (V_{RESP}, V_{RESM}) through the pulse generator circuitry 225). Advantageously, reducing the number of switching components along the main signal path reduces noise and improves sound to noise ratio (SNR).

At a first time 550, the reset clock signal 510 has a rising edge, which begins a reset stage. During the reset stage, the transistors 442, 445, 448 charge the capacitors 451, 454, 457, 460 responsive to the reset clock signal 510. At a second time 560, the resent clock signal 510 has a falling edge, which ends the reset stage. At the second time 560, the capacitors 451, 454, 457, 460 are charged to a reset voltage. Also at the second time 560, the bias clock signal 520 has a rising edge, which turns on (enables, conducts current) the transistor 406. Between the second time 560 and a third time 570, the transistor 406 biases the transistors 409, 415 for conducting current. Advantageously, biasing the transistors 409, 415 prior to the third time 570 reduces the turn on time of the transistor 409, 415 after the third time 570.

At the third time 570, the transistors 412, 418, 430, 433 conduct current responsive to the V2V clock signal 530. Between the third time 570 and a fourth time 580 the transistors 409, 412 430 discharge the capacitors 457, 460 based on the plus residue voltage (V_{RESP}). Similarly, between the third time 570 and the fourth time 580, the transistors 415, 418, 433 discharge the capacitors 451, 454 based on the minus residue voltage (V_{RESM}). In some examples, the operations of discharging the capacitors 451, 454, 457, 460 may be referred to as integrating.

Advantageously, the rate of discharge of the capacitors 451, 454, 457, 460 are set by the magnitudes of the plus and minus residue voltages. However, in calibration operations, the corresponding transistors of the amplifier circuitry 208 discharge the capacitors 451, 454, 457, 460 responsive to the magnitudes of the plus and minus DAC signals (DACP, DACM). Advantageously, the transistors 424, 427, 430, 433 contribute to the rate of discharge of the capacitors 451, 454, 457, 460. Advantageously, the current of the transistors 424, 427, 430, 433 accounts for voltage offset and gain. During calibration operations, the calibration controller circuitry 235 structures the calibration circuitry 215 to set the current of the transistors 424, 427, 430, 433. Such example calibration operations are further illustrated and described in connection with FIGS. 9 and 10.

At a fifth time 585, the bias clock signal 520 has a falling edge, which turns off (disables, fails to conduct current) the transistor 406. Between the fourth time 580 and the fifth time 585, the bias clock signal 520 allows the amplifier circuitry 204 to settle. At a sixth time 590, the V2D clock signal 540 has a rising edge to begin a delay conversion. At the sixth time 590, the transistor 439 turns on responsive to the V2D clock signal 540. Between the sixth time 590 and a seventh time 595, the transistors 436, 439 discharge the capacitors 451, 454, 457, 460 at the same rate. Also, between the sixth time 590 and the seventh time 595, the voltages of the capacitors 451, 454, 457, 460 cross the threshold voltages of the transistors 463, 466, 481, 484. The transistors 463, 466, 481, 484 generate falling edges on the plus and minus delay signals (PULSE_OUTP, PULSE_OUTM) responsive to the voltage of the capacitors 451, 454, 457, 460 decreasing below the threshold. Advantageously, the time at which the voltages of the capacitors 451, 454, 457, 460 cross the threshold voltage is based on the rate of discharge between the third time 570 and the fourth time 580. Advantageously, the TDC circuitry 230 determines the digital value (TDC_{OUT}) responsive to the delay between the plus and minus delay signals.

FIG. 6 is a schematic diagram of another example of the calibration circuitry 215 of FIGS. 2 and 4. In the example of FIG. 6, the calibration circuitry 215 includes the amplifier circuitry 421 of FIG. 4 and the transistors 424, 427, 430, 433 of FIG. 4. The example amplifier circuitry 421 of FIG. 6 includes a first example transistor 605, a second example transistor 610, first example current source circuitry 615, a third example transistor 620, a fourth example transistor 625, a fifth example transistor 630, a sixth example transistor 635, a seventh example transistor 640, an eighth example transistor 645, second example current source circuitry 650, a ninth example transistor 655, a tenth example transistor 660, an eleventh example transistor 665, third example current source circuitry 670, a first example switch 675, a second example switch 680, a third example switch 685, and a fourth example switch 690.

The amplifier circuitry 421 of FIG. 6 has a first input, a second input, a third input, a fourth input, a fifth input, a sixth input, a seventh input, an eighth input, a first output, and a second output. The first and second inputs of the amplifier circuitry 421 are structured to be coupled to the sampling circuitry 212 of FIGS. 2 and 3, which provides the plus and minus delay input signals (IND_{P}, IND_{M}). The third, fourth, fifth, sixth, seventh, and eighth inputs of amplifier circuitry 421 are structured to be coupled to the calibration controller circuitry 235 of FIG. 2, which provides the reference input common mode voltage (V_{INCM_REF}), the plus bias current select signal (SEL_{ICURR_P}), an inverted plus bias current select signal (~SEL_{ICURR_P}), the minus bias current select signal (SEL_{ICURR_M}), an inverted minus bias current select signal (~SEL_{ICURR_M}), and the gain control signal (GAIN_{CNTRL}). In the example of FIG. 6, the inverted plus bias current select signal (~SEL_{ICURR_P}) is an inverted version of the plus bias select signal (SEL_{ICURR_P}) at the fourth input of the amplifier circuitry 421. In some examples, the amplifier circuitry 421 may include circuitry, such as an inverter, to produce the inverted plus bias current select signal (~SEL_{ICURR_P}) from the plus bias current select signal (SEL_{ICURR_P}). Similarly, the inverted minus bias current select signal (~SEL_{ICURR_M}) is an inverted version of the minus bias select signal (SEL_{ICURR_M}) at the sixth input of the amplifier circuitry 421. In some examples, the amplifier circuitry 421 may include circuitry, such as an inverter to produce the inverted minus bias current select signal (~SEL_{ICURR_M}) from the minus bias current select signal (SEL_{ICURR_M}). The first output of the amplifier circuitry 421 is coupled to the transistor 424, which receives a plus correction current (ICURR_P). The second output of the amplifier circuitry 421 is coupled to the transistor 427, which receives a minus correction current (ICURR_M).

The transistor 605 has a first terminal, a second terminal, and a control terminal. The first terminal of the transistor 605 is coupled to the transistors 610, 620 and the current source circuitry 615. The second terminal of the transistor 605 is coupled to the transistor 610, 625, 630. The control terminal of the transistor 605 is coupled to the second input of the amplifier circuitry 421 (IND_{M}).

The transistor 610 has a first terminal, a second terminal, and a control terminal. The first terminal of the transistor 610 is coupled to the transistors 605, 620 and the current source circuitry 615. The second terminal of the transistor 610 is coupled to the transistors 625, 630. The control terminal of the transistor 610 is coupled to the first input of the amplifier circuitry 421 (IND_{P}).

The current source circuitry 615 has a first terminal, a second terminal, and a control input. The first terminal of the current source circuitry 615 is coupled to the supply terminal, which supplies the supply voltage. The second terminal of the current source circuitry 615 is coupled to the transistors 605, 610, 620. In some examples, the current source circuitry 615 includes a control terminal, which controls the magnitude of the current source circuitry 615. The control input of the current source circuitry 615 is coupled to the eighth input of the amplifier circuitry 421 (GAIN_{CNTRL}).

The transistor 620 has a first terminal, a second terminal, and a control terminal. The first terminal of the transistor 620 is coupled to the transistors 605, 610 and the current source circuitry 615. The second terminal of the transistor 620 is coupled to the transistors 630, 635, 645. The control terminal of the transistor 620 is coupled to the third input of the amplifier circuitry 421 (V_{INCM_REF}).

The transistor 625 has a first terminal, a second terminal, and a control terminal. The first and control terminals of the transistor 625 are coupled to the transistors 605, 610, 630. The second terminal of the transistor 625 is coupled to the common terminal, which supplies the common potential. The transistor 630 has a first terminal, a second terminal, and a control terminal. The first terminal of the transistor 630 is coupled to the transistors 620, 635, 645. The second terminal of the transistor 630 is coupled to the common terminal, which supplies the common potential. The control terminal of the transistor 630 is coupled to the transistor 605, 610, 625. In the example of FIG. 6, the transistors 625, 635 form current mirror circuitry, which mirrors the current through the transistors 605, 610 through the transistor 630. Alternatively, the transistors 625, 630 may be replaced with alternative current mirror circuitry.

The transistor 635 has a first terminal, a second terminal, and a control terminal. The first terminal of the transistor 635 is coupled to the transistors 620, 630, 645. The second terminal of the transistor 635 is coupled to the common terminal, which supplies the common potential. The control terminal of the transistor 635 is coupled to the transistor 630 and the switches 675, 685.

The transistor 640 has a first terminal, a second terminal, and a control terminal. The first terminal of the transistor 640 is coupled to the supply terminal, which supplies the supply voltage. The second terminal of the transistor 640 is coupled to the transistor 635 and the switches 675, 685. The control terminal of the transistor 640 is coupled to the transistor 645 and the current source circuitry 650.

The transistor 645 has a first terminal, a second terminal, and a control terminal. The first terminal of the transistor 645 is coupled to the transistor 640 and the current source circuitry 650. The second terminal of the transistor 645 is coupled to the transistors 620, 630, 635. The control terminal of the transistor 645 is coupled to a bias terminal, which supplies a bias voltage (BIAS). In some examples, the bias voltage biases the conduction of the transistor 645. In some such examples, the transistor 645 is a drain extended transistor.

The current source circuitry 650 has a first terminal and a second terminal. The first terminal of the current source circuitry 650 is coupled to the supply terminal, which supplies the supply voltage. The second terminal of the current source circuitry 650 is coupled to the transistors 640, 645.

The transistor 655 has a first terminal, a second terminal, and a control terminal. The first terminal of the transistor 655 is coupled to the transistor 665. The second terminal of the transistor 655 is coupled to the common terminal, which supplies the common potential. The control terminal of the transistor 655 is coupled to the transistor 660 and the switches 680, 690.

The transistor 660 has a first terminal, a second terminal, and a control terminal. The first terminal of the transistor 660 is coupled to the supply terminal, which supplies the supply voltage. The second terminal of the transistor 660 is coupled to the transistor 655 and the switches 680, 690. The control terminal of the transistor 660 is coupled to the transistor 665 and the current source circuitry 670.

The transistor 665 has a first terminal, a second terminal, and a control terminal. The first terminal of the transistor 665 is coupled to the transistor 660 and the current source circuitry 670. The second terminal of the transistor 665 is coupled to the transistor 655. The control terminal of the transistors 665 is coupled to the bias terminal, which supplies the bias voltage. In some such examples, the transistor 665 is a drain extended transistor.

The current source circuitry 670 has a first terminal and a second terminal. The first terminal of the current source circuitry 670 is coupled to the supply terminal, which supplies the supply voltage. The second terminal of the current source circuitry 670 is coupled to the transistors 660, 665.

The switch 675 has a first terminal, a second terminal, and a control terminal. The first terminal of the switch 675 is coupled to the transistors 635, 640 and the switch 685. The second terminal of the switch 675 is coupled to the transistor 424 and the switch 680. The control terminal of the switch 675 is coupled to the fourth input of the amplifier circuitry 421 (SEL_{ICURR_P}).

The switch 680 has a first terminal, a second terminal, and a control terminal. The first terminal of the switch 680 is coupled to the transistors 655, 660 and the switch 690. The second terminal of the switch 680 is coupled to the transistor 424 and the switch 675. The control terminal of the switch 680 is coupled to the fifth input of the amplifier circuitry 421 (~SEL_{ICURR_P}).

The switch 685 has a first terminal, a second terminal, and a control terminal. The first terminal of the switch 685 is coupled to the transistors 635, 640 and the switch 675. The second terminal of the switch 685 is coupled to the transistor 427 and the switch 690. The control terminal of the switch 685 is coupled to the sixth input of the amplifier circuitry 421 (SEL_{ICURR_M}).

The switch 690 has a first terminal, a second terminal, and a control terminal. The first terminal of the switch 690 is coupled to the transistors 655, 660 and the switch 680. The second terminal of the switch 690 is coupled to the transistor 427 and the switch 685. The control terminal of the switch 690 is coupled to the seventh input of the amplifier circuitry 421 (~SEL_{ICURR_M}).

In the example of FIG. 6, the transistors 424, 427, 430, 433, 625, 630, 635, 640, 645, 655, 660, 665 are n-channel MOSFETs. Alternatively, the transistors 424, 427, 430, 433, 625, 630, 635, 640, 645, 655, 660, 665 may be n-channel FETs, n-channel IGBTs, n-channel JFETs, NPN BJTs or, with slight modifications, p-type equivalent devices. In the example of FIG. 6, the transistors 605, 610, 620 are p-channel MOSFETs. Alternatively, the transistors 605, 610, 620 may be p-channel FETs, p-channel IGBTs, p-channel JFETs, PNP BJTs, or, with slight modifications, N-type equivalent devices. The transistors 424, 427, 430, 433, 605, 610, 620, 625, 630, 635, 640, 645, 655, 660, 665 may be depletion mode devices, drain-extended devices, enhancement mode devices, natural transistors or other type of device structure transistors. Furthermore, the transistors 424, 427, 430, 433, 605, 610, 620, 625, 630, 635, 640, 645, 655, 660, 665 may be implemented in/over a silicon substrate (Si), a silicon carbide substrate (SiC), a gallium nitride substrate (GaN) or a gallium arsenide substrate (GaAs).

In example operations, the transistors 605, 610 are structured to each have a first width (W) and the transistor 620 is structured to have a second width (2 W), which is twice the width of the first width. In such examples, the first and second widths correspond to the channel width or more generally the size of the transistors 605, 610, 620. Advantageously, sizing the transistors 605, 610 to be equal structures the transistors 605, 610 to average of the plus and minus delay input signals (IND_{P}, IND_{M}), which represents the input common mode voltage. Advantageously, sizing the transistors 605, 610 to be half of the size of the transistor 620 structures the transistors 605, 610, 620 to equal ratio the input common mode voltage and the reference input common mode voltage from the calibration controller circuitry 235.

In such example operations, the transistors 605, 610, 620 route current from the current source circuitry 615 based on the ratio of the input common mode voltage and the reference input common mode voltage (V_{INCM_REF}). For example, if the input common mode voltage of the plus and minus delay inputs is equal to the reference input common mode voltage, the transistors 605, 610 conduct a first half of the current of the current source circuitry 615 and the transistor 620 conducts a second half of the current of the current source circuitry 615. In another example, the transistor 620 conducts more current than the transistors 605, 610 combined responsive to the input common mode voltage being less than the reference input common mode voltage. Advantageously, the amplifier circuitry 421 produces an output responsive to the difference between the input common mode voltage from the sampling circuitry 212 and the reference input common mode voltage from the calibration controller circuitry 235. Example operations of the amplifier circuitry 421 are further illustrated and described in connection with FIGS. 9 and 10.

FIG. 7 is a block diagram of an example implementation of the calibration controller circuitry 170 of FIG. 1, which includes the calibration controller circuitry 235 of FIG. 2. The calibration controller circuitry 170 of FIG. 7 may be instantiated (e.g., creating an instance of, bring into being for any length of time, materialize, implement, etc.) by programmable circuitry such as a Central Processor Unit (CPU) executing first instructions. Also or alternatively, the calibration controller circuitry 170 of FIG. 7 may be instantiated (e.g., creating an instance of, bring into being for any length of time, materialize, implement, etc.) by (i) an Application Specific Integrated Circuit (ASIC) or (ii) a Field Programmable Gate Array (FPGA) structured or configured in response to execution of second instructions to perform operations corresponding to the first instructions. Some or all of the circuitry of FIG. 7 may, thus, be instantiated at the same or different times. Some or all of the circuitry of FIG. 7 may be instantiated, for example, in one or more threads executing concurrently on hardware or in series on hardware. Moreover, in some examples, some or all of the circuitry of FIG. 7 may be implemented by microprocessor circuitry executing instructions or FPGA circuitry performing operations to implement one or more virtual machines or containers.

In the example of FIG. 7, the calibration controller circuitry 170 includes the calibration controller circuitry 235, which may be specific to the delay ADC circuitry 200 of FIG. 2, and second calibration controller circuitry 705. In some examples, the calibration controller circuitry 170 may include any number of instances of the calibration controller circuitry 235 to support any number of delay ADC circuitry, such as the delay ADC circuitry 155, 160, 165 of FIG. 1. The example calibration controller circuitry 235 of FIG. 7 includes example sequencing circuitry 710, example offset correction circuitry 715, example gain correction circuitry 720, example DAC circuitry 725, example DAC code circuitry 730, and example DAC common mode code circuitry 735. The example offset correction circuitry 715 of FIG. 7 includes example offset controller circuitry 740, example reference generation circuitry 745, example comparator circuitry 750, first example offset correction circuitry 755, second example offset correction circuitry 760, and example total offset correction circuitry 765. The example gain correction circuitry 720 of FIG. 7 includes example gain controller circuitry 770, example plus DAC code circuitry 775, example minus DAC code circuitry 780, example minimum DAC code circuitry 785, and example gain correction circuitry 790. The calibration controller circuitry 170 is structured to be coupled to the sampling circuitry 212 of FIGS. 2 and 3, the calibration circuitry 215 of FIGS. 2, 4, and 6, and the TDC circuitry 230 of FIG. 2.

The calibration controller circuitry 235 has an input, a first output, a second output, a third output, a fourth output, a fifth output, a sixth output, a seventh output, an eighth output, a ninth output, a tenth output, an eleventh output, and a twelfth output. The input of the calibration controller circuitry 235 is coupled to the TDC circuitry 230 of FIG. 2. The TDC circuitry 230 provides the digital value (TDC_{OUT}). The first, second, and third outputs of the calibration controller circuitry 235 provides the input control signal (INP_CNTRL), the inverted input control signal (INP_CNTRL_Z), and the calibration control signal (CALIB_CNTRL). The fourth and fifth outputs of the calibration controller circuitry 235 provide the plus and minus DAC signals (DACP, DACM) to the amplifier circuitry 208 of FIG. 2 and the sampling circuitry 212. The sixth, seventh, eighth, ninth, tenth, and eleventh outputs of the calibration controller circuitry 235 provide the reference input common mode voltage (V_{INCM_REF}), the gain control signal (GAIN_{CNTRL}), the plus bias current select signal (SEL_{ICUR_P}), the minus bias current select signal (SEL_{ICUR_M}), the first gain trim value (GAIN_{TRIM_T1}), and the second gain trim value (GAIN_{TRIM_T2}) to the calibration circuitry 215 of FIGS. 2, 4, and 6. The twelfth output of the calibration controller circuitry 235 provides the calibration enable signal (EN_CALIB) to the clock circuitry 402, 404 of FIG. 4.

The calibration controller circuitry 705 has an input and outputs. The input of the calibration controller circuitry 705 is structured to be coupled to the TDC circuitry of a subsequent instance of the delay ADC circuitry 200 of FIG. 2, such as the delay ADC circuitry 160, 165. The outputs of the calibration controller circuitry 705 are structured similar to the outputs of the calibration controller circuitry 705 and are structured to be coupled to the subsequent instance of the delay ADC circuitry 200. Although in the example of FIG. 7, the calibration controller circuitry 235 includes multiple instances of the calibration controller circuitry 235. In other examples, the calibration controller circuitry 235 may include any number of instances of the calibration controller circuitry 235. In some examples, the calibration controller circuitry 705 is instantiated by application specific integrated circuitry or programmable circuitry executing delay ADC calibration instructions to perform operations such as those represented by the flowchart(s) of FIGS. 8, 9, and 10.

The sequencing circuitry 710 has a first output, a second output, a third output, and a fourth output. The first output of the sequencing circuitry 710 provides the input control signal (INP_CNTRL) to the sampling circuitry 212. The second output of the sequencing circuitry 710 provides the calibration enable signal (CALIB_EN) to the clock circuitry 402, 404. The third output of the sequencing circuitry 710 is coupled to the offset correction circuitry 715 and provides an enable offset calibration signal (EN_OFF_CAL). The fourth output of the sequencing circuitry 710 is coupled to the gain correction circuitry 720 and provides an enable gain calibration signal (EN_GAIN_CAL). In some examples, the sequencing circuitry 710 is instantiated by application specific integrated circuitry or programmable circuitry executing sequencing instructions to perform operations such as those represented by the flowchart(s) of FIGS. 8, 9, and 10.

The offset correction circuitry 715 has a first input, a second input, a first output, a second output, a third output, a fourth output, a fifth output, and a sixth output. The first input of the offset correction circuitry 715 is coupled to the input of the calibration controller circuitry 235, which provides the digital value (TDC_{OUT}). The second input of the offset correction circuitry 715 is coupled to the sequencing circuitry 710. The first output of the offset correction circuitry 715 provides the calibration control signal (CAL_CNTRL) to the sampling circuitry 212. The second, third, and fourth outputs of the offset correction circuitry 715 provide the reference input common mode voltage (V_{INCM_REF}), the plus bias current select signal (SEL_{ICUR_P}), and the minus bias current select signal (SEL_{ICUR_M}) to the calibration circuitry 215. The fifth output of the offset correction circuitry 715 is coupled to the DAC code circuitry 730. The sixth output of the offset correction circuitry 715 is coupled to the DAC common mode code circuitry 735. In some examples, the offset correction circuitry 715 is instantiated by application specific integrated circuitry or programmable circuitry executing offset correction instructions to perform operations such as those represented by the flowchart(s) of FIGS. 8 and 9.

The gain correction circuitry 720 has a first input, a second input, a first output, a second output, a third output, a fourth output, a fifth output, and a sixth output. The first input of the gain correction circuitry 715 is coupled to the input of the calibration controller circuitry 235, which provides the digital value (TDC_{OUT}). The second input of the gain correction circuitry 720 is coupled to the sequencing circuitry 710. The first output of the gain correction circuitry 720 provides the calibration control signal (CAL_CNTRL) to the sampling circuitry 212. The second, third, and fourth outputs of the gain correction circuitry 720 provide the gain control signal (GAIN_{CNTRL}), the first gain trim value (GAIN_{TRIM_T1}), and the second gain trim value (GAIN_{TRIM_T2}) to the calibration circuitry 215. The fifth output of the gain correction circuitry 720 is coupled to the DAC code circuitry 730. The sixth output of the gain correction circuitry 720 is coupled to the DAC common mode code circuitry 735. In some examples, the gain correction circuitry 720 is instantiated by application specific integrated circuitry or programmable circuitry executing gain correction instructions to perform operations such as those represented by the flowchart(s) of FIGS. 8 and 10.

The DAC circuitry 725 has a first input, a second input, a first output, and a second output. The first input of the DAC circuitry 725 is coupled to the DAC code circuitry 730. The second input of the DAC circuitry 725 is coupled to the DAC common mode code circuitry 735. The first output of the DAC circuitry 725 provides the plus DAC signal (DACP) to the amplifier circuitry 208 and the sampling circuitry 212. The second output of the DAC circuitry 725 provides the minus DAC signal (DACM) to the amplifier circuitry 208 and the sampling circuitry 212. In some examples, the DAC circuitry 725 is instantiated by application specific integrated circuitry or programmable circuitry executing gain controller instructions to perform operations such as those represented by the flowchart(s) of FIGS. 8 and 10.

The DAC code circuitry 730 has inputs and an output. The inputs of the DAC code circuitry 730 are coupled to offset correction circuitry 715 and the gain correction circuitry 720. The output of the DAC code circuitry 730 is coupled to the DAC circuitry 725. In some examples, the DAC code circuitry 730 is instantiated by application specific integrated circuitry or programmable circuitry executing gain controller instructions to perform operations such as those represented by the flowchart(s) of FIGS. 8 and 10.

The DAC common mode code circuitry 735 has inputs and an output. The inputs of the DAC common mode code circuitry 735 are coupled to offset correction circuitry 715 and the gain correction circuitry 720. The output of the DAC common mode code circuitry 735 is coupled to the DAC circuitry 725. In some examples, the DAC common mode code circuitry 735 is instantiated by application specific integrated circuitry or programmable circuitry executing gain controller instructions to perform operations such as those represented by the flowchart(s) of FIGS. 8 and 10.

The offset controller circuitry 740 has an input, a first output, a second output, a third output, a fourth output, a fifth output, a sixth output, a seventh output, an eighth output, and a ninth output. The input of the offset controller circuitry 740 is coupled to the comparator circuitry 750. The first output of the offset controller circuitry 740 provides the calibration control signal (CAL_CNTRL) to the sampling circuitry 212. The second and third outputs of the offset controller circuitry 740 provide the plus bias current select signal (SEL_{ICUR_P}) and the minus bias current select signal (SEL_{ICUR_M}) to the calibration circuitry 215. The fourth output of the offset controller circuitry 740 is coupled to the DAC code circuitry 730. The fifth output of the offset controller circuitry 740 is coupled to the DAC common mode code circuitry 735. The sixth output of the offset controller circuitry 740 is coupled to the reference generation circuitry 745. The seventh output of the offset controller circuitry 740 is coupled to the offset correction circuitry 755. The eighth output of the offset controller circuitry 740 is coupled to the offset correction circuitry 760. The ninth output of the offset controller circuitry 740 is coupled to the total offset correction circuitry 765. In some examples, the offset controller circuitry 740 is instantiated by application specific integrated circuitry or programmable circuitry executing offset controller instructions to perform operations such as those represented by the flowchart(s) of FIGS. 8 and 9.

The reference generation circuitry 745 has an input and an output. The input of the reference generation circuitry 745 is coupled to the offset controller circuitry 740. The output of the reference generation circuitry 745 provides the reference input common mode voltage (V_{INCM_REF}) to the calibration circuitry 215. In some examples, the reference generation circuitry 745 is implemented using DAC circuitry, which sets the reference input common mode voltage responsive to a DAC code from the offset controller circuitry 740. In some examples, the reference generation circuitry 745 is instantiated by application specific integrated circuitry or programmable circuitry executing reference generation instructions to perform operations such as those represented by the flowchart(s) of FIGS. 8 and 9.

The comparator circuitry 750 has an input and an output. The input of the comparator circuitry 750 is coupled to the input of the calibration controller circuitry 235, which provides the digital value (TDC_{OUT}). The output of the comparator circuitry 750 is coupled to the offset controller circuitry 740. In some examples, the comparator circuitry 750 is instantiated by application specific integrated circuitry or programmable circuitry executing comparator instructions to perform operations such as those represented by the flowchart(s) of FIGS. 8 and 9.

The offset correction circuitry 755 has an input and an output coupled to the offset controller circuitry 740. The offset correction circuitry 760 has an input and an output coupled to the offset controller circuitry 740. The total offset correction circuitry 765 has an input and an output. The input of the total offset correction circuitry 765 is coupled to the offset controller circuitry 740. The output of the total offset correction circuitry 765 is coupled to the offset controller circuitry 740. The offset correction circuitry 755, 760, 765 store reference offset values. Examples of the reference offset values are further described in connection with the operations represented by the flowchart(s) of FIGS. 8 and 9.

The gain controller circuitry 770 has an input, a first output, a second output, a third output, a fourth output, a fifth output, a sixth output, a seventh output, an eighth output, a ninth output, and a tenth output. The input of the gain controller circuitry 770 is coupled to the input of the calibration controller circuitry 235, which provides the digital value (TDC_{OUT}). The first output of the gain controller circuitry 770 provides the calibration control signal (CALIB_CNTRL) to the sampling circuitry 212. The second, third, and fourth outputs of the gain controller circuitry 770 provide the gain control signal (GAIN_{CNTRL}), the first gain trim value (GAIN_{TRIM_T1}), and the second gain trim value (GAIN_{TRIM_T2}) to the calibration circuitry 215. The fifth output of the gain controller circuitry 770 is coupled to the DAC code circuitry 730. The sixth output of the gain controller circuitry 770 is coupled to the DAC common mode code circuitry 735. The seventh output of the gain controller circuitry 770 is coupled to the plus DAC code circuitry 775. The eighth output of the gain controller circuitry 770 is coupled to the minus DAC code circuitry 780. The ninth output of the gain controller circuitry 770 is coupled to the minimum DAC code circuitry 785. The tenth output of the gain controller circuitry 770 is coupled to the gain correction circuitry 790. In some examples, the gain controller circuitry 770 is instantiated by application specific integrated circuitry or programmable circuitry executing gain controller instructions to perform operations such as those represented by the flowchart(s) of FIGS. 8 and 10.

The plus DAC code circuitry 775 has an input and an output coupled to the gain controller circuitry 770. The minus DAC code circuitry 780 has an input and an output coupled to the gain controller circuitry 770. The minimum DAC code circuitry 785 has an input and an output coupled to the gain controller circuitry 770. The gain correction circuitry 790 has an input and an output. The input of the gain correction circuitry 790 is coupled to the gain controller circuitry 770. The output of the gain correction circuitry 790 is coupled to the gain controller circuitry 770. The DAC code circuitry 775, 780, 785 and the gain correction circuitry 790 store reference gain values. Examples of the reference gain values are further described in connection with the operations represented by the flowchart(s) of FIGS. 8 and 10.

FIG. 8 is a flowchart representative of example machine-readable instructions or example operations 800 that may be at least one of executed, instantiated, or performed using example implementations of the delay ADC circuitry 155, 160, 165, 200 of FIGS. 1 and 2 and the calibration controller circuitry 170, 235 of FIGS. 1, 2, and 7, or more generally the delay domain ADC circuitry 150 of FIG. 1, or even more generally the ADC circuitry 100 of FIG. 1.

The example operations 800 of FIG. 8 begin at Block 805, at which the ADC circuitry 100 receives an analog input. In example operations, the ADC circuitry 100 receives an analog input responsive to the clock circuitry 145 closing the switches 105, 115. In such example operations, the analog input charges the capacitors 110, 120, which store the analog value after a first duration of time. After the first duration, the capacitors 110, 120 store the analog input and the clock circuitry 145 opens the switches 105, 115. In some examples, the ADC circuitry 100 buffers the analog input prior to the capacitors 110, 120. In such examples, buffering the analog input prior to the capacitors 110, 120 increases the drive strength of the analog input.

The ADC 125 of FIG. 1 generates a first digital value (DOUT₀) as an approximation of the analog input. (Block 810). In example operations, the ADC 125 produces a relatively low-resolution digital representation of the analog input at the capacitors 110, 120. In such example operations, the digital output of the ADC 125 (DOUT₀) represents a relatively low resolution (also referred to as approximation) representation of the analog input in digital.

The CDAC 130 of FIG. 1 produces a residue as the difference between the approximation and the actual analog input. (Block 815). In example operations, the CDAC 130 produces an approximate analog value responsive to the digital output from the ADC 125. In such example operations, the CDAC 130 differentially applies the approximate analog value to a first side of capacitor circuitry that is also coupled to the analog input of the capacitors 110, 120 through the switches 135, 140. In such examples, the CDAC 130 sets the voltages of the capacitors 110, 120 to the residue voltage. Advantageously, the voltage difference across the capacitors 110, 120 represents the difference between the analog input and the approximate analog value of the CDAC 130. The CDAC 130 supplies the residue voltage (V_{RES}) to the delay domain ADC circuitry 150.

The delay domain ADC circuitry 150 of FIG. 1 generates a second digital value (DOUT₁) of the residue using a delay ADC. (Block 820). In example operations, the calibration controller circuitry 170 activates one of the delay ADC circuitry 155, 160, 165 responsive to enabling the main clock circuitry 402 of FIG. 4 using the calibration enable signal (EN_CALIB). For example, the ADC circuitry 155 produces the second digital value (DOUT₁) responsive to the calibration controller circuitry 170 activating the main clock circuitry 402 of the ADC circuitry 155. In such example operations, the amplifier circuitry 204, the V2D circuitry 220, and the pulse generator circuitry 225 convert the residue voltage into a delay between rising edges of two signals. In some examples, such as the delay ADC circuitry 200, the pulse generator circuitry 225 produces two signals having falling edges timed based on the residue voltage. For example, the delay between edges of first and second delay signals from the pulse generator circuitry 225 increases as the analog value of the residue voltage increases. Similarly, the delay between the first and second delay signals (PULSE_OUTP, PULSE_OUTM) from the pulse generator circuitry 225 decreases as the analog value of the residue voltage decreases. The TDC circuitry 230 generates a digital output responsive to comparing the delay between the delay signals to reference delays. For example, the TDC circuitry 230 sets a first bit to a logic one responsive to a determination that the delay between edges of the delay signals is greater than a first reference delay. Similarly, the TDC sets a second bit to a logic zero responsive to a determination that the remaining delay between the falling edges of the delay signals is less than a second reference delay. Advantageously, the TDC circuitry 230 generates a digital output representing the delay between the delay signals from the pulse generator circuitry 225.

The ADC circuitry 100 represents the analog input with the first and second digital values. (Block 825). In example operations, the ADC circuitry 100 produces a digital output representing the analog input using the bits of the digital output from the ADC 125 and the bits of the digital output of the delay ADC circuitry 155. In some examples, the ADC circuitry 100 may include at least one of latch, alignment, combination, or correction circuitry to logically combine the digital outputs of the ADC 125 and the delay domain ADC circuitry 150. In some such examples, the additional circuitry may account differences between the digital outputs resulting from gain, delays, etc.

The calibration controller circuitry 170, 235 determines if the delay ADC circuitry 155 is to be calibrated. (Block 830). In example operations, the calibration controller circuitry 170, 235 may include circuitry, such as the sequencing circuitry 710 of FIG. 7, to sequence the calibration of at least one of the delay ADC circuitry 155, 160, 165. In such examples, the calibration controller circuitry 170, 235 may calibrate one of the delay ADC circuitry 155, 160, 165 responsive to at least one of a periodic interval, a fault detection, completion of a calibration of a different delay ADC, etc. If the calibration controller circuitry 170, 235 determines that the active delay ADC is not to be calibrated (e.g., Block 830 returns a result of NO), control proceeds to return to Block 805.

If the calibration controller circuitry 170, 235 determines that the active delay ADC is to be calibrated (e.g., Block 830 returns a result of YES), the calibration controller circuitry 170, 235 disconnects the delay ADC circuitry 155. (Block 835). In example operation, the calibration controller circuitry 170, 235 adjusts the calibration enable signal (EN_CALIB) to disable the main clock circuitry 402 and enable the calibration clock circuitry 404. In such example operations, the calibration clock circuitry 404 provides the V2V clock signal (CLK_V2V) to the amplifier circuitry 208 of FIGS. 2 and 4 and the main clock circuitry 402 stops providing the V2V clock signal (CLK_V2V) to the amplifier circuitry 204 of FIGS. 2 and 4. Advantageously, the calibration controller circuitry 170, 235 may use the calibration enable signal (EN_CALIB) to disconnect the delay ADC circuitry 200 from the plus and minus residue voltages (V_{RESP}, V_{RESM}). Advantageously, the amplifier circuitry 208 receives inputs from the DAC circuitry 725 of FIG. 7 during calibration operations.

In some examples, as illustrated by the dashed outline, the calibration controller circuitry 170, 235 activates another delay ADC to generate subsequent second digital values. (Block 840). In some examples, such as in FIG. 1, the delay domain ADC circuitry 150 includes multiple instances of the delay ADC circuitry 155, 160, 165. In such examples, the calibration controller circuitry 170, 235 may activate one of the delay ADC circuitry 160, 165 to continue to provide digital outputs during the calibration of the delay ADC circuitry 155.

In some examples, as illustrated by the dashed outline, the TDC circuitry 230 of FIG. 2 is calibrated. (Block 845). In some example operations, calibrating the TDC circuitry 230 prior to calibrating the delay ADC circuitry 200 improves the accuracy of the calibration operations.

The offset correction circuitry 715 of FIG. 7 calibrates for common mode offset. (Operations 900 of FIG. 9). In example operations, the offset correction circuitry 715 determines a common mode voltage offset added by the amplifier circuitry 204, the V2D circuitry 220, and the pulse generator circuitry 225 responsive to performing the operations 900. In such example operations, the offset correction value accounts for the common mode voltage offset by adjusting the reference input common mode voltage (V_{INCM_REF}). Advantageously, the calibration circuitry 215 of FIGS. 2, 4, and 6 may account for common mode voltage offset by adjusting the reference input common mode voltage of the calibration circuitry 215. Further operations of the offset correction circuitry 715 are further illustrated and described in connection with FIG. 9. Advantageously, the calibration circuitry 215 reduces the common mode voltage offset responsive to adjusting the reference input common mode voltage.

The gain correction circuitry 720 of FIG. 7 calibrates for common mode gain. (Operations 1000 of FIG. 10). In some examples, the gain of a common mode voltage across the delay ADC circuitry 200 depends on the magnitude of the common mode voltage. For example, relatively small common mode voltages (e.g., close to the common potential) may have a relatively high gain and relatively large common mode voltages (e.g., close to the supply voltage) may have a relatively small gain. In such examples, the gain correction circuitry 720 sweeps a range of common mode voltages to determine the common mode voltage having the lowest gain. The gain correction circuitry 720 sets the gain of the calibration circuitry 215 responsive to determining the common mode voltage with the lowest gain. Advantageously, setting the gain of the calibration circuitry 215 based on the lowest common mode gain improves CMRR. Further operations of the gain correction circuitry 720 are further illustrated and described in connection with FIG. 10. Control proceeds to return to Block 805.

Example methods are described with reference to the flowchart illustrated in FIG. 8. However, many other methods of implementing the delay ADC circuitry 155, 160, 165, 200 of FIGS. 1 and 2 and the calibration controller circuitry 170, 235 of FIGS. 1, 2, and 7, or more generally the delay domain ADC circuitry 150 of FIG. 1, or even more generally the ADC circuitry 100 of FIG. 1 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

FIG. 9 is a flowchart representative of example machine-readable instructions or example operations 900 that may be at least one of executed, instantiated, or performed using example implementations of the calibration circuitry 215 of FIGS. 2, 4, and 6, the offset correction circuitry 715 of FIG. 7, or more generally the delay ADC circuitry 155, 160, 165, 200 of FIGS. 1 and 2 and the calibration controller circuitry 170, 235 of FIGS. 1, 2, and 7.

The example operations 900 of FIG. 9 begin at Block 905 at which the offset correction circuitry 715 initializes a calibration DAC. In example operation, the offset correction circuitry 715 sets values of the DAC code circuitry 730 of FIG. 7 and the DAC common mode code circuitry 735 of FIG. 7 to initial values. In some examples, the DAC circuitry 725 of FIG. 7 sets the plus and minus DAC signals (DACP, DACM) to an initial value responsive to the values of the DAC code circuitry 730 and the DAC common mode code circuitry 735. In some such examples, the DAC circuitry 725 initializes the plus and minus DAC signals (DACP, DACM) to have a differential voltage approximately equal to zero (e.g., the plus and minus DAC signals (DACP, DACM) are equal). In such example operations, the offset correction circuitry 715 adjusts the calibration control signal (CAL_CNTRL) to close the switches 315, 320 of FIG. 3. The sampling circuitry 212 supplies the plus and minus DAC signals (DACP, DACM) to the calibration circuitry 215 responsive to closing the switches 315, 320. In such examples, the plus and minus inputs signals (IND_{P}, IND_{M}) of the switching circuitry 212 are approximately equal to the plus and minus DAC signals (DACP, DACM) responsive to closing the switches 315, 320.

The amplifier circuitry 240, 421 of FIGS. 2 and 3 drives a plus side calibration transistor with a correction bias. (Block 910). In example operations, the offset controller circuitry 740 controls a supply of a CMRR correction bias (CMRR_CORR_BIAS) to the transistors 424, 427 of FIGS. 4 and 6 using the plus and minus bias current select signals (SEL_{ICURR_P}, SEL_{ICURR_M}). The transistors 635, 640 produce the CMRR correction bias responsive to currents of the current source circuitry 650 and the current of the transistor 630. In such example operations, the switch 675 of FIG. 6 supplies the CMRR correction bias to the transistor 424 responsive to the offset controller circuitry 740 setting the plus bias current select signal (SEL_{ICURR_P}). The CMRR correction bias is a control signal that is set responsive to the difference in current conduction by the transistors 605, 610 and the transistor 620. Advantageously, the CMRR correction bias is based on the difference between the input common mode voltage at the inputs of the amplifier circuitry 204 and the reference input common mode voltage from the calibration controller circuitry 235.

The amplifier circuitry 240, 421 drives a minus side calibration transistor with a calibration bias. (Block 915). In example operations, the offset controller circuitry 740 controls a supply of a CMRR calibration bias (CMRR_CALIB_BIAS) to the transistors 424, 427 of using the plus and minus bias current select signals (SEL_{ICURR_P}, SEL_{ICURR_M}). The transistors 655, 660 produce the CMRR calibration bias responsive to currents of the current source circuitry 670 and the current of the transistor 655. In such example operations, the switch 690 of FIG. 6 supplies the CMRR calibration bias to the transistor 427 responsive to the offset controller circuitry 740 clearing the minus bias current select signal (SEL_{ICURR_M}) or setting the inverted minus bias current select signal (~SEL_{ICURR_M}). The CMRR calibration bias is a control signal that is a fixed bias signal. Unlike the CMRR correction bias, the CMRR calibration bias does not change responsive to changes in the common mode voltages at the inputs of the amplifier circuitry 240, 421. Advantageously, the CMRR calibration bias provides a fixed reference bias that is independent of voltages at the input of the amplifier circuitry 240, 421.

The reference generation circuitry 745 of FIG. 7 sets a reference common mode voltage. (Block 920). In example operations, the reference generation circuitry 745 sets the reference input common mode voltage (V_{INCM_REF}) to an initial voltage, which represents a target common mode voltage. For example, if the inputs of the amplifier circuitry 204 are equal, the reference generation circuitry 745 sets the reference input common mode voltage to zero volts.

The comparator circuitry 750 of FIG. 7 determines if the TDC output is zero. (Block 925). In example operations, the amplifier circuitry 208, the V2D circuitry 220, and the pulse generator circuitry 225 generate plus and minus delay signals (PULSE_OUTP, PULSE_OUTM) responsive to input voltages of the amplifier circuitry 204 and current from the calibration circuitry 215. In such example operations, the TDC circuitry 230 outputs a digital value representing the delay between the plus and minus delay signals (PULSE_OUTP, PULSE_OUTM). The comparator circuitry 750 compares the digital value from the TDC circuitry 230 to the target output of zero. Advantageously, if the inputs of the amplifier circuitry 204 are equal, the digital value at the output of the TDC circuitry 230 represents the offset of the calibration circuitry 215. Advantageously, controlling the transistor 424 with the CMRR correction bias and the transistor 427 with the CMRR calibration bias shifts the common mode at the inputs of the V2D circuitry 220 based on the offset of the amplifier circuitry 240, 421.

If the comparator circuitry 750 determines that the TDC output is not zero (e.g., Block 925 returns a result of NO), the offset controller circuitry 740 of FIG. 7 adjusts a first offset correction value to adjust the reference common mode voltage. (Block 930). In example operations, the comparator circuitry 750 detects a voltage offset responsive to the digital value from the TDC circuitry 230 being non-zero. In such example operations, the offset controller circuitry 740 adjusts the reference generation circuitry 745 based on the digital value from the TDC circuitry 230. For example, the comparator circuitry 750 increases the input reference common mode voltage responsive to the digital value from the TDC circuitry 230 corresponding to a voltage less than zero. Similarly, the comparator circuitry 750 decreases the input reference common mode voltage responsive to the digital value from the TDC circuitry 230 corresponding to a voltage greater than zero. In some examples, such as in FIG. 7, the offset correction circuitry 755 stores a first offset correction value (OFF_CORR1). In such examples, the first offset correction value represents the adjustments to the reference input common mode voltage when the CMRR correction bias controls the transistor 424.

If the comparator circuitry 750 determines that the TDC output is zero (e.g., Block 925 returns a result of YES), the amplifier circuitry 240, 421 drives the plus side calibration transistor with the calibration bias. (Block 935). In example operations, the switch 680 of FIG. 6 supplies the CMRR calibration bias to the transistor 424 responsive to the offset controller circuitry 740 clearing the plus bias current select signal (SEL_{ICURR_P}) or setting the inverted plus bias current select signal (~SEL_{ICURR_P}).

The amplifier circuitry 240, 421 drives the minus side calibration transistor with the correction bias. (Block 940). In example operations, the switch 685 of FIG. 6 supplies the CMRR correction bias to the transistor 427 responsive to the offset controller circuitry 740 setting the minus bias current select signal (SEL_{ICURR_M}).

The reference generation circuitry 745 sets the reference common mode voltage. (Block 945). In example operations, the reference generation circuitry 745 sets the reference input common mode voltage to the initial voltage, which represents the target common mode voltage. For example, if the inputs of the amplifier circuitry 204 are equal, the reference generation circuitry 745 sets the reference input common mode voltage to zero volts.

The comparator circuitry 750 determines if the TDC output is zero. (Block 950). In example operations, the amplifier circuitry 204, 208, the V2D circuitry 220, and the pulse generator circuitry 225 generate plus and minus delay signals (PULSE_OUTP, PULSE_OUTM) responsive to input voltages of the amplifier circuitry 204 and current from the calibration circuitry 215. In such example operations, the TDC circuitry 230 outputs a digital value representing the delay between the plus and minus delay signals (PULSE_OUTP, PULSE_OUTM). The comparator circuitry 750 compares the digital value from the TDC circuitry 230 to the target output of zero. Advantageously, if the inputs of the amplifier circuitry 204 are equal, the digital value at the output of the TDC circuitry 230 represents the offset of the calibration circuitry 215. Advantageously, controlling the transistor 427 with the CMRR correction bias and the transistor 424 with the CMRR calibration bias shifts the common mode at the inputs of the V2D circuitry 220 based on the offset of the amplifier circuitry 240, 421.

If the comparator circuitry 750 determines that the TDC output is not zero (e.g., Block 950 returns a result of NO), the offset controller circuitry 740 adjusts a second offset correction value to adjust the reference common mode voltage. (Block 955). In example operations, the comparator circuitry 750 determines the presence of a voltage offset responsive to the digital value from the TDC circuitry 230 being non-zero. In such example operations, the offset controller circuitry 740 adjusts the reference generation circuitry 745 based on the digital value from the TDC circuitry 230. In some examples, such as in FIG. 7, the offset correction circuitry 760 stores a second offset correction value (OFF_CORR2). In such examples, the second offset correction value represents the adjustments to the reference input common mode voltage when the CMRR correction bias controls the transistor 427.

If the comparator circuitry 750 determines that the TDC output is zero (e.g., Block 950 returns a result of YES), the total offset correction circuitry 765 of FIG. 7 determines an offset correction value based on the first and second offset correction values. (Block 960). In example operations, the total offset correction circuitry 765 determines an offset correction value responsive to the first and second offset correction values from the offset correction circuitry 755, and 760. In some examples, the total offset correction circuitry 765 determines the final offset correction value responsive to averaging the first and second offset correction values. In such examples, the offset correction value of the total offset correction circuitry 765 represents the common mode voltage offset of the calibration circuitry 215 or more generally the delay ADC circuitry 200. Advantageously, averaging the first and second offset correction values provides the offset correction for the calibration circuitry 215. Advantageously, both the first and second offset correction values account for offset by the amplifier circuitry 204, the V2D circuitry 220, the pulse generator circuitry 225, and the TDC circuitry 230.

The offset controller circuitry 740 sets the reference common mode voltage based on the offset correction value. (Block 965). In example operations, after the total offset correction circuitry 765 determines the offset correction value, the offset controller circuitry 740 structures the CMRR correction bias (CMRR_CORR_BIAS) and the CMRR calibration bias (CMRR_CALIB_BIAS) to close the switches 675, 685 and open the switches 680, 690. Also, the reference generation circuitry 745 sets the reference input common mode voltage (V_{INCM_REF}) to the determined offset correction value.

In such example operations, the calibration controller circuitry 170, 235 controls the transistors 620 of FIG. 6 responsive to supplying the reference input common mode voltage (V_{INCM_REF}) to the amplifier circuitry 240, 421. In such example operations, the transistor 620 conducts a current proportional to the ratio of the reference input common mode voltage to the input common mode voltage of the transistors 605, 610 of FIG. 6. The current mirror circuitry of the transistors 625, 630 produces a current proportional to the difference between the current conduction of the transistors 605, 610 and the transistor 620. The transistors 645, 635 subtract the current difference from a bias current from the current source circuitry 650 to control the conduction of the transistor 640, which drives the transistors 245, 250, 424, 427. Control proceeds to the operations 1000.

In such example operations, the delay period (Ta) between the edges of the plus and minus delays at the outputs of the V2D circuitry 220 is proportional to the gain of the amplifier circuitry 204 (Gainᵥ₂ᵥ), the input common mode voltage of the plus and minus residue voltages (V_{incm}), the gain of the V2D circuitry 220 (Gain_{v2d}), the output common mode voltage at the input of the V2D circuitry 220 (V_{outcm}), and the input voltage (V_{RES}). Examples operations, including calculations of the gain of the amplifier circuitry 204, 208 and the V2D circuitry 220 are further illustrated and described in “VOLTAGE-TO-DELAY CONVERTER” U.S. patent application Ser. No. 18/498,358, which is incorporated by reference in its entirety and is assigned to the assignee of the instant application. The delay period is proportional to Equation (1). Advantageously, the calibration circuitry 215 of FIGS. 2, 4, and 6, the offset correction circuitry 715 of FIG. 7 improves the CMRR of the delay domain ADC circuitry 150 by decreasing the contribution of the output common mode voltage at the input of the V2D circuitry 220. The CMRR of the delay domain ADC circuitry 150 is proportional to the common mode gain over the differential gain or the contributions of the CMRR of the amplifier circuitry 204, 208, the CMRR of the V2D circuitry 220, and the gain of the amplifier circuitry 204, 208. The CMRR of the delay domain ADC circuitry 150 may be found using Equation (2). Advantageously, improving the CMRR of the amplifier circuitry 204, 208 increases the total CMRR of the delay domain ADC circuitry 150. Advantageously, as described in connection with FIG. 10, the operations 1000 further improve the CMRR of the delay domain ADC circuitry 150 by reducing the common mode gain of the amplifier circuitry 204, 208 using the calibration circuitry 215.

$${T}_{d} = {Gain}_{v 2 v} ( {V}_{incm} ) {Gain}_{v 2 d} ( {V}_{outcm} ) {V}_{i n} \qquad Equation ( 1 )$$

$$\frac{{CM}_{gain}}{{DF}_{gain}} = \frac{{G}_{v 2 v}^{′}}{{G}_{v 2 v}} + \frac{{G}_{v 2 d}^{′}}{{G}_{v 2 d}} \times \frac{\partial {V}_{outcm}}{\partial {V}_{incm}} = {CMRR}_{v 2 v} + {CMRR}_{v 2 d} \times C {M}_{{gain}_{v 2 v}} \qquad Equation ( 2 )$$

Advantageously, the transistors 245, 250, 424, 427 conduct a correction current based on the difference between the input common mode voltage at the input of the amplifier circuitry 204 and the reference input common mode voltage from the calibration controller circuitry 170, 235. Advantageously, the transistors 245, 250, 424, 427 sink a current to replicate as though the input common mode voltage at the inputs of the amplifier circuitry 204 is the reference input common mode voltage. Advantageously, setting the common mode voltage to the determined reference input common mode voltage reduces common mode offset across the delay ADC circuitry 155, 160, 165, 200. Advantageously, decreasing the common mode offset improves the CMRR of the delay ADC circuitry 155, 160, 165, 200. Advantageously, improving the CMRR of the delay ADC circuitry 155, 160, 165, 200 increases the overall accuracy of the ADC circuitry 100.

Example methods are described with reference to the flowchart illustrated in FIG. 9. However, many other methods of implementing the calibration circuitry 215 of FIGS. 2, 4, and 6, the offset correction circuitry 715 of FIG. 7, or more generally the delay ADC circuitry 155, 160, 165, 200 of FIGS. 1 and 2 and the calibration controller circuitry 170, 235 of FIGS. 1, 2, and 7 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

FIG. 10 is a flowchart representative of example machine-readable instructions or example operations 1000 that may be at least one of executed, instantiated, or performed using example implementations of the calibration circuitry 215 of FIGS. 2, 4, and 6, the gain correction circuitry 720 of FIG. 7, or more generally the delay ADC circuitry 155, 160, 165, 200 of FIGS. 1 and 2 and the calibration controller circuitry 170, 235 of FIGS. 1, 2, and 7.

The example operations 1000 of FIG. 10 begin at Block 1005, the DAC code circuitry 730 of FIG. 7 sets a DAC code of the calibration DAC to a reference value. In example operations, the DAC code circuitry 730 controls the analog output of the DAC circuitry 725 responsive to supplying a DAC code. In such example operations, the DAC circuitry 725 generates an analog output having a voltage corresponding to the DAC code of the DAC code circuitry 730. In some examples, the reference DAC code corresponds to an analog output having a voltage near a maximum voltage of the DAC circuitry 725. For example, the reference value corresponds to an analog voltage ninety percent of the largest differential voltage between the plus and minus DAC signals (DACP, DACM).

The DAC common mode code circuitry 735 of FIG. 7 sets a DAC common mode code of the calibration DAC to an initial value. (Block 1010). In example operations, the DAC common mode code circuitry 735 controls the common mode voltage of the DAC circuitry 725. In such example operations, the DAC circuitry 725 generates an analog output having a common mode voltage corresponding to the DAC common mode code of the DAC common mode code circuitry 735. In some examples, the initial value of the DAC common mode code circuitry 735 corresponds to the lowest possible common mode voltage of the DAC circuitry 725. In other examples, the initial value of the DAC common mode code circuitry 735 corresponds to the highest possible common mode voltage of the DAC circuitry 725. In yet another example, the initial value of the DAC common mode code circuitry 735 corresponds to a common mode voltage in the middle of the range of the DAC circuitry 725.

The gain controller circuitry 770 of FIG. 7 determines a first digital value at the output of the TDC responsive to the DAC common mode code. (Block 1015). In example operations, the amplifier circuitry 208, the V2D circuitry 220, and the pulse generator circuitry 225 generate plus and minus delay signals (PULSE_OUTP, PULSE_OUTM) responsive to the analog output of the DAC circuitry 725. In such example operations, the TDC circuitry 230 outputs a digital value representing the delay between the plus and minus delay signals (PULSE_OUTP, PULSE_OUTM). Ideally the digital value corresponds to the DAC code of the DAC common mode code circuitry 735. However, at least one of the amplifier circuitry 208, the V2D circuitry 220, the pulse generator circuitry 225, and the TDC circuitry 230 may amplify the common mode voltage. The gain controller circuitry 770 stores the first digital value.

The DAC common mode code circuitry 735 increases the DAC common mode code by a step value. (Block 1020). In some examples, the gain of at least one of the amplifier circuitry 208, the V2D circuitry 220, the pulse generator circuitry 225, and the TDC circuitry 230 may be dependent on the common mode voltage of the plus and minus DAC signals (DACP, DACM). In some examples, the DAC common mode code circuitry 735 sweeps possible common mode voltages of the plus and minus DAC signals (DACP, DACM). In such examples, during a sweep of possible common mode voltages, the DAC common mode code circuitry 735 increments the DAC common mode code by a step value across the range of possible common mode voltages. For example, the DAC common mode code circuitry 735 may decrease the DAC common mode code by ten millivolts (mV).

The gain controller circuitry 770 determines a second digital value at the output of the TDC responsive to the DAC common mode code. (Block 1025). In example operations, the amplifier circuitry 208, the V2D circuitry 220, and the pulse generator circuitry 225 generate plus and minus delay signals (PULSE_OUTP, PULSE_OUTM) responsive to the analog output of the DAC circuitry 725. In such example operations, the TDC circuitry 230 outputs a digital value representing the delay between the plus and minus delay signals (PULSE_OUTP, PULSE_OUTM). Ideally, the digital value corresponds to the DAC code of the DAC common mode code circuitry 735. However, at least one of the amplifier circuitry 208, the V2D circuitry 220, the pulse generator circuitry 225, and the TDC circuitry 230 may amplify the common mode voltage. The gain controller circuitry 770 stores the second digital value.

The DAC common mode code circuitry 735 decreases the original DAC common mode code by the step value. (Block 1030). In some examples, the DAC common mode code circuitry 735 sweeps possible common mode voltages of the plus and minus DAC signals (DACP, DACM). In such examples, during a sweep of possible common mode voltages, the DAC common mode code circuitry 735 increments the DAC common mode code by a step value across the range of possible common mode voltages. For example, the DAC common mode code circuitry 735 may decrease the DAC common mode code by ten millivolts.

The gain controller circuitry 770 determines a third digital value at the output of the TDC responsive to the DAC common mode code. (Block 1035). In example operations, the amplifier circuitry 208, the V2D circuitry 220, and the pulse generator circuitry 225 generate plus and minus delay signals (PULSE_OUTP, PULSE_OUTM) responsive to the analog output of the DAC circuitry 725. In such example operations, the TDC circuitry 230 outputs a digital value representing the delay between the plus and minus delay signals (PULSE_OUTP, PULSE_OUTM). Ideally, the digital value corresponds to the DAC code of the DAC common mode code circuitry 735. However, at least one of the amplifier circuitry 208, the V2D circuitry 220, the pulse generator circuitry 225, and the TDC circuitry 230 may amplify the common mode voltage. The gain controller circuitry 770 stores the third digital value.

The plus DAC code circuitry 775 of FIG. 7 determines a first difference between the second digital value and the first digital value. (Block 1040). In example operations, the plus DAC code circuitry 775 determines a first difference between the digital value from Block 1015 and the digital value from the Block 1025 as a first change in the gain. The first difference represents a change in the output of the TDC circuitry 230 responsive to the DAC common mode code circuitry 735 increasing the DAC common mode code, from Block 1015, by the step value.

The minus DAC code circuitry 780 of FIG. 7 determines a second difference between the third digital value and the first digital value. (Block 1045). In example operations, the minus DAC code circuitry 780 determines a second difference between the digital value from Block 1015 and the digital value from the Block 1035 as a second change in the gain. The second difference represents a change in the output of the TDC circuitry 230 responsive to the DAC common mode code circuitry 735 decreasing the DAC common mode code, from Block 1015, by the step value.

The minimum DAC code circuitry 785 of FIG. 7 determines an absolute value of the greater one of the first or second differences. (Block 1050). In example operations, the minimum DAC code circuitry 785 takes the absolute values of the first difference from Block 1040 and the second difference from Block 1045. The minimum DAC code circuitry 785 determines a minimum common mode DAC code responsive to determining which of the differences are greater. In such example operations, the common mode gain of the delay domain ADC circuitry 150 has convex characteristics. Advantageously, the greater change at the output of the TDC circuitry 230 corresponds to the local minimum of the common mode gain curve.

The gain controller circuitry 770 determines if the determined absolute value is greater than a previously determined absolute value. (Block 1055). In example operations, the gain controller circuitry 770 compares the determined minimum common mode DAC code to a previously determined minimum DAC code. In such example operations, the gain control circuitry 770 may determine the true minimum DAC code across the range of the DAC circuitry 725.

If the gain controller circuitry 770 determines that the determined absolute value is not greater than the previously determined absolute value (e.g., Block 1055 returns a result of NO), the gain correction circuitry 790 of FIG. 7 updates a gain correction value based on the determined absolute value. (Block 1060). In example operation, the gain correction circuitry 790 adjusts at least one of the gain control signal (GAIN_{CNTRL}), the first gain trim value (GAIN_{TRIM_T1}), or the second gain trim value (GAIN_{TRIM_T2}) to adjust the gain of the calibration circuitry 215. In some examples, the gain control signal (GAIN_{CNTRL}) adjusts the current of the current source circuitry 615 of FIG. 6 to adjust the gain of the amplifier circuitry 421. In other examples, the gain trim values adjust the gain of the calibration circuitry 215 responsive to adjusting the size of the transistors 245, 250, 424, 427. In yet another example, the gain correction circuitry 790 adjusts the gain control signal (GAIN_{CNTRL}) and the gain trim values. Advantageously, adjusting one or more of the gain control signal (GAIN_{CNTRL}) or the gain trim values adjusts the gain of the calibration circuitry 215. Advantageously, as illustrated in Equation (2), adjusting the common mode gain of the amplifier circuitry 204, 208 using the calibration circuitry 215 allows the calibration controller circuitry 235 to control the CMRR of the delay domain ADC circuitry 150.

If the gain controller circuitry 770 determines that the determined absolute value is greater than the previously determined absolute value (e.g., Block 1055 returns a result of YES), control proceeds from Block 1060, the DAC common mode code circuitry 735 determines if all DAC common mode codes have been tested. (Block 1065).

If the DAC common mode code circuitry 735 determines that not all DAC common mode codes have been tested (e.g., Block 1065 returns a result of NO), the DAC common mode code circuitry 735 adjusts the DAC common mode code of the calibration DAC. (Block 1070). In some examples, the DAC common mode code circuitry 735 sweeps all possible DAC common mode codes during calibration. In such examples, the DAC common mode code circuitry 735 continues to calibrate the delay domain ADC circuitry 150 until an ideal CMRR is achieved. Control proceeds to return to Block 1015. If the DAC common mode code circuitry 735 determines that all DAC codes have been tested (e.g., Block 1065 returns a result of YES), control proceeds to return.

Advantageously, setting the common mode voltage to the calibrated reference input common mode voltage reduces common mode offset and reduces common mode gain across the delay ADC circuitry 155, 160, 165, 200. Advantageously, decreasing the common mode offset and common mode gain improves the CMRR of the delay ADC circuitry 155, 160, 165, 200. Advantageously, improving the CMRR of the delay ADC circuitry 155, 160, 165, 200 increases the overall accuracy of the ADC circuitry 100.

Example methods are described with reference to the flowchart illustrated in FIG. 9. However, many other methods of implementing the calibration circuitry 215 of FIGS. 2, 4, and 6, the gain correction circuitry 720 of FIG. 7, or more generally the delay ADC circuitry 155, 160, 165, 200 of FIGS. 1 and 2 and the calibration controller circuitry 170, 235 of FIGS. 1, 2, and 7 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

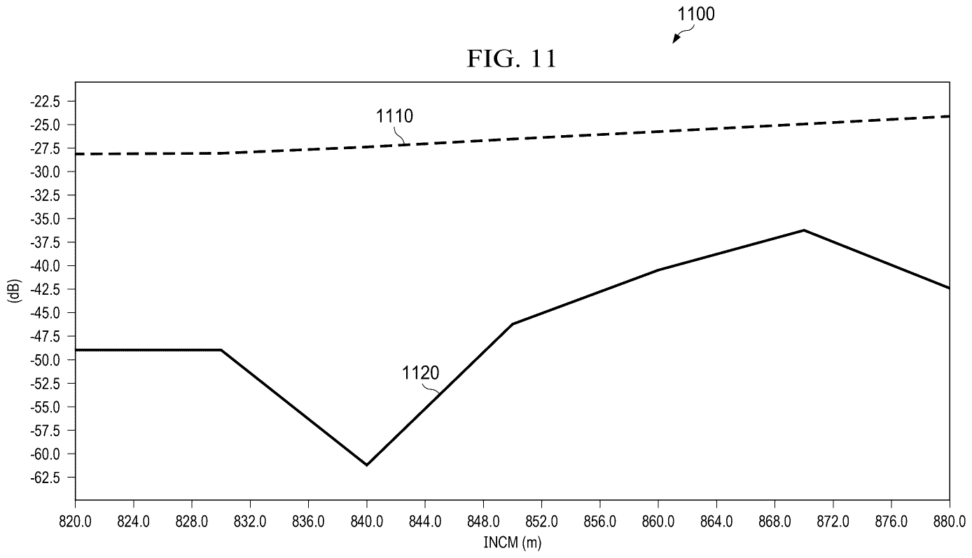

FIG. 11 is a plot 1100 of an example common mode rejection ratio (CMRR) of the V2D circuitry 220 of FIGS. 2 and 4 with and without the calibration operations 900, 1000 of FIGS. 9 and 10. The example plot 1100 of FIG. 11 illustrates an uncalibrated CMRR 1110 and a calibrated CMRR 1120 across different common mode voltages (INCM). The uncalibrated CMRR 1110 represents the noise resulting from CMRR for the delay domain ADC circuitry 150 without the calibration circuitry 215. The calibrated CMRR 1120 represents the noise resulting from CMRR for the delay domain ADC circuitry 150 with the calibration circuitry 215 after the operations 900, 1000 of FIGS. 9 and 10. The uncalibrated CMRR 1110 has higher noise across the range of difference common mode voltages in comparison to the calibrated CMRR 1120. Advantageously, the calibration circuitry 215 and the operations 900, 1000 reduce the noise resulting from different common mode voltages.

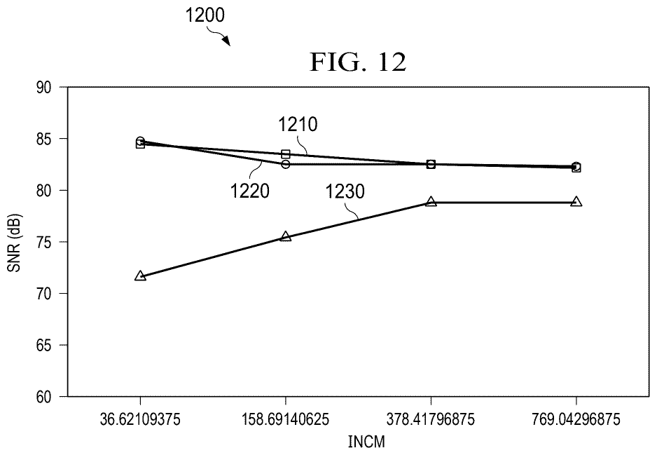

FIG. 12 is a plot 1200 of example performance of the delay ADC circuitry of FIGS. 2 and 4 with and without the calibration operations 900, 1000 of FIGS. 9 and 10. The plot 1200 of FIG. 12 illustrates a first calibrated sound to noise ratio (SNR) 1210, a second calibrated SNR 1220, and an uncalibrated SNR 1230 across different common mode voltages (INCM). In the example of FIG. 12, the Y-axis represents the sound to noise ratio (in decibels) and the X-axis represents an input common mode voltage (INCM). The calibrated SNRs 1210, 1220 represent operations of the delay domain ADC circuitry 150 with the calibration circuitry 215 and the operations 900, 1000. The uncalibrated SNR 1230 represents operations of the delay domain ADC circuitry 150 without the calibration circuitry 215 or the operations 900, 1000. Advantageously, the calibration circuitry 215 and the operations 900, 1000 reduce the noise resulting from different common mode voltages.

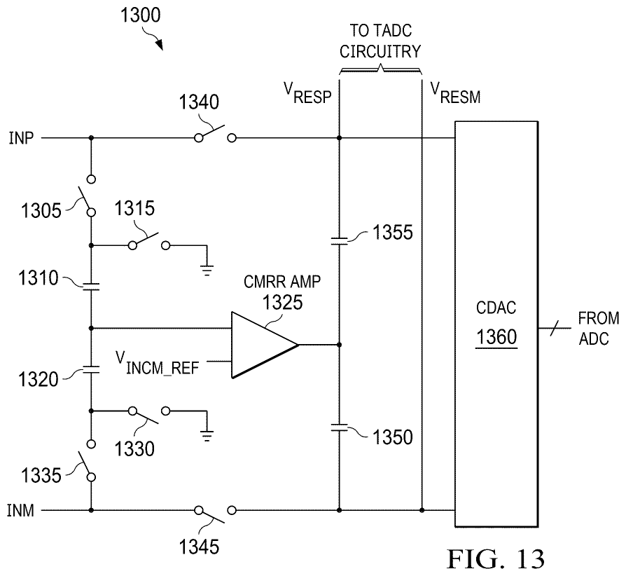

FIG. 13 is a schematic diagram of example ADC circuitry 1300, which illustrates an alternative implementation of the calibration circuitry 215 of FIGS. 2, 4, and 6. The example ADC circuitry 1300 of FIG. 13 includes a first example switch 1305, a first example capacitor 1310, a second example switch 1315, a second example capacitor 1320, example amplifier circuitry 1325, a third example switch 1330, a fourth example switch 1335, a fifth example switch 1340, a sixth example switch 1345, a third example capacitor 1350, a fourth example capacitor 1355, and an example CDAC 1360. Unlike the calibration circuitry 215 of FIGS. 2, 4, and 6, the amplifier circuitry 1325 implements the CMRR corrections by controlling the voltage between the capacitors 1350, 1355. In the example of FIG. 13, the amplifier circuitry 1325 is an implementation of the amplifier circuitry 421 of FIGS. 4 and 6. Example operations of the amplifier circuitry 1325 are further illustrated and described below.

The ADC circuitry 1300 has a first input, a second input, a third input, a first output, and a second output. The first input of the ADC circuitry 1300 (INP) is structured to be coupled to external circuitry, which supplies an analog signal. The second input of the ADC circuitry 1300 (INM) is structured to be coupled to external circuitry. The third input of the ADC circuitry 1300 is structured to be coupled to an ADC (e.g., the ADC 125), which provides digital bits. The first and second outputs of the ADC circuitry 1300 (V_{RESP}, V_{RESM}) are structured to be coupled to the delay domain ADC circuitry 150 of FIG. 1. In the example of FIG. 13, the ADC circuitry 1300 includes a first stage of an analog-to-digital conversion. Specifically, an illustration of a utilization of the amplifier circuitry 421 of the calibration circuitry 215 in a first stage as the amplifier circuitry 1325.

The switch 1305 has a first terminal and a second terminal. The first terminal of the switch 1305 is coupled to the switch 1340 and the first input of the ADC circuitry 1300 (INP). The second terminal of the switch 1305 is coupled to the capacitor 1310 and the switch 1315.

The capacitor 1310 has a first terminal and a second terminal. The first terminal of the capacitor 1310 is coupled to the switches 1305, 1315. The second terminal of the capacitor 1310 is coupled to the capacitor 1320 and the amplifier circuitry 1325.

The switch 1315 has a first terminal and a second terminal. The first terminal of the switch 1315 is coupled to the switch 1305 and the capacitor 1310. The second terminal of the switch 1315 is coupled to the common terminal, which provides the common potential.

The capacitor 1320 has a first terminal and a second terminal. The first terminal of the capacitor 1320 is coupled to the capacitor 1310 and the amplifier circuitry 1325. The second terminal of the capacitor 1320 is coupled to the switches 1330, 1335.

The amplifier circuitry 1325 has a first input, a second input, and an output. The first input of the amplifier circuitry 1325 is coupled to the capacitors 1310, 1320. The second input of the amplifier circuitry 1325 is structured to be coupled to the calibration controller circuitry 235, which provides the reference input common mode voltage (V_{INCM_REF}). The output of the amplifier circuitry 1325 is coupled to the capacitors 1350, 1355. The amplifier circuitry 1325 is an example implementation of the amplifier circuitry 421 in the first stage of the ADC circuitry 1300.

The switch 1330 has a first terminal and a second terminal. The first terminal of the switch 1330 is coupled to the capacitor 1320 and the switch 1335. The second terminal of the switch 1330 is coupled to the common terminal, which provides a common potential.

The switch 1335 has a first terminal and a second terminal. The first terminal of the switch 1335 is coupled to the capacitor 1320 and the switch 1330. The second terminal of the switch 1335 is coupled to the switch 1345 and the second input of the ADC circuitry 1300 (INM).

The switch 1340 has a first terminal and a second terminal. The first terminal of the switch 1340 is coupled to the switch 1305 and the first input of the ADC circuitry 1300 (INP). The second terminal of the switch 1340 is coupled to the capacitor 1355, the CDAC 1360, and the first output of the ADC circuitry 1300 (V_{RESP}).

The switch 1345 has a first terminal and a second terminal. The first terminal of the switch 1345 is coupled to the switch 1335 and the second input of the ADC circuitry 1300 (INM). The second terminal of the switch 1345 is coupled to the capacitor 1350, the CDAC 1360, and the second output of the ADC circuitry 1300 (V_{RESM}).

The capacitor 1350 has a first terminal and a second terminal. The first terminal of the capacitor 1350 is coupled to the amplifier circuitry 1325 and the capacitor 1355. The second terminal of the capacitor 1350 is coupled to the switch 1345, the CDAC 1360, and the second output of the ADC circuitry 1300 (V_{RESM}).

The capacitor 1355 has a first terminal and a second terminal. The first terminal of the capacitor 1355 is coupled to the amplifier circuitry 1325 and the capacitor 1350. The second terminal of the capacitor 1355 is coupled to the switch 1340, the CDAC 1360, and the first output of the ADC circuitry (V_{RESP}).

The CDAC 1360 has inputs, a first output, and a second output. The inputs of the CDAC 1360 are coupled to the third input of the ADC circuitry 1300. The first output of the CDAC 1360 is coupled to the switch 1340, the capacitor 1355, and the first output of the ADC circuitry 1300 (V_{RESP}). The second output of the CDAC 1360 is coupled to the switch 1345, the capacitor 1350, and the second output of the ADC circuitry 1300 (V_{RESP}).

In example operation, the switches 1305, 1315, 1330, 1335, 1340, 1345 sample and hold the first and second inputs of the ADC circuitry 1300 (INP, INM) across the capacitors 1310, 1320. The capacitors 1310, 1320 divide the voltages of the first and second inputs of the ADC circuitry 1300 to provide an input common mode voltage to the amplifier circuitry 1325. The amplifier circuitry 1325 compares the input common mode voltage from the capacitors 1310, 1320 to the reference input common mode voltage from the calibration controller circuitry 235. The capacitors 1350, 1355 set the common mode voltage of the first and second outputs of the ADC circuitry 1300 (V_{RESP}, V_{RESM}) responsive to the comparison by the amplifier circuitry 1325. In the examples described above, the transistors 245, 250 compensate for errors resulting from the input common mode voltage by sinking current. Such corrections after the input common mode voltage traverses the amplifier 204 may be referred to as corrections occurring after the error is introduced. In the example of FIG. 13, the amplifier circuitry 1325 compensates for errors resulting from the input common mode voltage responsive to adjusting the input common mode voltage as set by the capacitors 1350, 1355. Such corrections may be considered preemptive compensation. Advantageously, the amplifier circuitry 1325 improves the CMRR of the ADC circuitry 1300 by correcting the input common mode voltage based on the reference input common mode voltage. Advantageously, the amplifier circuitry 1325 and the capacitors 1350, 1355 corrects the output common mode voltage of the CDAC 1360.

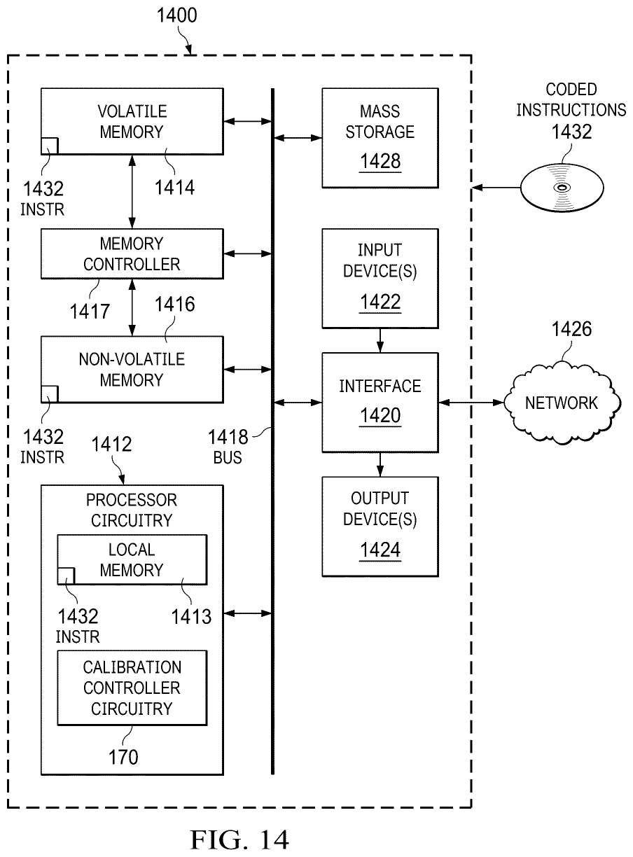

FIG. 14 is a block diagram of an example programmable circuitry platform 1400 structured to one or a combination of execute or instantiate one or more of the example machine-readable instructions or the example operations of FIGS. 8, 9, and 10 to implement the calibration controller circuitry 170 of FIGS. 1 and 7. The programmable circuitry platform 1400 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing or electronic device.

The programmable circuitry platform 1400 of the illustrated example includes programmable circuitry 1412. The programmable circuitry 1412 of the illustrated example is hardware. For example, the programmable circuitry 1412 can be implemented by one or more integrated circuits, logic circuits, FPGAs, microprocessors, CPUs, GPUs, DSPs, or microcontrollers from any desired family or manufacturer. The programmable circuitry 1412 may be implemented by one or more semiconductor based (e.g., silicon based) devices. In this example, the programmable circuitry 1412 implements the calibration controller circuitry 235, or more generally the calibration controller circuitry 170. In another example, a block in programmable circuitry platform 1400 may engage in at least one of controlling or interfacing with the delay ADC circuitry 155, 160, 165, 200 implements the calibration controller circuitry 170. In yet another example, a block in programmable circuitry platform 1400 engaged in engage in at least one of controlling or interfacing with the delay ADC circuitry 155, 160, 165, 200 executes some or all of the machine-readable instructions of the flowcharts of FIGS. 8, 9, and 10.

The programmable circuitry 1412 of the illustrated example includes a local memory 1413 (e.g., a cache, registers, etc.). The programmable circuitry 1412 of the illustrated example is in communication with main memory 1414, 1416, which includes a volatile memory 1414 and a non-volatile memory 1416, by a bus 1418. The volatile memory 1414 may be implemented by one or more Synchronous Dynamic Random Access Memory (SDRAM), Dynamic Random Access Memory (DRAM), RAMBUS® Dynamic Random Access Memory (RDRAM®), or any other type of RAM device. The non-volatile memory 1416 may be implemented by one or a combination of flash memory or any other desired type of memory device. Access to the main memory 1414, 1416 of the illustrated example is controlled by a memory controller 1417. In some examples, the memory controller 1417 may be implemented by one or more integrated circuits, logic circuits, microcontrollers from any desired family or manufacturer, or any other type of circuitry to manage the flow of data going to and from the main memory 1414, 1416.

The programmable circuitry platform 1400 of the illustrated example also includes interface circuitry 1420. The interface circuitry 1420 may be implemented by hardware in according to any type of interface standard, such as an Ethernet interface, a universal serial bus (USB) interface, a Bluetooth® interface, a near field communication (NFC) interface, a Peripheral Component Interconnect (PCI) interface, or a Peripheral Component Interconnect Express (PCIe) interface.

In the illustrated example, one or more input devices 1422 are connected to the interface circuitry 1420. The input device(s) 1422 permit(s) a user (e.g., a human user, a machine user, etc.) to enter one of or a combination of data or commands into the programmable circuitry 1412. The input device(s) 1422 can be implemented by, for example, one of or a combination of an audio sensor, a microphone, a camera (still or video), a keyboard, a button, a mouse, a touchscreen, a trackpad, a trackball, an isopoint device, or a voice recognition system.

One or more output devices 1424 are also connected to the interface circuitry 1420 of the illustrated example. The output device(s) 1424 can be implemented, for example, by one of or a combination of display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, or speaker. The interface circuitry 1420 of the illustrated example, thus, includes one of or a combination of a graphics driver card, a graphics driver chip, or graphics processor circuitry such as a GPU.

The interface circuitry 1420 of the illustrated example also includes a communication device such as one of or a combination of a transmitter, a receiver, a transceiver, a modem, a residential gateway, a wireless access point, or a network interface to facilitate exchange of data with external machines (e.g., computing devices of any kind) by a network 1426. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 1400 of the illustrated example also includes one or more mass storage discs or devices 1428 to store one or more of firmware, software, or data. Examples of such mass storage discs or devices 1428 include one or more magnetic storage devices (e.g., floppy disk, drives, HDDs, etc.), optical storage devices (e.g., Blu-ray disks, CDs, DVDs, etc.), RAID systems, or solid-state storage discs or devices such as flash memory devices and SSDs.

The machine-readable instructions 1432, which may be implemented by the machine-readable instructions of FIGS. 8, 9, and 10, may be stored in one of or a combination of the mass storage device 1428, in the volatile memory 1414, in the non-volatile memory 1416, or on at least one non-transitory computer readable storage medium such as a CD or DVD which may be removable.

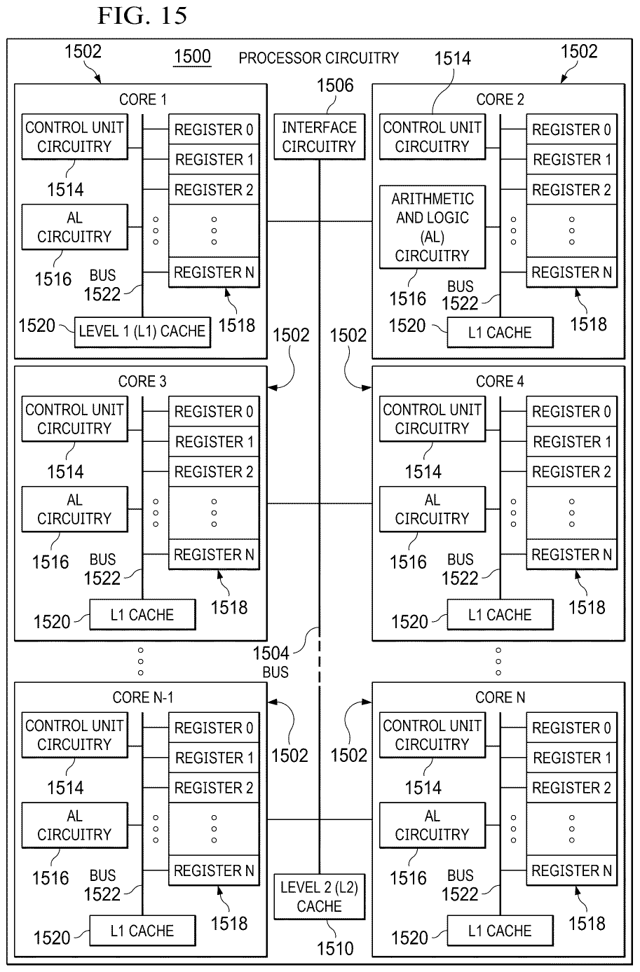

FIG. 15 is a block diagram of an example implementation of the programmable circuitry 1412 of FIG. 14. In this example, the programmable circuitry 1412 of FIG. 14 is implemented by a microprocessor 1500. For example, the microprocessor 1500 may be a general-purpose microprocessor (e.g., general-purpose microprocessor circuitry). The microprocessor 1500 executes some or all of the machine-readable instructions of the flowcharts of FIGS. 8, 9, and 10 to effectively instantiate the circuitry of FIG. 2 as logic circuits to perform operations corresponding to those machine-readable instructions. In some such examples, the circuitry of FIGS. 1 and 7 is instantiated by the hardware circuits of the microprocessor 1500 in combination with the machine-readable instructions. For example, the microprocessor 1500 may be implemented by multi-core hardware circuitry such as a CPU, a DSP, a GPU, an XPU, etc. Although it may include any number of example cores 1502 (e.g., 1 core), the microprocessor 1500 of this example is a multi-core semiconductor device including N cores. The cores 1502 of the microprocessor 1500 may operate independently or may cooperate to execute machine-readable instructions. For example, machine code corresponding to a firmware program, an embedded software program, or a software program may be executed by one of the cores 1502 or may be executed by multiple ones of the cores 1502 at the same or different times. In some examples, the machine code corresponding to the firmware program, the embedded software program, or the software program is split into threads and executed in parallel by two or more of the cores 1502. The software program may correspond to a portion or all of the machine-readable instructions or operations represented by the flowcharts of FIGS. 8, 9, and 10.

The cores 1502 may communicate by a first example bus 1504. In some examples, the first bus 1504 may be implemented by a communication bus to effectuate communication associated with one(s) of the cores 1502. For example, the first bus 1504 may be implemented by at least one of an Inter-Integrated Circuit (I2C) bus, a Serial Peripheral Interface (SPI) bus, a PCI bus, or a PCIe bus. Also or alternatively, the first bus 1504 may be implemented by any other type of computing or electrical bus. The cores 1502 may obtain data, instructions, and signals from one or more external devices by example interface circuitry 1506. The cores 1502 may output data, instructions, and signals to the one or more external devices by the interface circuitry 1506. Although the cores 1502 of this example include example local memory 1520 (e.g., Level 1 (L1) cache that may be split into an L1 data cache and an L1 instruction cache), the microprocessor 1500 also includes example shared memory 1510 that may be shared by the cores (e.g., Level 2 (L2 cache)) for high-speed access to data and instructions. Data and instructions may be transferred (e.g., shared) by one of or a combination of writing to or reading from the shared memory 1510. The local memory 1520 of each of the cores 1502 and the shared memory 1510 may be part of a hierarchy of storage devices including multiple levels of cache memory and the main memory (e.g., the main memory 1414, 1416 of FIG. 14). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 1502 may be referred to as a CPU, DSP, GPU, etc., or any other type of hardware circuitry. Each core 1502 includes control unit circuitry 1514, arithmetic and logic (AL) circuitry (sometimes referred to as an ALU) 1516, a plurality of registers 1518, the local memory 1520, and a second example bus 1522. Other structures may be present. For example, each core 1502 may include vector unit circuitry, single instruction multiple data (SIMD) unit circuitry, load/store unit (LSU) circuitry, branch/jump unit circuitry, floating-point unit (FPU) circuitry, etc. The control unit circuitry 1514 includes semiconductor-based circuits structured to control (e.g., coordinate) data movement within the corresponding core 1502. The AL circuitry 1516 includes semiconductor-based circuits structured to perform one or more mathematic or logic operations on the data within the corresponding core 1502. The AL circuitry 1516 of some examples performs integer-based operations. In other examples, the AL circuitry 1516 also performs floating-point operations. In yet other examples, the AL circuitry 1516 may include first AL circuitry that performs integer-based operations and second AL circuitry that performs floating-point operations. In some examples, the AL circuitry 1516 may be referred to as an Arithmetic Logic Unit (ALU).

The registers 1518 are semiconductor-based structures to store data and instructions such as results of one or more of the operations performed by the AL circuitry 1516 of the corresponding core 1502. For example, the registers 1518 may include vector register(s), SIMD register(s), general-purpose register(s), flag register(s), segment register(s), machine-specific register(s), instruction pointer register(s), control register(s), debug register(s), memory management register(s), machine check register(s), etc. The registers 1518 may be arranged in a bank as shown in FIG. 15. Alternatively, the registers 1518 may be organized in any other arrangement, format, or structure, such as by being distributed throughout the core 1502 to shorten access time. The second bus 1522 may be implemented by at least one of an I2C bus, a SPI bus, a PCI bus, or a PCIe bus.

Each core 1502 or, more generally, the microprocessor 1500 may include additional or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) or other circuitry may be present. The microprocessor 1500 is a semiconductor device fabricated to include many transistors interconnected to implement the structures described above in one or more integrated circuits (ICs) contained in one or more packages.

The microprocessor 1500 may include or cooperate with one or more accelerators (e.g., acceleration circuitry, hardware accelerators, etc.). In some examples, accelerators are implemented by logic circuitry to perform certain tasks more quickly and efficiently than can be done by a general-purpose processor. Examples of accelerators include ASICs and FPGAs such as those discussed herein. A GPU, DSP, or other programmable device can also be an accelerator. Accelerators may be on-board the microprocessor 1500, in the same chip package as the microprocessor 1500, or in one or more separate packages from the microprocessor 1500.

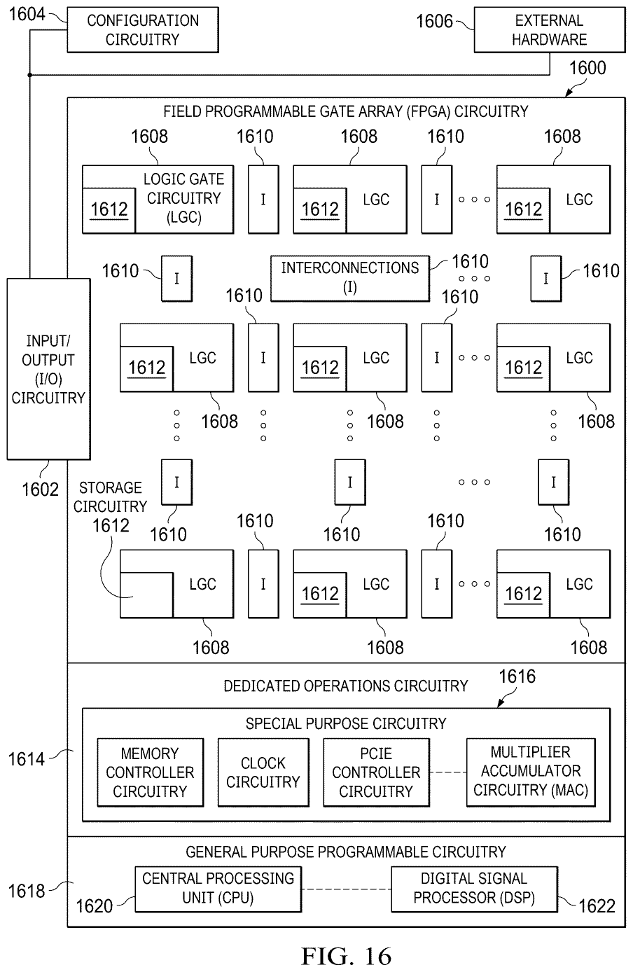

FIG. 16 is a block diagram of another example implementation of the programmable circuitry 1412 of FIG. 14. In this example, the programmable circuitry 1412 is implemented by FPGA circuitry 1600. For example, the FPGA circuitry 1600 may be implemented by an FPGA. The FPGA circuitry 1600 can be used, for example, to perform operations that could otherwise be performed by the example microprocessor 1500 of FIG. 15 executing corresponding machine-readable instructions. However, once configured, the FPGA circuitry 1600 instantiates the operations and functions corresponding to the machine-readable instructions in hardware and, thus, can often execute the operations/functions faster than they could be performed by a general-purpose microprocessor executing the corresponding software.

More specifically, in contrast to the microprocessor 1500 of FIG. 15 described above (which is a general purpose device that may be programmed to execute some or all of the machine-readable instructions represented by the flowchart(s) of FIGS. 8, 9, and 10 but whose interconnections and logic circuitry are fixed once fabricated), the FPGA circuitry 1600 of the example of FIG. 16 includes interconnections and logic circuitry that may be one of or a combination of configured, structured, programmed, and interconnected in different ways after fabrication to instantiate, for example, some or all of the operations/functions corresponding to the machine-readable instructions represented by the flowchart(s) of FIGS. 8, 9, and 10. In particular, the FPGA circuitry 1600 may be thought of as an array of logic gates, interconnections, and switches. The switches can be programmed to change how the logic gates are interconnected by the interconnections, effectively forming one or more dedicated logic circuits (unless and until the FPGA circuitry 1600 is reprogrammed). The configured logic circuits enable the logic gates to cooperate in different ways to perform different operations on data received by input circuitry. Those operations may correspond to some or all of the instructions (e.g., the software and/or firmware) represented by the flowchart(s) of FIGS. 8, 9, and 10. As such, the FPGA circuitry 1600 may be at least one of configured or structured to effectively instantiate some or all of the operations/functions corresponding to the machine-readable instructions of the flowchart(s) of FIGS. 8, 9, and 10 as dedicated logic circuits to perform the operations/functions corresponding to those software instructions in a dedicated manner analogous to an ASIC. Therefore, the FPGA circuitry 1600 may perform the operations/functions corresponding to the some or all of the machine-readable instructions of FIGS. 8, 9, and 10 faster than the general-purpose microprocessor can execute the same.

In the example of FIG. 16, the FPGA circuitry 1600 is at least one of configured or structured in response to being programmed (and/or reprogrammed one or more times) based on a binary file. In some examples, the binary file may be one of or both of compiled or generated based on instructions in a hardware description language (HDL) such as Lucid, Very High-Speed Integrated Circuits (VHSIC) Hardware Description Language (VHDL), or Verilog. For example, a user (e.g., a human user, a machine user, etc.) may write code or a program corresponding to one or more operations/functions in an HDL; the code/program may be translated into a low-level language as needed; and the code/program (e.g., the code/program in the low-level language) may be converted (e.g., by a compiler, a software application, etc.) into the binary file. In some examples, the FPGA circuitry 1600 of FIG. 16 may at least one of access or load the binary file to cause the FPGA circuitry 1600 of FIG. 16 to be at least one of configured or structured to perform the one or more operations/functions. For example, the binary file may be implemented by one of or a combination of a bit stream (e.g., one or more computer-readable bits, one or more machine-readable bits, etc.), data (e.g., computer-readable data, machine-readable data, etc.), or machine-readable instructions accessible to the FPGA circuitry 1600 of FIG. 16 to at least one of configure or structure the FPGA circuitry 1600 of FIG. 16, or portion(s) thereof.

In some examples, the binary file is at least one of compiled, generated, transformed, or otherwise output from a uniform software platform utilized to program FPGAs. For example, the uniform software platform may translate first instructions (e.g., code or a program) that correspond to one or more operations/functions in a high-level language (e.g., C, C++, Python, etc.) into second instructions that correspond to the one or more operations/functions in an HDL. In some such examples, the binary file is at least one of compiled, generated, or otherwise output from the uniform software platform based on the second instructions. In some examples, the FPGA circuitry 1600 of FIG. 16 may at least one of access or load the binary file to cause the FPGA circuitry 1600 of FIG. 16 to be at least one of configured or structured to perform the one or more operations/functions. For example, the binary file may be implemented by one of or a combination of a bit stream (e.g., one or more computer-readable bits, one or more machine-readable bits, etc.), data (e.g., computer-readable data, machine-readable data, etc.), or machine-readable instructions accessible to the FPGA circuitry 1600 of FIG. 16 to at least one of configure or structure the FPGA circuitry 1600 of FIG. 16, or portion(s) thereof.

The FPGA circuitry 1600 of FIG. 16, includes example input/output (I/O) circuitry 1602 to at least one of obtain or output data to/from at least one of example configuration circuitry 1604 or external hardware 1606. For example, the configuration circuitry 1604 may be implemented by interface circuitry that may obtain a binary file, which may be implemented by one or more of a bit stream, data, or machine-readable instructions, to configure the FPGA circuitry 1600, or portion(s) thereof. In some such examples, the configuration circuitry 1604 may obtain the binary file from one of or a combination of a user, a machine (e.g., hardware circuitry (e.g., programmable or dedicated circuitry) that may implement an Artificial Intelligence/Machine Learning (AI/ML) model to generate the binary file, etc.), or any combination(s) thereof). In some examples, the external hardware 1606 may be implemented by external hardware circuitry. For example, the external hardware 1606 may be implemented by the microprocessor 1500 of FIG. 15.

The FPGA circuitry 1600 also includes an array of example logic gate circuitry 1608, a plurality of example configurable interconnections 1610, and example storage circuitry 1612. The logic gate circuitry 1608 and the configurable interconnections 1610 are configurable to instantiate one or more operations/functions that may correspond to at least some of the machine-readable instructions of FIGS. 8, 9, and 10 and/or other desired operations. The logic gate circuitry 1608 shown in FIG. 16 is fabricated in blocks or groups. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 1608 to enable configuration of one of or a combination of the electrical structures or the logic gates to form circuits to perform desired operations/functions. The logic gate circuitry 1608 may include other electrical structures such as look-up tables (LUTs), registers (e.g., flip-flops or latches), multiplexers, etc.

The configurable interconnections 1610 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 1608 to program desired logic circuits.

The storage circuitry 1612 of the illustrated example is structured to store result(s) of the one or more of the operations performed by corresponding logic gates. The storage circuitry 1612 may be implemented by registers or the like. In the illustrated example, the storage circuitry 1612 is distributed amongst the logic gate circuitry 1608 to facilitate access and increase execution speed.

The example FPGA circuitry 1600 of FIG. 16 also includes example dedicated operations circuitry 1614. In this example, the dedicated operations circuitry 1614 includes special purpose circuitry 1616 that may be invoked to implement commonly used functions to avoid the need to program those functions in the field. Examples of such special purpose circuitry 1616 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 1600 may also include example general purpose programmable circuitry 1618 such as an example CPU 1620 or an example DSP 1622. Other general purpose programmable circuitry 1618 may also or alternatively be present such as a GPU, an XPU, etc., that can be programmed to perform other operations.

Although FIGS. 15 and 16 illustrate two example implementations of the programmable circuitry 1412 of FIG. 14, many other approaches are contemplated. For example, FPGA circuitry may include an on-board CPU, such as one or more of the example CPU 1620 of FIG. 15. Therefore, the programmable circuitry 1412 of FIG. 14 may also be implemented by combining at least the example microprocessor 1500 of FIG. 15 and the example FPGA circuitry 1600 of FIG. 16. In some such hybrid examples, one or more cores 1502 of FIG. 15 may execute a first portion of the machine-readable instructions represented by the flowchart(s) of FIGS. 8, 9, and 10 to perform first operation(s)/function(s), the FPGA circuitry 1600 of FIG. 16 may be at least one of configured or structured to perform second operation(s)/function(s) corresponding to a second portion of the machine-readable instructions represented by the flowcharts of FIGS. 8, 9, and 10, and/or an ASIC may be at least one of configured or structured to perform third operation(s)/function(s) corresponding to a third portion of the machine-readable instructions represented by the flowcharts of FIGS. 8, 9, and 10.

Some or all of the circuitry of FIGS. 1 and 7 may, thus, be instantiated at the same or different times. For example, same and/or different portion(s) of the microprocessor 1500 of FIG. 15 may be programmed to execute portion(s) of machine-readable instructions at the same and/or different times. In some examples, same and/or different portion(s) of the FPGA circuitry 1600 of FIG. 16 may be at least one of configured or structured to perform operations/functions corresponding to portion(s) of machine-readable instructions at the same and/or different times.

In some examples, some or all of the circuitry of FIGS. 1 and 7 may be instantiated, for example, in one or more threads executing concurrently and/or in series. For example, the microprocessor 1500 of FIG. 15 may execute machine-readable instructions in one or more threads executing concurrently and/or in series. In some examples, the FPGA circuitry 1600 of FIG. 16 may be at least one of configured or structured to carry out operations/functions concurrently and/or in series. Moreover, in some examples, some or all of the circuitry of FIGS. 1 and 7 may be implemented within one or more virtual machines or containers executing on the microprocessor 1500 of FIG. 15.

In some examples, the programmable circuitry 1412 of FIG. 14 may be in one or more packages. For example, at least one of the microprocessor 1500 of FIG. 15 or the FPGA circuitry 1600 of FIG. 16 may be in one or more packages. In some examples, an XPU may be implemented by the programmable circuitry 1412 of FIG. 14, which may be in one or more packages. For example, the XPU may include a CPU (e.g., the microprocessor 1500 of FIG. 15, the CPU 1620 of FIG. 16, etc.) in one package, a DSP (e.g., the DSP 1622 of FIG. 16) in another package, a GPU in yet another package, and an FPGA (e.g., the FPGA circuitry 1600 of FIG. 16) in still yet another package.

While an example manner of implementing the calibration controller circuitry 170 of FIG. 1 is illustrated in FIGS. 1 and 7, one or more of the elements, processes, or devices illustrated in FIGS. 1 and 7 may be combined, divided, re-arranged, omitted, eliminated, or implemented in any other way. Further, the calibration controller circuitry 235, or more generally the calibration controller circuitry 170 of FIGS. 1 and 7, may be implemented by hardware alone or by hardware in combination with software and firmware. Thus, for example, any of the calibration controller circuitry 235, or more generally the calibration controller circuitry 170, could be implemented by programmable circuitry in combination with one or more machine-readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), or field programmable logic device(s) (FPLD(s)) such as FPGAs. Further still, the example calibration controller circuitry 170 of FIGS. 1 and 7 may include one or more elements, processes, or devices in addition to, or instead of, those illustrated in FIGS. 1 and 7, or may include more than one of any or all of the illustrated elements, processes and devices.

Flowchart(s) representative of example machine-readable instructions, which may be executed by programmable circuitry to at least one of implement or instantiate the calibration controller circuitry 170 of FIGS. 1 and 7 or representative of example operations which may be performed by programmable circuitry to at least one of implement or instantiate the calibration controller circuitry 170 of FIGS. 1 and 7, are shown in FIGS. 8, 9, and 10. The machine-readable instructions may be one or more executable programs or portion(s) of one or more executable programs for execution by programmable circuitry such as the programmable circuitry 1412 shown in the example processor platform 1400 discussed below in connection with FIG. 14 and may be one or more function(s) or portion(s) of functions to be performed by the example programmable circuitry (e.g., an FPGA) discussed below in connection with FIG. 15 or 16. In some examples, the machine-readable instructions cause an operation, a task, etc., to be carried out or performed in an automated manner in the real-world. As used herein, “automated” means without human involvement.

The program may be embodied in instructions (e.g., software and/or firmware) stored on one or more non-transitory computer readable and/or machine-readable storage medium such as one of or a combination of cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), or any other storage device or storage disk. The instructions of the non-transitory computer readable and/or machine-readable medium may program or be executed by programmable circuitry located in one or more hardware devices, but the entire program or parts thereof could alternatively be executed or instantiated by one or more hardware devices other than the programmable circuitry or embodied in dedicated hardware. The machine-readable instructions may be distributed across multiple hardware devices or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart(s) illustrated in FIGS. 8, 9, and 10, many other methods of implementing the example calibration controller circuitry 170 may alternatively be used. For example, the order of execution of the blocks of the flowchart(s) may be changed, or some of the blocks described may be changed, eliminated, or combined. Also or alternatively, any or all of the blocks of the flow chart may be implemented by one or more hardware circuits (e.g., processor circuitry, discrete, integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations or local to one or more hardware devices (e.g., a single-core processor (e.g., a single core CPU), a multi-core processor (e.g., a multi-core CPU, an XPU, etc.)). For example, the programmable circuitry may be one of or a combination of a CPU or an FPGA located in the same package (e.g., the same integrated circuit (IC) package or in two or more separate housings), one or more processors in a single machine, multiple processors distributed across multiple servers of a server rack, multiple processors distributed across one or more server racks, etc., or any combination(s) thereof.

The machine-readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, or produce machine executable instructions. For example, the machine-readable instructions may be fragmented and stored on one or more storage devices, disks or computing devices (e.g., servers) located at the same or different locations of a network or collection of networks (e.g., in the cloud, in edge devices, etc.). The machine-readable instructions may require one or more of installation, modification, adaptation, updating, combining, supplementing, configuring, decryption, decompression, unpacking, distribution, reassignment, compilation, etc., in order to make them directly readable, interpretable, or executable by a computing device or other machine. For example, the machine-readable instructions may be stored in multiple parts, which are individually compressed, encrypted, or stored on separate computing devices, wherein the parts when decrypted, decompressed, or combined form a set of one or more computer-executable or machine executable instructions that implement one or more functions or operations that may together form a program such as that described herein.

In another example, the machine-readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine-readable instructions may need to be configured (e.g., settings stored, data input, network addresses recorded, etc.) before the machine-readable instructions or the corresponding program(s) can be executed in whole or in part. Thus, machine-readable, computer readable or machine-readable media, as used herein, may include one or a combination of instructions and program(s) regardless of the particular format or state of the machine-readable instructions or program(s).

The machine-readable instructions described herein can be represented by any past, present, or future instruction language, scripting language, programming language, etc. For example, the machine-readable instructions may be represented using any of the following languages: C, C++, Java, C#, Perl, Python, JavaScript, HyperText Markup Language (HTML), Structured Query Language (SQL), Swift, etc.

As mentioned above, the example operations of FIGS. 8, 9, and 10 may be implemented using executable instructions (e.g., computer readable and/or machine-readable instructions) stored on one or more non-transitory computer readable or machine-readable media. As used herein, the terms non-transitory computer readable medium, non-transitory computer readable storage medium, non-transitory machine-readable medium, and non-transitory machine-readable storage medium are expressly defined to include any type of computer readable storage device or storage disk and to exclude propagating signals and to exclude transmission media. Examples of such non-transitory computer readable medium, non-transitory computer readable storage medium, non-transitory machine-readable medium, or non-transitory machine-readable storage medium include one or more optical storage devices, magnetic storage devices, an HDD, a flash memory, a read-only memory (ROM), a CD, a DVD, a cache, a RAM of any type, a register, or any other storage device or storage disk in which information is stored for any duration (e.g., for extended time periods, permanently, for brief instances, for temporarily buffering, for caching of the information). As used herein, the terms “non-transitory computer readable storage device” and “non-transitory machine-readable storage device” are defined to include any physical (mechanical, magnetic, electromechanical, or electrical) hardware to retain information for a time period, but to exclude propagating signals and to exclude transmission media. Examples of non-transitory computer readable storage devices or non-transitory machine-readable storage devices include one or a combination of random-access memory of any type, read only memory of any type, solid state memory, flash memory, optical discs, magnetic disks, disk drives, or redundant array of independent disks (RAID) systems. As used herein, the term “device” refers to physical structure such as one of or a combination of mechanical, electromechanical, or electrical equipment, hardware, or circuitry that may or may not be configured by computer readable instructions, machine-readable instructions, etc., or manufactured to execute computer-readable instructions, machine-readable instructions, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and things, the phrase “at least one of A and B” refers to implementations including any of (1) at least one A, (2) at least one B, or (3) at least one A and at least one B. Similarly, as used herein in the context of describing structures, components, items, objects and things, the phrase “at least one of A or B” refers to implementations including any of (1) at least one A, (2) at least one B, or (3) at least one A and at least one B. As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Also, although individual features may be included in different examples or claims, these may possibly be combined, and the inclusion in different examples or claims does not imply that a combination of features is at least one of not feasible or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by at least one of the connection reference or relative movement between those elements unless otherwise indicated. As such, connection references do not necessarily infer that two elements are directly connected or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, or ordering in any way, but are merely used as at least one of labels or arbitrary names to distinguish elements for ease of understanding the described examples. In some examples, the descriptor “first” may be used to refer to an element in the detailed description, while the same element may be referred to in a claim with a different descriptor such as “second” or “third.” In such instances, such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to at least one of manufacturing tolerances or other real-world imperfections. For example, “approximately” and “about” may indicate such dimensions may be within a tolerance range of +/−10% unless otherwise specified herein.

As used herein, the phrase “in communication,” including variations thereof, encompasses one of or a combination of direct communication or indirect communication through one or more intermediary components, and does not require direct physical (e.g., wired) communication or constant communication, but rather also includes selective communication at least one of periodic intervals, scheduled intervals, aperiodic intervals, or one-time events.

As used herein, “programmable circuitry” is defined to include at least one of (i) one or more special purpose electrical circuits (e.g., an application specific circuit (ASIC)) structured to perform specific operation(s) and including one or more semiconductor-based logic devices (e.g., electrical hardware implemented by one or more transistors), or (ii) one or more general purpose semiconductor-based electrical circuits programmable with instructions to perform one or more specific functions(s) or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations or functions, Field Programmable Gate Arrays (FPGAs) that may be programmed with second instructions to at least one of configure or structure the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., at least one of programmed or hardwired) at a time of manufacturing by a manufacturer to at least one of perform the function or be configurable (or re-configurable) by a user after manufacturing to perform the function/or other additional or alternative functions. The configuring may be through at least one of firmware or software programming of the device, through at least one of a construction or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as one of or a combination of resistors, capacitors, or inductors), or one or more sources (such as voltage and/or current sources) may instead include only the semiconductor elements within a single physical device (e.g., at least one of a semiconductor die or integrated circuit (IC) package) and may be adapted to be coupled to at least some of the passive elements or the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. For example, a transistor shown and described herein as a single component may instead be multiple transistors. In some such examples, transistor circuitry may correspond to one or more transistor components. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

Uses of the phrase “ground” in the foregoing description include at least one of a chassis ground, an Earth ground, a floating ground, a virtual ground, a digital ground, a common ground, or any other form of ground connection applicable to, or suitable for, the teachings of this description. Unless otherwise stated, “about,” “approximately,” or “substantially” preceding a value means+/−10 percent of the stated value, or, if the value is zero, a reasonable range of values around zero.

Modifications are possible in the described embodiments, and other embodiments are possible, within the scope of the claims.

What is claimed is:

1. An apparatus comprising:
first amplifier circuitry having a first output and a second output;
second amplifier circuitry having an output;
first transistor circuitry having a first terminal and a control terminal;
second transistor circuitry having a first terminal and a control terminal, the control terminal of the second transistor circuitry coupled to the output of the second amplifier circuitry and the control terminal of the first transistor circuitry; and
voltage-to-delay circuitry having a first input and a second input, the first input of the voltage-to-delay circuitry coupled to the first output of the first amplifier circuitry and the first terminal of the first transistor circuitry, the second input of the voltage-to-delay circuitry coupled to the second output of the first amplifier circuitry and the first terminal of the second transistor circuitry.

2. The apparatus of claim 1, wherein the first transistor circuitry includes:
a first transistor having a first terminal and a control terminal, the control terminal of the first transistor coupled to the output of the second amplifier circuitry and the control terminal of the second transistor circuitry; and
a second transistor having a first terminal, a second terminal, and a control terminal, the first terminal of the second transistor coupled to the first output of the first amplifier circuitry and the first input of the voltage-to-delay circuitry, the second terminal of the second transistor coupled to the first terminal of the first transistor.

3. The apparatus of claim 2, wherein the control terminal of the second transistor circuitry is a first control terminal, the second transistor circuitry further includes a second control terminal, and the first amplifier circuitry includes:
a third transistor having a first terminal, a second terminal, and a control terminal, the first terminal of the third transistor coupled to the first input of the voltage-to-delay circuitry and the first terminal of the second transistor;
a fourth transistor having a first terminal and a second terminal, the first terminal of the fourth transistor coupled to the second terminal of the third transistor;
a fifth transistor having a first terminal, a second terminal, and a control terminal, the first terminal of the fifth transistor coupled to the second input of the voltage-to-delay circuitry and the first terminal of the second transistor circuitry, the control terminal of the fifth transistor coupled to the control terminal of the second transistor, the second control terminal of the second transistor circuitry, and the control terminal of the third transistor; and
a sixth transistor having a first terminal and a second terminal, the first terminal of the sixth transistor coupled to the second terminal of the fifth transistor, the second terminal of the sixth transistor coupled to the second terminal of the fourth transistor.

4. The apparatus of claim 1, wherein the voltage-to-delay circuitry includes:
a first capacitor having a first terminal and a second terminal, the first terminal of the first capacitor coupled to the first output of the first amplifier circuitry and the first terminal of the first transistor circuitry;
a second capacitor having a first terminal and a second terminal, the first terminal of the second capacitor coupled to the second output of the first amplifier circuitry and the first terminal of the second transistor circuitry; and
a transistor having a terminal coupled to the second terminal of the first capacitor and the second terminal of the second capacitor.

5. The apparatus of claim 1, wherein the first amplifier circuitry has a first input and a second input, and the second amplifier circuitry includes:
a first transistor having a first terminal, a second terminal, and a control terminal, the control terminal of the first transistor coupled to the first input of the first amplifier circuitry;
a second transistor having a first terminal, a second terminal, and a control terminal, the control terminal of the second transistor coupled to the second input of the first amplifier circuitry;
current mirror circuitry having an input and an output, the input of the current mirror circuitry coupled to the first terminal of the first transistor and the first terminal of the second transistor;
a third transistor having a first terminal and a second terminal;
current source circuitry having a terminal coupled to the second terminal of the first transistor, the second terminal of the second transistor, and the first terminal of the third transistor; and
a fourth transistor having a first terminal and a control terminal, the first terminal of the fourth transistor coupled to the output of the current mirror circuitry and the second terminal of the third transistor, the control terminal of the fourth transistor coupled to the control terminal of the first transistor circuitry and the control terminal of the second transistor circuitry.

6. The apparatus of claim 5, wherein the current source circuitry is first current source circuitry, and the second amplifier circuitry further includes:
a fifth transistor having a first terminal and a control terminal;
second current source circuitry having a terminal coupled to the output of the current mirror circuitry, the second terminal of the third transistor, the first terminal of the fourth transistor, and the control terminal of the fifth transistor;
a first switch having a first terminal and a second terminal, the first terminal coupled to the control terminal of the fourth transistor and the first terminal of the fifth transistor;
a sixth transistor having a first terminal and a control terminal;
third current source circuitry having a terminal;
a seventh transistor having a first terminal and a control terminal, the control terminal of the seventh transistor coupled to the first terminal of the sixth transistor and the terminal of the third current source circuitry; and
a second switch having a first terminal and a second terminal, the first terminal of the second switch coupled to the control terminal of the sixth transistor and first terminal of the seventh transistor, the second terminal of the second switch coupled to the control terminal of the first transistor circuitry and the second terminal of the first switch.

7. The apparatus of claim 1, wherein the second amplifier circuitry further has an input, and the apparatus further comprising:
pulse generator circuitry including a first input, a second input, a first output, and a second output, the first input of the pulse generator circuitry coupled to the first output of the first amplifier circuitry, the first terminal of the first transistor circuitry, and the first input of the voltage-to-delay circuitry, the second input of the pulse generator circuitry coupled to the second output of the first amplifier circuitry, the first terminal of the second transistor circuitry, and the second input of the voltage-to-delay circuitry;
time-to-digital converter (TDC) circuitry having a first input, a second input, and an output, the first input of the TDC circuitry is coupled to the first output of the pulse generator circuitry, the second input of the TDC circuitry is coupled to the second output of the pulse generator circuitry; and
calibration controller circuitry having an input and an output, the input of the calibration controller circuitry coupled to the output of the TDC circuitry, the output of the calibration controller circuitry coupled to the input of the second amplifier circuitry.

8. The apparatus of claim 7, wherein the first amplifier circuitry further has a first input and second input, the input of the second amplifier circuitry is a first input, the second amplifier circuitry further has a second input, and a third input, and the apparatus further comprising:
sampling circuitry including:
a first switch having a first terminal, a second terminal, and a control terminal;
a second switch having a terminal;
a third switch having a first terminal, a second terminal, and a control terminal;
a fourth switch having a terminal; and
a fifth switch having a first terminal, a second terminal, and a control terminal, the first terminal of the fifth switch coupled to the first terminal of the first switch, the terminal of the second switch, the first input of the first amplifier circuitry, and the second input of the second amplifier circuitry, the second terminal of the fifth switch coupled to the first terminal of the third switch, the terminal of the fourth switch, the second input of the first amplifier circuitry, and the third input of the second amplifier circuitry; and
wherein the calibration controller circuitry includes:
offset correction circuitry having an input, a first output, a second output, and a third output, the first output of the offset correction circuitry coupled to the third input of the second amplifier circuitry, the second output of the offset correction circuitry coupled to the control terminal of the fifth switch; and
gain correction circuitry having an input, a first output, a second output, and a third output, the input of the gain correction circuitry coupled to the output of the TDC circuitry and the input of the offset correction circuitry, the first output of the gain correction circuitry coupled to the second terminal of the first switch, the second output of the gain correction circuitry coupled to the second terminal of the third switch, the third output of the gain correction circuitry coupled to the control terminal of the first switch and the control terminal of the third switch.

9. An apparatus comprising:
amplifier circuitry having a first input, a second input, a first output, and a second output;
voltage-to-delay circuitry having a first input and a second input;
pulse generator circuitry having a first input and a second input; and
calibration circuitry having a first input, a second input, a first output, and a second output, the first input of the calibration circuitry coupled to the first input of the amplifier circuitry, the second input of the calibration circuitry coupled to the second input of the amplifier circuitry, the first output of the calibration circuitry coupled to the first output of the amplifier circuitry, the first input of the voltage-to-delay circuitry, and the first input of the pulse generator circuitry, the second output of the calibration circuitry coupled to the second output of the amplifier circuitry, the second input of the voltage-to-delay circuitry, and the second input of the pulse generator circuitry.

10. The apparatus of claim 9, wherein the amplifier circuitry is first amplifier circuitry, and the calibration circuitry includes:
second amplifier circuitry having a first input, a second input, and an output, the first input of the second amplifier circuitry coupled to the first input of the first amplifier circuitry, the second input of the second amplifier circuitry coupled to the second input of the first amplifier circuitry;
first transistor circuitry having a first terminal and a control terminal, the first terminal of the first transistor circuitry coupled to the first output of the first amplifier circuitry, the first input of the voltage-to-delay circuitry, and the first input of the pulse generator circuitry; and
second transistor circuitry having a first terminal and a control terminal, the first terminal of the second transistor circuitry coupled to the second output of the first amplifier circuitry, the second input of the voltage-to-delay circuitry, and the second input of the pulse generator circuitry, the control terminal of the second transistor circuitry coupled to the output of the second amplifier circuitry and the control terminal of the first transistor circuitry.

11. The apparatus of claim 10, wherein the second amplifier circuitry includes:
a first transistor having a first terminal, a second terminal, and a control terminal, the control terminal of the first transistor coupled to the first input of the first amplifier circuitry;
a second transistor having a first terminal, a second terminal, and a control terminal, the control terminal of the second transistor coupled to the second input of the first amplifier circuitry;
current mirror circuitry having an input and an output, the input of the current mirror circuitry coupled to the first terminal of the first transistor and the first terminal of the second transistor;
a third transistor having a first terminal and a second terminal;
current source circuitry having a terminal coupled to the second terminal of the first transistor, the second terminal of the second transistor, and the first terminal of the third transistor; and
a fourth transistor having a first terminal and a control terminal, the first terminal of the fourth transistor coupled to the output of the current mirror circuitry and the second terminal of the third transistor, the control terminal of the fourth transistor coupled to the control terminal of the first transistor circuitry and the control terminal of the second transistor circuitry.

12. The apparatus of claim 11, wherein the current source circuitry is first current source circuitry, and the second amplifier circuitry further includes:
a fifth transistor having a first terminal and a control terminal;
second current source circuitry having a terminal coupled to the output of the current mirror circuitry, the second terminal of the third transistor, the first terminal of the fourth transistor, and the control terminal of the fifth transistor;
a first switch having a first terminal and a second terminal, the first terminal coupled to the control terminal of the fourth transistor and the first terminal of the fifth transistor;
a sixth transistor having a first terminal and a control terminal;
third current source circuitry having a terminal;
a seventh transistor having a first terminal and a control terminal, the control terminal of the seventh transistor coupled to the first terminal of the sixth transistor and the terminal of the third current source circuitry; and
a second switch having a first terminal and a second terminal, the first terminal of the second switch coupled to the control terminal of the sixth transistor and first terminal of the seventh transistor, the second terminal of the second switch coupled to the control terminal of the first transistor circuitry and the second terminal of the first switch.

13. The apparatus of claim 9, wherein the amplifier circuitry includes:
a first transistor having a first terminal, a second terminal, and a control terminal, the first terminal of the first transistor coupled to the first output of the calibration circuitry and the first input of the voltage-to-delay circuitry;
a second transistor having a first terminal, a second terminal, and a control terminal, the first terminal of the second transistor coupled to the second terminal of the first transistor, the control terminal of the second transistor coupled to the first input of the calibration circuitry;
a third transistor having a first terminal, a second terminal, and a control terminal, the first terminal of the third transistor coupled to the second output of the calibration circuitry and the second input of the voltage-to-delay circuitry, the control terminal of the third transistor coupled to the control terminal of the first transistor; and
a fourth transistor having a first terminal, a second terminal, and a control terminal, the first terminal of the fourth transistor coupled to the second terminal of the third transistor, the second terminal of the fourth transistor coupled to the second terminal of the second transistor, the control terminal of the fourth transistor coupled to the second input of the calibration circuitry.

14. The apparatus of claim 9, wherein the voltage-to-delay circuitry includes:
a first capacitor having a first terminal and a second terminal, the first terminal of the first capacitor coupled to the first output of the amplifier circuitry and the first output of the calibration circuitry;
a second capacitor having a first terminal and a second terminal, the first terminal of the second capacitor coupled to the second output of the amplifier circuitry and the second output of the calibration circuitry; and
a transistor having a terminal coupled to the second terminal of the first capacitor and the second terminal of the second capacitor.

15. The apparatus of claim 9, wherein the calibration circuitry further has a third input, and the apparatus further comprising:
time-to-digital converter (TDC) circuitry having a first input, a second input, and an output, the first input of the TDC circuitry is coupled to the first output of the pulse generator circuitry, the second input of the TDC circuitry is coupled to the second output of the pulse generator circuitry; and
calibration controller circuitry having an input and an output, the input of the calibration circuitry coupled to the output of the TDC circuitry, the output of the calibration circuitry coupled to the third input of the calibration circuitry.

16. The apparatus of claim 15, further comprising:
sampling circuitry including:
a first switch having a first terminal, a second terminal, and a control terminal;
a second switch having a terminal;
a third switch having a first terminal, a second terminal, and a control terminal;
a fourth switch having a terminal; and
a fifth switch having a first terminal, a second terminal, and a control terminal, the first terminal of the fifth switch coupled to the first terminal of the first switch, the terminal of the second switch, and the first input of the calibration circuitry, the second terminal of the fifth switch coupled to the first terminal of the third switch, the terminal of the fourth switch, and the second input of the calibration circuitry; and
wherein the calibration controller circuitry includes:
offset correction circuitry having an input, a first output, a second output, and a third output, the first output of the offset correction circuitry coupled to the third input of the calibration circuitry, the second output of the offset correction circuitry coupled to the control terminal of the fifth switch; and
gain correction circuitry having an input, a first output, a second output, and a third output, the input of the gain correction circuitry coupled to the output of the TDC circuitry and the input of the offset correction circuitry, the first output of the gain correction circuitry coupled to the second terminal of the first switch, the second output of the gain correction circuitry coupled to the second terminal of the third switch, the third output of the gain correction circuitry coupled to the control terminal of the first switch and the control terminal of the third switch.

17. An apparatus comprising:
amplifier circuitry having an input and an output;
voltage-to-delay circuitry having an input;
calibration circuitry having an input and an output, the input of the calibration circuitry coupled to the input of the amplifier circuitry, the output of the calibration circuitry coupled to the output of the amplifier circuitry and the input of the voltage-to-delay circuitry, the calibration circuitry configured to:
adjust a common mode voltage at the output of the amplifier circuitry corresponding to an offset correction value; and
adjust the common mode voltage at the output of the amplifier circuitry corresponding to a gain correction value.

18. The apparatus of claim 17, wherein the voltage-to-delay circuitry further has an output, and the apparatus further comprising:
pulse generator circuitry having an input and an output, the input of the pulse generator circuitry coupled to the output of the voltage-to-delay circuitry; and
time-to-digital converter (TDC) circuitry having an input coupled to the output of the pulse generator circuitry.

19. The apparatus of claim 18, wherein the input of the calibration circuitry is a first input, the calibration circuitry further has a second input, the TDC circuitry further has an output, and the apparatus further comprising calibration controller circuitry having an input and an output, the input of the calibration controller circuitry coupled to the output of the TDC circuitry, the output of the calibration controller circuitry coupled to the second input of the calibration circuitry, the calibration controller circuitry configured to:
determine a common mode voltage offset of the amplifier circuitry and the voltage-to-delay circuitry based on the output of the TDC circuitry;
adjust the common mode voltage offset using a reference common mode voltage of the calibration circuitry; and
determine the offset correction value based on the reference common mode voltage.

20. The apparatus of claim 17, wherein the amplifier circuitry is first amplifier circuitry, the apparatus further comprising:
second amplifier circuitry having an input and an output; and
wherein the calibration circuitry is further configured to:
adjust the common mode voltage of the output of the second amplifier circuitry based on the input of the second amplifier circuitry.
